(19) United States
(12) Patent Application Publication
(10) Pub. No.: US 2021/0165324 A1
(43) Pub. Date: Jun. 3, 2021

(54) RESIST COMPOSITION AND METHOD OF FORMING RESIST PATTERN

(71) Applicant: TOKYO OHKA KOGYO CO., LTD., Kawasaki-shi (JP)

(72) Inventors: Yosuke SUZUKI, Kawasaki-shi (JP); Takahiro KOJIMA, Kawasaki-shi (JP); Yasuhiro YOSHII, Kawasaki-shi (JP); Yoichi HORI, Kawasaki-shi (JP); Mari MURATA, Kawasaki-shi (JP)

(21) Appl. No.: 17/103,234

(22) Filed: Nov. 24, 2020

(30) Foreign Application Priority Data
Dec. 3, 2019 (JP) 2019-218926

(51) Int. Cl. G03F 7/039; G03F 7/004; G03F 7/09; G03F 7/20; C08L 33/08

(52) U.S. Cl. CPC G03F 7/0392; G03F 7/0045; C08L 33/08; G03F 7/2004; G03F 7/09

(57) ABSTRACT

A resist composition containing: a base material component exhibiting changed solubility in a developing solution under action of acid; an acid generator component generating an acid upon exposure; and a photodegradable base controlling diffusion of the acid generated from the acid generator component upon exposure, in which the photodegradable base contains a compound represented by General Formula (d0), in which R⁰¹¹ represents an aryl group having an electron-withdrawing group, R⁰²¹ and R⁰²² each independently represent an aryl group which may have a substituent, Z represents a sulfur atom, an oxygen atom, a carbonyl group, or a single bond, and X⁻ represents a counter anion

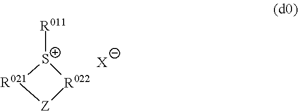

### BACKGROUND OF THE INVENTION

### Field of the Invention

The present invention relates to a resist composition and a method of forming a resist pattern.

Priority is claimed on Japanese Patent Application No. 2019-218926, filed on Dec. 3, 2019, the content of which is incorporated herein by reference.

### Description of Related Art

In recent years, in the production of semiconductor elements and liquid crystal display elements, advances in lithography techniques have led to rapid progress in the field of pattern miniaturization. Typically, these miniaturization techniques involve shortening the wavelength (increasing the energy) of the light source for exposure.

Resist materials for use with these types of light sources for exposure require lithography characteristics such as a high resolution capable of reproducing patterns of minute dimensions, and a high level of sensitivity to these types of light sources for exposure.

As a resist material that satisfies these requirements, in the related art, a chemical amplification type resist composition that contains a base material component exhibiting changed solubility in a developing solution under action of acid and an acid generator component that generates an acid upon exposure has been used.

In the formation of the resist pattern, the behavior of an acid generated from an acid generator component upon exposure is considered as one factor that has a great influence on the lithography characteristics.

On the other hand, a chemical amplification type resist composition having both an acid generator component and an acid diffusion controlling agent that controls the diffusion of an acid generated from the acid generator component upon exposure has been proposed.

For example, Japanese Unexamined Patent Application, First Publication No. 2014-115386 discloses a resist composition containing a resin component exhibiting changed solubility in a developing solution under action of acid; an acid generator component, and a photoreactive quencher having a cation moiety that has a specific structure, as an acid diffusion controlling agent. This photoreactive quencher is considered as a component that exhibits a quenching effect by causing an ion exchange reaction with an acid generated from an acid generator component. In a case where such a photoreactive quencher is blended, the diffusion of an acid generated from an acid generator component from the exposed portion of the resist film to the unexposed portion is controlled, whereby the lithography characteristics are improved.

### CITATION LIST

### Patent Literature

[Patent Literature 1] Japanese Unexamined Patent Application, First Publication No. 2014-115386

### SUMMARY OF THE INVENTION

As the pattern miniaturization progresses, in regard to the resist material, it is important for the generation of scum (resist residue) to be suppressed after development together with improvement of the various lithography characteristics.

However, in a case of attempting further resist pattern miniaturization by using the conventional resist composition as described above, it has been difficult to sufficiently suppress the generation of scum (resist residue) after development.

The present invention has been made in consideration of the above circumstances, an object of the present invention is to provide a resist composition, with which the generation of scum (resist residue) after development can be reduced, and a method of forming a resist pattern using the resist composition.

In order to achieve the above-described object, the present invention employs the following configurations.

That is, the first aspect of the present invention is a resist composition which generates an acid upon exposure and exhibits changed solubility in a developing solution under action of acid. The resist composition contains: a base material component (A) exhibiting changed solubility in a developing solution under action of acid; an acid generator component (B) generating an acid upon exposure; and a photodegradable base (D0) controlling diffusion of the acid generated from the acid generator component (B) upon exposure, where the photodegradable base (D0) contains a compound represented by General Formula (d0).

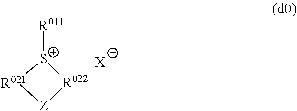

[In the formula, R⁰¹¹ represents an aryl group having an electron-withdrawing group. R⁰²¹ and R⁰²² each independently represent an aryl group which may have a substituent. Z represents a sulfur atom, an oxygen atom, a carbonyl group, or a single bond. X⁻ represents a counter anion.]

The second aspect of the present invention is a method of forming a resist pattern, including a step of forming a resist film on a support using the resist composition according to the first aspect, a step of exposing the resist film, and a step of developing the exposed resist film to form a resist pattern.

According to the present invention, it is possible to provide a resist composition, with which the generation of scum (resist residue) after development can be reduced, and a method of forming a resist pattern using the resist composition.

### DETAILED DESCRIPTION OF THE INVENTION

In the present specification and the scope of the present patent claims, the term “aliphatic” is a relative concept used with respect to the term “aromatic” and denines a group or compound that has no aromaticity.

The term “alkyl group” contains a monovalent saturated hydrocarbon group that is linear, branched, or cyclic, unless otherwise specified. The same applies to the alkyl group in an alkoxy group.

The term “alkylene group” contains a divalent saturated hydrocarbon group that is linear, branched, or cyclic, unless otherwise specified.

Examples of the “halogen atom” include a fluorine atom, a chlorine atom, a bromine atom, and an iodine atom.

The term “constitutional unit” means a monomer unit (monomeric unit) that contributes to the formation of a high molecular compound (a resin, a polymer, or a copolymer).

In a case where “may have a substituent” is described, both of a case where a monovalent group is substituted for a hydrogen atom (—H) and a case where a divalent group is substituted for a methylene (—CH₂—) group are included.

The term “exposure” is used as a general concept that includes irradiation with any form of radiation.

The term “acid decomposable group” indicates a group having an acid decomposability, in which at least a part of a bond in the structure of the acid decomposable group can be cleaved by an action of an acid.

Examples of the acid decomposable group having a polarity which is increased by an action of an acid include groups which are decomposed by an action of an acid to generate a polar group.

Examples of the polar group include a carboxy group, a hydroxy group, an amino group, and a sulfo group (—SO₃H).

More specific examples of the acid decomposable group include a group in which the above-described polar group has been protected by an acid dissociable group (for example, a group in which a hydrogen atom of the OH-containing polar group has been protected by an acid dissociable group).

The “acid dissociable group” indicates both (i) a group having an acid dissociability in which a bond between the acid dissociable group and an atom adjacent to the acid dissociable group can be cleaved by an action of an acid; and (ii) a group in which some bonds are cleaved by an action of an acid, and then a decarboxylation reaction occurs, thereby cleaving the bond between the acid dissociable group and the atom adjacent to the acid dissociable group.

It is necessary that the acid dissociable group that constitutes the acid decomposable group is a group which exhibits a polarity lower than the polarity of the polar group generated by the dissociation of the acid dissociable group. Accordingly, in a case where the acid dissociable group is dissociated by an action of an acid, a polar group which exhibits a polarity higher than the polarity of the acid dissociable group is generated, thereby increasing the polarity. As a result, the polarity of the entire component (A1) is increased. By the increase in the polarity, the solubility in a developing solution relatively changes. The solubility is increased in a case where the developing solution is an alkali developing solution, whereas the solubility is decreased in a case where the developing solution is an organic developing solution.

The “base material component” is an organic compound having a film forming ability. The organic compounds used as the base material component are roughly classified into a non-polymer and a polymer. As the non-polymer, those having a molecular weight of 500 or more and less than 4,000 are usually used. Hereinafter, a “low molecular compound” refers to a non-polymer having a molecular weight of 500 or more and less than 4,000. As the polymer, those having a molecular weight of 1,000 or more are usually used. Hereinafter, “resin”, “high molecular compound”, or “polymer” refers to a polymer having a molecular weight of 1,000 or more. As the molecular weight of the polymer, a polystyrene-equivalent mass-average molecular weight determined by gel permeation chromatography (GPC) is used.

A “constitutional unit derived from” means a constitutional unit that is formed by the cleavage of a multiple bond between carbon atoms, for example, an ethylenic double bond.

In the acrylic acid ester, the hydrogen atom bonded to the carbon atom at the α-position may be substituted with a substituent. The substituent (R^{αx}) that is substituted for the hydrogen atom bonded to the carbon atom at the α-position is an atom other than a hydrogen atom or a group. Further, an itaconic acid diester in which the substituent (R^{αx}) is substituted with a substituent having an ester bond or an α-hydroxyacryl ester in which the substituent (R^{αx}) is substituted with a hydroxyalkyl group or a group obtained by modifying a hydroxy group thereof can be mentioned as the acrylic acid ester. A carbon atom at the α-position of the acrylic acid ester indicates the carbon atom bonded to the carbonyl group of acrylic acid, unless otherwise specified.

Hereinafter, an acrylic acid ester in which the hydrogen atom bonded to the carbon atom at the α-position is substituted with a substituent is also referred to as the α-substituted acrylic acid ester”.

The term “derivative” includes those in which the hydrogen atom at the α-position of an object compound has been substituted with other substituents such as an alkyl group and a halogenated alkyl group; and derivatives thereof. Examples of the derivatives thereof include: a derivative in which the hydrogen atom of the hydroxy group of the object compound in which the hydrogen atom at the α-position may be substituted with an organic group; and a derivative in which a substituent other than a hydroxy group is bonded to the object compound in which the hydrogen atom at the α-position may be substituted with a substituent. The α-position refers to the first carbon atom adjacent to the functional group unless otherwise specified.

Examples of the substituent that is substituted for the hydrogen atom at the α-position of hydroxystyrene include the same group as R^{αx}.

In the present specification and the scope of the present patent claims, an asymmetric carbon may be present or enantiomers or diastereomers may be present depending on the structure of the chemical formula. In that case, these isomers are represented by one chemical formula. These isomers may be used alone or in the form of a mixture.

(Resist Composition)

The resist composition of the present embodiment is a resist composition generating an acid upon exposure and exhibiting changed solubility in a developing solution under action of acid.

The resist composition contains: a base material component (A) (hereinafter, also referred to as component (A)) exhibiting changed solubility in a developing solution under action of acid; an acid generator component (B) (hereinafter, also referred to as “component (B)”) generating an acid upon exposure; and a photodegradable base (D0) (hereinafter, also referred to as “component (D0)”) controlling diffusion of the acid generated from the acid generator component (B) upon exposure. In addition, the photodegradable base (D0) contains a compound represented by General Formula (d).

In a case where a resist film is formed using the resist composition of the present embodiment and the formed resist film is subjected to selective exposure, an acid is generated from the component (B) at the exposed portion of the resist film, and the generated acid acts on the component (A) to change the solubility of the component (A) in a developing solution, whereas the solubility of the component (A) in the developing solution is not changed at the unexposed portion, thereby generating the difference in solubility in the developing solution between the exposed portion and the unexposed portion of the resist film. As a result, when the resist film is subjected to development, the exposed portion of the resist film is dissolved and removed to form a positive-tone resist pattern in a case where the resist composition is positive-tone, whereas the unexposed portion of the resist film is dissolved and removed to form a negative-tone resist pattern in a case where the resist composition is negative-tone.

In the present specification, a resist composition which forms a positive-tone resist pattern by dissolving and removing the exposed portion of the resist film is called a positive-tone resist composition, and a resist composition which forms a negative-tone resist pattern by dissolving and removing the unexposed portion of the resist film is called a negative-tone resist composition. The resist composition of the present embodiment may be a positive-tone resist composition or a negative-tone resist composition. Further, in the formation of a resist pattern, the resist composition of the present embodiment may be applied to an alkali developing process using an alkali developing solution in the developing treatment, or a solvent developing process using a developing solution (an organic developing solution) containing an organic solvent in the developing treatment.

<Component (A)>

In the resist composition of the present embodiment, the component (A) preferably contains a resin component (A1) (hereinafter, also referred to as “component (A1)”) exhibiting changed solubility in a developing solution under action of acid. In a case where the component (A1) is used, the polarity of the base material component before and after exposure is changed, and thus an excellent development contrast can be obtained in the alkali developing process and the solvent developing process.

As the component (A), at least the component (A1) is used, and other high molecular compound and/or a low molecular compound may be used in combination with the component (A1).

In a case where an alkali developing process is employed, a base material component containing the component (A1) is substantially insoluble in an alkali developing solution before exposure, but in a case where an acid is generated from the component (B) upon exposure, the action of the acid causes an increase in the polarity of the base material component, thereby increasing the solubility of the base material component in an alkali developing solution. Accordingly, in the formation of a resist pattern, by performing selective exposure of a resist film formed by applying the resist composition onto a support, the exposed portion of the resist film changes from an insoluble state to a soluble state in an alkali developing solution, whereas the unexposed portion of the resist film remains insoluble in an alkali developing solution, and thus a positive-tone resist pattern is formed by alkali developing.

On the other hand, in a case where a solvent developing process is employed, the base material component containing the component (A1) exhibits high solubility in an organic developing solution before exposure, and in a case where an acid is generated from the component (B) upon exposure, the polarity of the component (A1) is increased by the action of the generated acid, thereby decreasing the solubility of the component (A1) in an organic developing solution. As a result, in the formation of a resist pattern, by performing selective exposure of a resist film formed by applying the resist composition onto a support, the exposed portion of the resist film changes from a soluble state to an insoluble state in an organic developing solution, whereas the unexposed portion of the resist film remains soluble and does not change, whereby a contrast between the exposed portion and the un exposed portion can be obtained, and thus a negative-tone resist pattern is formed by developing in the organic developing solution.

In the resist composition of the present embodiment, the component (A) may be used alone or in a combination of two or more kinds thereof.

In Regard to Component (A1)

The component (A1) is a resin component exhibiting changed solubility in a developing solution under action of acid. The component (A1) preferably has a constitutional unit (a1) which includes an acid decomposable group having a polarity which is increased by an action of an acid.

The component (A1) may have other constitutional units as necessary in addition to the constitutional unit (a1).

<<Constitutional Unit (a1)>>

The constitutional unit (a1) is a constitutional unit which contains an acid decomposable group having a polarity which is increased by an action of an acid.

Examples of the acid dissociable group are the same as those which have been proposed as an acid dissociable group for the base resin for a chemical amplification type resist composition.

Specific examples of the acid dissociable group of a base resin for a chemical amplification type resist composition include an “acetal-type acid dissociable group”, a “tertiary alkyl ester-type acid dissociable group” and a “tertiary alkyloxycarbonyl-type acid dissociable group” described below.

Acetal-Type Acid Dissociable Group:

Examples of the acid dissociable group for protecting a carboxy group or a hydroxy group as a polar group include acid dissociable groups represented by General Formula (a1-r-1) (hereinafter, also referred to as the “acetal-type acid dissociable group”).

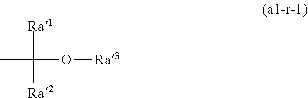

[In the formula, Ra′¹ and Ra′² represent hydrogen atoms or alkyl groups. Ra′³ represents a hydrocarbon group, and Ra′³ may be bonded to Ra′¹ or Ra′² to form a ring.]

In Formula (a1-r-1), it is preferable that at least one of Ra′¹ and Ra′² represents a hydrogen atom and more preferable that both of Ra′¹ and Ra′² represent hydrogen atoms.

In a case where Ra′¹ or Ra′² represents an alkyl group, examples of the alkyl group include the same alkyl groups as those mentioned as the substituent which may be bonded to the carbon atom at the α-position in the description on the α-substituted acrylic acid ester. Among these, an alkyl group having 1 to 5 carbon atoms is preferable. Specific examples thereof preferably include linear or branched alkyl groups. Specific examples of the alkyl group include a methyl group, an ethyl group, a propyl group, an isopropyl group, an n-butyl group, an isobutyl group, a tert-butyl group, a pentyl group, an isopentyl group, and a neopentyl group. Among these, a methyl group or an ethyl group is more preferable, and a methyl group is particularly preferable.

In Formula (a1-r-1), examples of the hydrocarbon group as Ra′³ include a linear or branched alkyl group and a cyclic hydrocarbon group.

The linear alkyl group has preferably 1 to 5 carbon atoms, more preferably 1 to 4 carbon atoms, and still more preferably 1 or 2 carbon atoms. Specific examples thereof include a methyl group, an ethyl group, an n-propyl group, an n-butyl group, and an n-pentyl group. Among these, a methyl group, an ethyl group, or an n-butyl group is preferable, and a methyl group or an ethyl group is more preferable.

The branched alkyl group has preferably 3 to 10 carbon atoms and more preferably 3 to 5 carbon atoms. Specific examples thereof include an isopropyl group, an isobutyl group, a tert-butyl group, an isopentyl group, a neopentyl group, a 1,1-diethylpropyl group, and a 2,2-dimethylbutyl group. Among these, an isopropyl group is preferable.

In a case where Ra′³ represents a cyclic hydrocarbon group, the cyclic hydrocarbon group may be an aliphatic hydrocarbon group or an aromatic hydrocarbon group and may be a polycyclic group or a monocyclic group.

The aliphatic hydrocarbon group which is a monocyclic group is preferably a group in which one hydrogen atom has been removed from a monocycloalkane. The monocycloalkane has preferably 3 to 6 carbon atoms, and specific examples thereof include cyclopentane and cyclohexane.

The aliphatic hydrocarbon group which is a polycyclic group is preferably a group in which one hydrogen atom has been removed from a polycycloalkane. The polycycloalkane is preferably a group having 7 to 12 carbon atoms, and specific examples of thereof include adamantane, norbornane, isobornane, tricyclodecane, and tetracyclododecane.

In a case where the cyclic hydrocarbon group as Ra′³ is an aromatic hydrocarbon group, the aromatic hydrocarbon group is a hydrocarbon group having at least one aromatic ring.

The aromatic ring is not particularly limited as long as it is a cyclic conjugated system having (4n+2) π electrons, and may be monocyclic or polycyclic. The aromatic ring has preferably 5 to 30 carbon atoms, more preferably 5 to 20 carbon atoms, still more preferably 6 to 15 carbon atoms, and particularly preferably 6 to 12 carbon atoms. Specific examples of the aromatic ring include: aromatic hydrocarbon rings such as benzene, naphthalene, anthracene, and phenanthrene; and aromatic hetero rings in which a part of carbon atoms constituting the above-described aromatic hydrocarbon rings have been substituted with hetero atoms. Examples of the hetero atom in the aromatic hetero rings include an oxygen atom, a sulfur atom, and a nitrogen atom. Specific examples of the aromatic hetero ring include a pyridine ring and a thiophene ring.

Specific examples of the aromatic hydrocarbon group as Ra′³ include: a group in which one hydrogen atom has been removed from the above-described aromatic hydrocarbon ring or aromatic hetero ring (an aryl group or a heteroaryl group); a group in which one hydrogen atom has been removed from an aromatic compound having two or more aromatic rings (biphenyl, fluorene or the like); and a group in which one hydrogen atom of the above-described aromatic hydrocarbon ring or aromatic hetero ring has been substituted with an alkylene group (for example, arylalkyl groups such as a benzyl group, a phenethyl group, a 1-naphthylmethyl group, a 2-naphthylmethyl group, a 1-naphthylethyl group, and a 2-naphthylethyl group). The number of carbon atoms in the alkylene group bonded to the aromatic hydrocarbon ring or aromatic hetero ring is preferably 1 to 4, more preferably 1 or 2, and particularly preferably 1.

The cyclic hydrocarbon group as Ra′³ may have a substituent. Examples of the substituent include, —R^{P1}, —R^{P2}—O—R^{P1}, —R^{P2}—CO—R^{P1}, —R^{P2}—CO—OR^{P1}, —R^{P2}—O—CO—R^{P1},—R^{P2}—OH, —R^{P2}—CN, and —R^{P2}—COOH (hereinafter, these substituents are also collectively referred to as “Ra^{x5}”.). Here, R^{P1} represents a monovalent chain-like saturated hydrocarbon group having 1 to 10 carbon atoms, a monovalent aliphatic cyclic saturated hydrocarbon group having 3 to 20 carbon atoms, or a monovalent aromatic hydrocarbon group having 6 to 30 carbon atoms. In addition, R^{P2} represents a single bond, a divalent chain-like saturated hydrocarbon group having 1 to 10 carbon atoms, a divalent aliphatic cyclic saturated hydrocarbon group having 3 to 20 carbon atoms, or a divalent aromatic hydrocarbon group having 6 to 30 carbon atoms. However, a part or all of the hydrogen atoms contained in the chain-like saturated hydrocarbon group, aliphatic cyclic saturated hydrocarbon group, and aromatic hydrocarbon group of R^{P1} and R^{P2} may be substituted with fluorine atoms. In the aliphatic cyclic hydrocarbon group, one or more of the above-described substituents may be included as a single kind, or one or more of the above-described substituents may be included as a plurality of kinds.

Examples of the monovalent chain-like saturated hydrocarbon group having 1 to 10 carbon atoms include a methyl group, an ethyl group, a propyl group, a butyl group, a pentyl group, a hexyl group, a heptyl group, an octyl group, and a decyl group.

Examples of the monovalent aliphatic cyclic saturated hydrocarbon group having 3 to 20 carbon atoms include: monocyclic aliphatic saturated hydrocarbon groups such as a cyclopropyl group, a cyclobutyl group, a cyclopentyl group, a cyclohexyl group, a cycloheptyl group, a cyclooctyl group, a cyclodecyl group, and cyclododecyl group; and polycyclic aliphatic saturated hydrocarbon groups such as a bicyclo[2.2.2]octanyl group, a tricyclo[5.2.1.02,6]decanyl group, a tricyclo [3.3.1.13,7]decanyl group, a tetracyclo[6.2.1.13,6.02,7] dodecanyl group, and an adamantyl group.

Examples of the monovalent aromatic hydrocarbon group having 6 to 30 carbon atoms include groups in which one hydrogen atom has been removed from aromatic hydrocarbon rings such as benzene, biphenyl, fluorene, naphthalene, anthracene, and phenanthrene.

In a case where Ra′³ is bonded to Ra′¹ or Ra′² to form a ring, the cyclic group is preferably a 4- to 7-membered ring, and more preferably a 4- to 6-membered ring. Specific examples of the cyclic group include a tetrahydropyranyl group and a tetrahydrofuranyl group.

Tertiary alkyl ester-type acid dissociable group:

Among the above polar groups, examples of the acid dissociable group for protecting the carboxy group include acid dissociable groups represented by General Formula (a1-r-2).

Among the acid dissociable groups represented by Formula (a1-r-2), for convenience, a group which is constituted of an alkyl group is referred to as “tertiary alkyl ester-type acid dissociable group”.

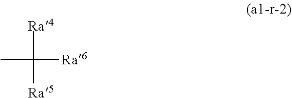

[In the formula, Ra′⁴ to Ra′⁶ each represent a hydrocarbon group, and Ra′⁵ and Ra′⁶ may be bonded to each other to form a ring.]

Examples of the hydrocarbon group as Ra′⁴ include a linear or branched alkyl group, a chain-like or cyclic alkenyl group, and a cyclic hydrocarbon group.

The linear or branched alkyl group or the cyclic hydrocarbon group (an aliphatic hydrocarbon group which is a monocyclic group, an aliphatic hydrocarbon group which is a polycyclic group, or an aromatic hydrocarbon group) as Ra′⁴ is the same as that mentioned as Ra′³.

The chain-like or cyclic alkenyl group as Ra′⁴ is preferably an alkenyl group having 2 to 10 carbon atoms.

Examples of the hydrocarbon group as Ra′⁵ or Ra′⁶ are the same as those mentioned above as Ra′³.

In a case where Ra′⁵ and Ra′⁶ are bonded to each other to form a ring, groups represented by General Formula (a1-r2-1), General Formula (a1-r2-2), and General Formula (a1-r2-3) can be suitably mentioned.

On the other hand, in a case where Ra′⁴ to Ra′⁶ are not bonded to each other and represent an independent hydrocarbon group, a group represented by General Formula (a1-r2-4) can be suitably mentioned.

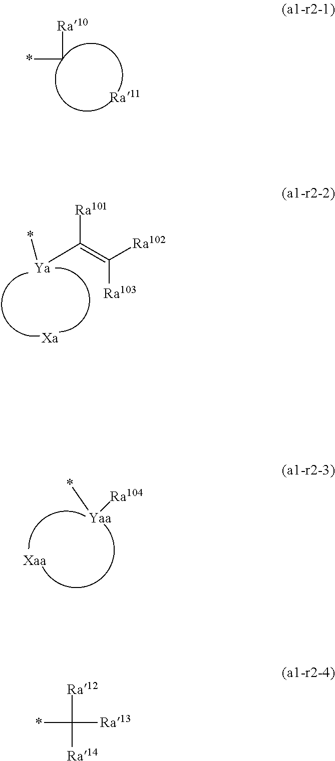

[In Formula (a1-r2-1), Ra′¹⁰ represents a linear or branched alkyl group having 1 to 12 carbon atoms, a part of which may be substituted with a halogen atom or a hetero atom-containing group. Ra′¹¹ represents a group that forms an aliphatic cyclic group together with a carbon atom to which Ra′¹¹ is bonded. In Formula (a1-r2-2), Ya represents a carbon atom. Xa is a group that forms a cyclic hydrocarbon group together with Ya. A part or all of the hydrogen atoms that the cyclic hydrocarbon group has may be substituted. Ra¹⁰¹ to Ra¹⁰³ each independently represent a hydrogen atom, a monovalent chain-like saturated hydrocarbon group having 1 to 10 carbon atoms, or a monovalent aliphatic cyclic saturated hydrocarbon group having 3 to 20 carbon atoms. Apart or all of the hydrogen atoms that the chain-like saturated hydrocarbon group and the aliphatic cyclic saturated hydrocarbon group have may be substituted. Two or more of Ra¹⁰¹ to Ra¹⁰³ may be bonded to each other to form a cyclic structure. In Formula (a1-r2-3), Yaa represents a carbon atom. Xaa is a group that forms an aliphatic cyclic group together with Yaa. Ra¹⁰⁴ represents an aromatic hydrocarbon group which may have a substituent. In Formula (a1-r2-4), Ra′¹² and Ra′¹³ each independently represent a monovalent chain-like saturated hydrocarbon group having 1 to 10 carbon atoms or a hydrogen atom. A part or all of the hydrogen atoms that the chain-like saturated hydrocarbon group has may be substituted. Ra′¹⁴ represents a hydrocarbon group which may have a substituent. * represents a bond.]

In Formula (a1-r2-1), Ra′¹⁰ represents a linear or branched alkyl group having 1 to 12 carbon atoms, a part of which may be substituted with a halogen atom or a hetero atom-containing group.

The linear alkyl group as Ra′¹⁰ has 1 to 12 carbon atoms, and has preferably 1 to 10 carbon atoms and particularly preferably 1 to 5 carbon atoms.

Examples of the branched alkyl group as Ra′¹⁰ are the same as those mentioned above as Ra′³.

A part of the alkyl group as Ra′¹⁰ may be substituted with a halogen atom or a hetero atom-containing group. For example, a part of the hydrogen atoms constituting the alkyl group may be substituted with a group containing a halogen atom or a hetero atom. Further, a part of carbon atoms (such as methylene group) constituting the alkyl group may be substituted with a hetero atom-containing group.

Examples of the hetero atom mentioned here include an oxygen atom, a sulfur atom, and a nitrogen atom. Examples of the hetero atom-containing group include —O—, —C(═O)—O—, —O—C(═O)—, —C(═O)—, —O—C(═O)—O—, —C(═O)—NH—, —NH—, —S—, —S(═O)₂—, and —S(═O)₂—O—.

In Formula (a1-r2-1), Ra′¹¹ (an aliphatic cyclic group that is formed together with the carbon atom to which Ra′¹⁰ is bonded) is preferably the group mentioned as the aliphatic hydrocarbon group (alicyclic hydrocarbon group) which is a monocyclic group or apolycyclic group as Ra′³ in Formula (a1-r-1). Among them, a monocyclic alicyclic hydrocarbon group is preferable, and specifically, a cyclopentyl group and a cyclohexyl group are more preferable, and a cyclopentyl group is still more preferable.

In Formula (a1-r2-2), examples of the cyclic hydrocarbon group formed by Xa together with Ya include groups in which one or more hydrogen atoms are further removed from a monovalent cyclic hydrocarbon group (an aliphatic hydrocarbon group) as Ra′³ in Formula (a1-r-1).

The cyclic hydrocarbon group that is formed by Xa together with Ya may have a substituent. Examples of this substituent include the same group as the substituent which the cyclic hydrocarbon group as Ra′³ may have.

In Formula (a1-r2-2), as Ra¹⁰¹ to Ra¹⁰³, examples of the monovalent chain-like saturated hydrocarbon group having 1 to 10 carbon atoms include a methyl group, an ethyl group, a propyl group, a butyl group, a pentyl group, a hexyl group, a heptyl group, an octyl group, and a decyl group.

Examples of the monovalent aliphatic cyclic saturated hydrocarbon group having 3 to 20 carbon atoms, as Ra¹⁰¹ to Ra¹⁰³, include: monocyclic aliphatic saturated hydrocarbon groups such as a cyclopropyl group, a cyclobutyl group, a cyclopentyl group, a cyclohexyl group, a cycloheptyl group, a cyclooctyl group, a cyclodecyl group, and cyclododecyl group; and polycyclic aliphatic saturated hydrocarbon groups such as a bicyclo[2.2.2]octanyl group, a tricyclo[5.2.1.02,6]decanyl group, a tricyclo [3.3.1.13,7]decanyl group, a tetracyclo[6.2.1.13,6.02,7] dodecanyl group, and an adamantyl group.

Among them, Ra¹⁰¹ to Ra¹⁰³ are preferably a hydrogen atom or a monovalent chain-like saturated hydrocarbon group having 1 to 10 carbon atoms, from the viewpoint of the easy synthesis. Among them, a hydrogen atom, a methyl group, and an ethyl group are more preferable, and a hydrogen atom is particularly preferable.

Examples of the substituent which the chain-like saturated hydrocarbon group represented by Ra¹⁰¹ to Ra¹⁰³ or the aliphatic cyclic saturated hydrocarbon group has include the same groups as Ra^{x5} described above.

Examples of the group including a carbon-carbon double bond generated by forming a cyclic structure, in which two or more of Ra¹⁰¹ to Ra¹⁰³ are bonded to each other, include a cyclopentenyl group, a cyclohexenyl group, a methylcyclopentenyl group, a methylcyclohexenyl group, a cyclopentylideneethenyl group, and a cyclohexylideneethenyl group. Among these, a cyclopentenyl group, a cyclohexenyl group, and a cyclopentylideneethenyl group are preferable from the viewpoint of easy synthesis.

In Formula (a1-r2-3), an aliphatic cyclic group that is formed by Xaa together with Yaa is preferably the group mentioned as the aliphatic hydrocarbon group which is a monocyclic group or a polycyclic group as Ra′³ in Formula (a1-r-1).

In Formula (a1-r2-3), examples of the aromatic hydrocarbon group as Ra¹⁰⁴ include groups in which one or more hydrogen atoms have been removed from an aromatic hydrocarbon ring having 5 to 30 carbon atoms. Among them, Ra¹⁰⁴ is preferably a group in which one or more hydrogen atoms have been removed from an aromatic hydrocarbon ring having 6 to 15 carbon atoms, more preferably a group in which one or more hydrogen atoms have been removed from benzene, naphthalene, anthracene, or phenanthrene, still more preferably a group in which one or more hydrogen atoms have been removed from benzene, naphthalene, or anthracene, particularly preferably a group in which one or more hydrogen atoms have been removed from benzene or naphthalene, and most preferably a group in which one or more hydrogen atoms have been removed from benzene.

Examples of the substituent which Ra¹⁰⁴ in Formula (a1-r2-3) may have include a methyl group, an ethyl group, propyl group, a hydroxy group, a carboxy group, a halogen atom, an alkoxy group (a methoxy group, an ethoxy group, a propoxy group, a butoxy group, and the like), and an alkyloxycarbonyl group.

In Formula (a1-r2-4), Ra′¹² and Ra′¹³ each independently represent a monovalent chain-like saturated hydrocarbon group having 1 to 10 carbon atoms or a hydrogen atom. Examples of the monovalent chain-like saturated hydrocarbon group having 1 to 10 carbon atoms as Ra′¹² and Ra′¹³ include the same monovalent chain-like saturated hydrocarbon groups as those having 1 to 10 carbon atoms as Ra¹⁰¹ to Ra¹⁰³ as described above. A part or all of the hydrogen atoms that the chain-like saturated hydrocarbon group has may be substituted.

Among them, Ra′¹² and Ra′¹³ are preferably a hydrogen atom or an alkyl group having 1 to 5 carbon atoms, more preferably an alkyl group having 1 to 5 carbon atoms, still more preferably a methyl group or an ethyl group, and particularly preferably a methyl group.

In a case where the chain-like saturated hydrocarbon groups represented by Ra′¹² and Ra′¹³ are substituted, examples of the substituent include the same group as Ra^{x5} described above.

In Formula (a1-r2-4), Ra′¹⁴ represents a hydrocarbon group which may have a substituent. Examples of the hydrocarbon group as Ra′¹⁴ include a linear or branched alkyl group and a cyclic hydrocarbon group.

The linear alkyl group as Ra′¹⁴ has preferably 1 to 5 carbon atoms, more preferably 1 to 4 carbon atoms, and still more preferably 1 or 2 carbon atoms. Specific examples thereof include a methyl group, an ethyl group, an n-propyl group, an n-butyl group, and an n-pentyl group. Among these, a methyl group, an ethyl group, or an n-butyl group is preferable, and a methyl group or an ethyl group is more preferable.

The branched alkyl group as Ra′¹⁴ has preferably 3 to 10 carbon atoms and more preferably 3 to 5 carbon atoms. Specific examples thereof include an isopropyl group, an isobutyl group, a tert-butyl group, an isopentyl group, a neopentyl group, a 1,1-diethylpropyl group, and a 2,2-dimethylbutyl group. Among these, an isopropyl group is preferable.

In a case where Ra′¹⁴ represents a cyclic hydrocarbon group, the cyclic hydrocarbon group may be an aliphatic hydrocarbon group or an aromatic hydrocarbon group and may be a polycyclic group or a monocyclic group.

The aliphatic hydrocarbon group which is a monocyclic group is preferably a group in which one hydrogen atom has been removed from a monocycloalkane. The monocycloalkane has preferably 3 to 6 carbon atoms, and specific examples thereof include cyclopentane and cyclohexane.

The aliphatic hydrocarbon group which is a polycyclic group is preferably a group in which one hydrogen atom has been removed from a polycycloalkane. The polycycloalkane is preferably a group having 7 to 12 carbon atoms, and specific examples of thereof include adamantane, norbornane, isobornane, tricyclodecane, and tetracyclododecane.

Examples of the aromatic hydrocarbon group as Ra′¹⁴ include the same group as the aromatic hydrocarbon group as Ra¹⁰⁴. Among them, Ra′¹⁴ is preferably a group in which one or more hydrogen atoms have been removed from an aromatic hydrocarbon ring having 6 to 15 carbon atoms, more preferably a group in which one or more hydrogen atoms have been removed from benzene, naphthalene, anthracene, or phenanthrene, still more preferably a group in which one or more hydrogen atoms have been removed from benzene, naphthalene, or anthracene, particularly preferably a group in which one or more hydrogen atoms have been removed from naphthalene or anthracene, and most preferably a group in which one or more hydrogen atoms have been removed from naphthalene.

Example of the substituent which Ra′¹⁴ may have include the same substituents as those which Ra¹⁰⁴ may have.

In a case where Ra′¹⁴ in Formula (a1-r2-4) is a naphthyl group, the position at which the tertiary carbon atom in Formula (a1-r2-4) is bonded may be any one of the 1-position and the 2-position of the naphthyl group.

In a case where Ra′¹⁴ in Formula (a1-r2-4) is an anthryl group, the position at which the tertiary carbon atom in Formula (a1-r2-4) is bonded may be any one of the 1-position, the 2-position, and the 9-position of the anthryl group.

Specific examples of the group represented by Formula (a1-r2-1) are as follows.

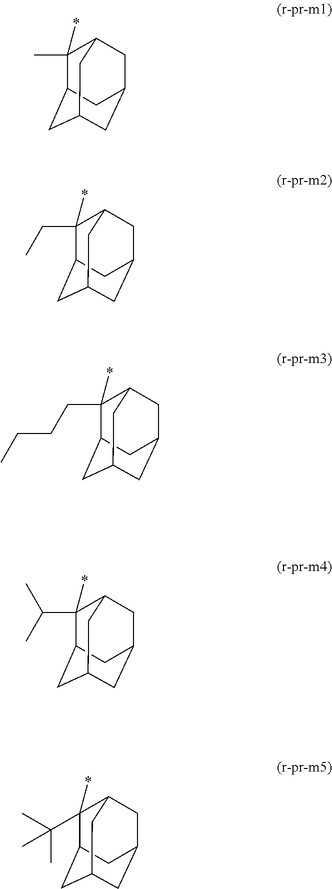 [SMILES: *C1(C)C2CC3CC(C2)CC1C3 ; *C1(CC)C2CC3CC(C2)CC1C3 ; *C1(CCCC)C2CC3CC(C2)CC1C3 ; *C1(C(C)C)C2CC3CC(C2)CC1C3 ; *C1(C(C)(C)C)C2CC3CC(C2)CC1C3]

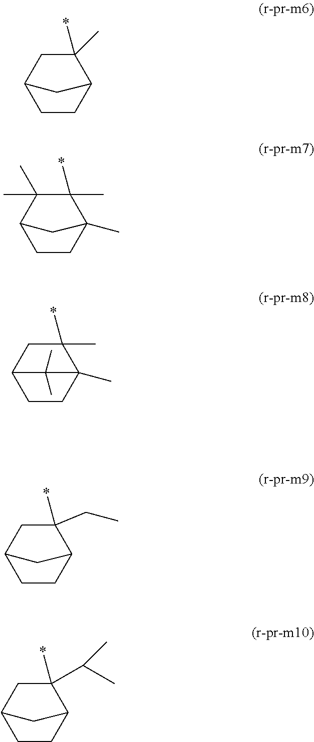

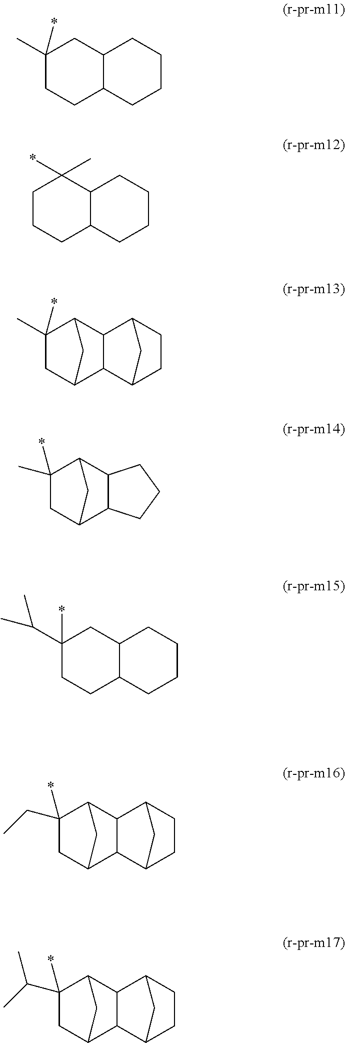

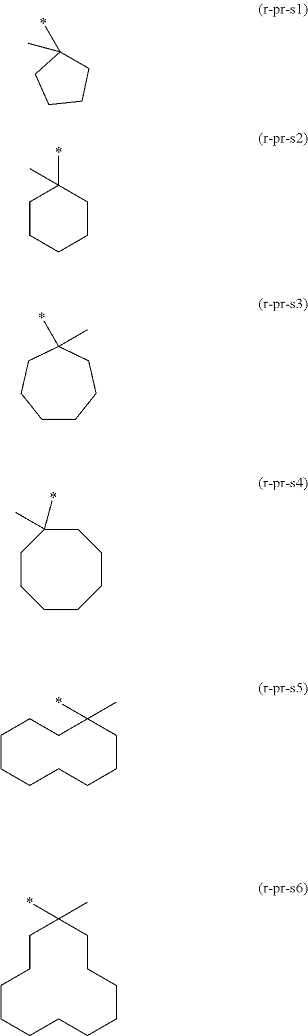

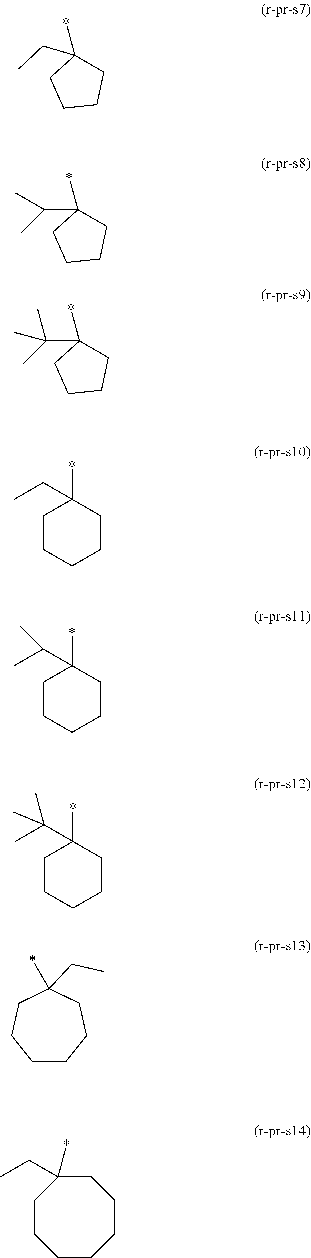

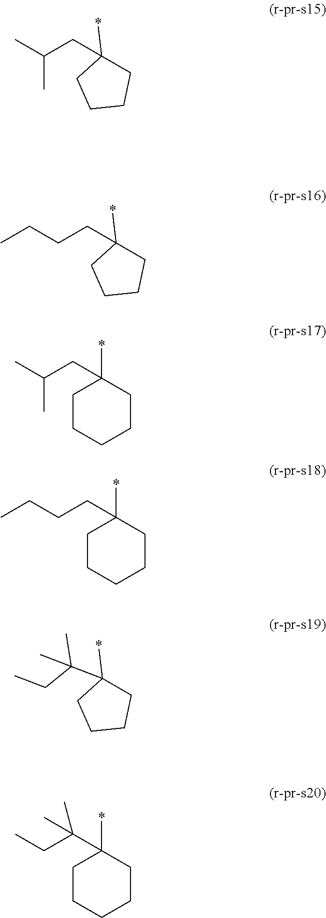

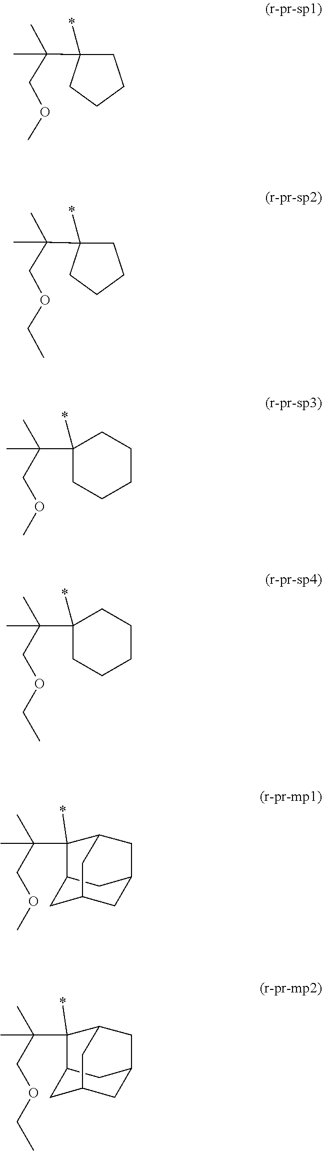 [SMILES: *C1(C(C)(C)COC)CCCC1 ; *C1(C(C)(C)COCC)CCCC1 ; *C1(C(C)(C)COC)CCCCC1 ; *C1(C(C)(C)COCC)CCCCC1 ; *C1(C(C)(C)COC)C2CC3CC(C2)CC1C3 ; *C1(C(C)(C)COCC)C2CC3CC(C2)CC1C3]

Specific examples of the group represented by Formula (a1-r2-2) are as follows.

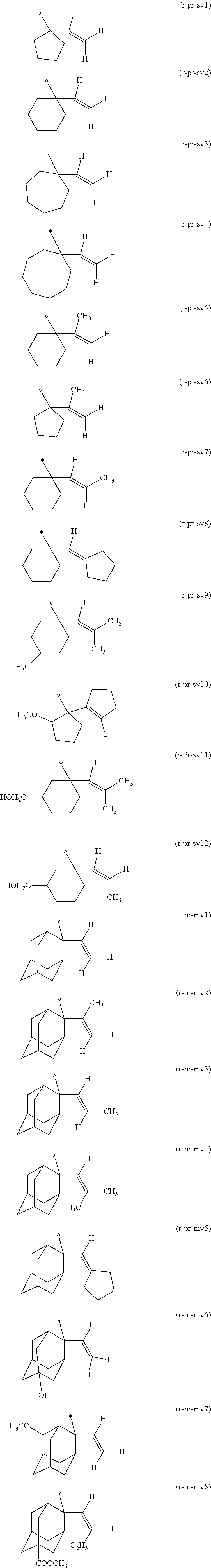

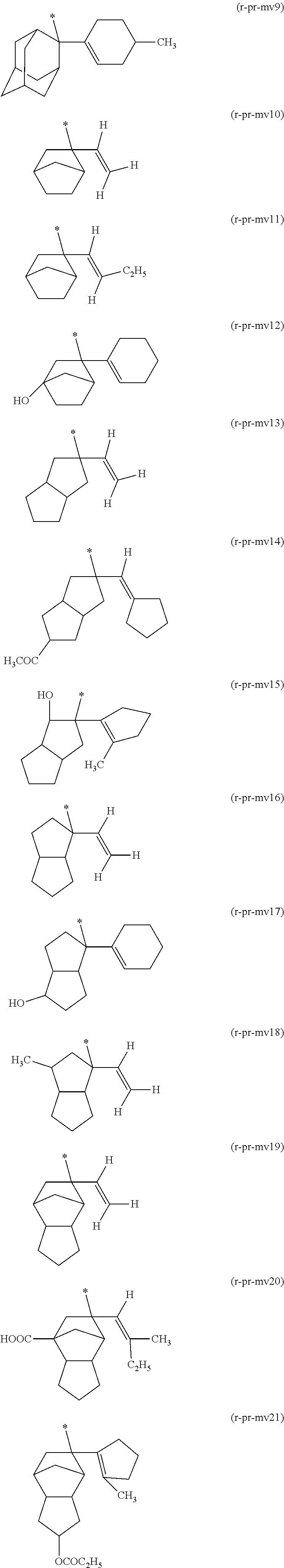

Specific examples of the group represented by Formula (a1-r2-3) are as follows.

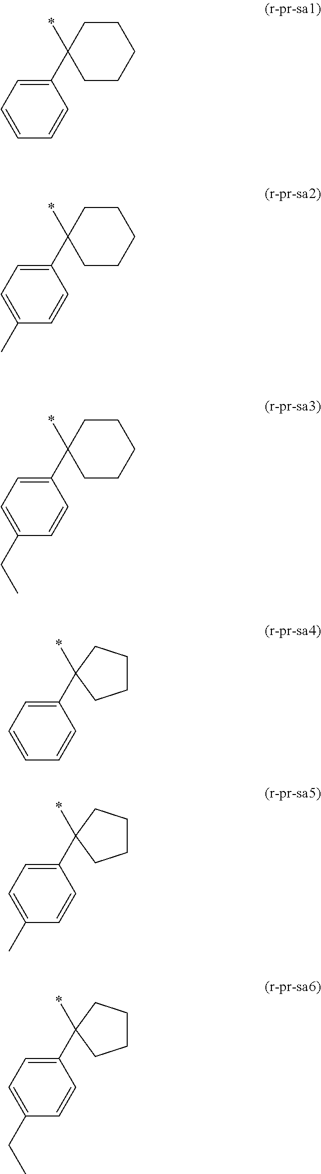 [SMILES: *C1(c2ccccc2)CCCCC1 ; *C1(c2ccc(C)cc2)CCCCC1 ; *C1(c2ccc(CC)cc2)CCCCC1 ; *C1(c2ccccc2)CCCC1 ; *C1(c2ccc(C)cc2)CCCC1 ; *C1(c2ccc(CC)cc2)CCCC1]

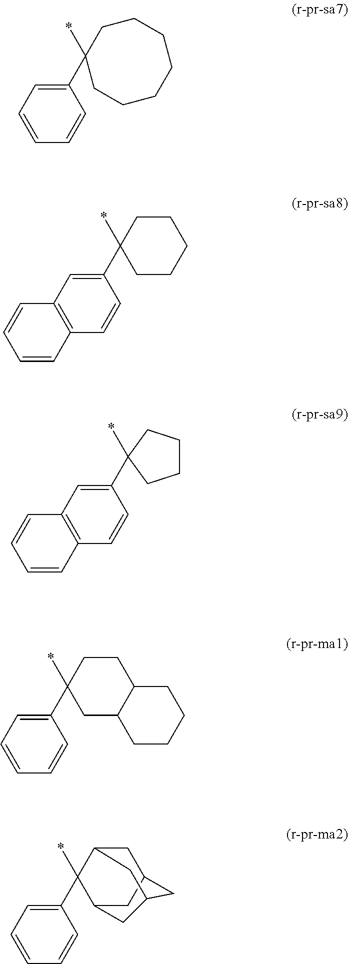 [SMILES: *C1(c2ccccc2)CCCCCCC1 ; *C1(c2ccc3ccccc3c2)CCCCC1 ; *C1(c2ccc3ccccc3c2)CCCC1 ; *C1(c2ccccc2)CCC2CCCCC2C1 ; *C1(c2ccccc2)C2CC3CC(C2)CC1C3]

Specific examples of the group represented by Formula (a1-r-2-4) are as follows.

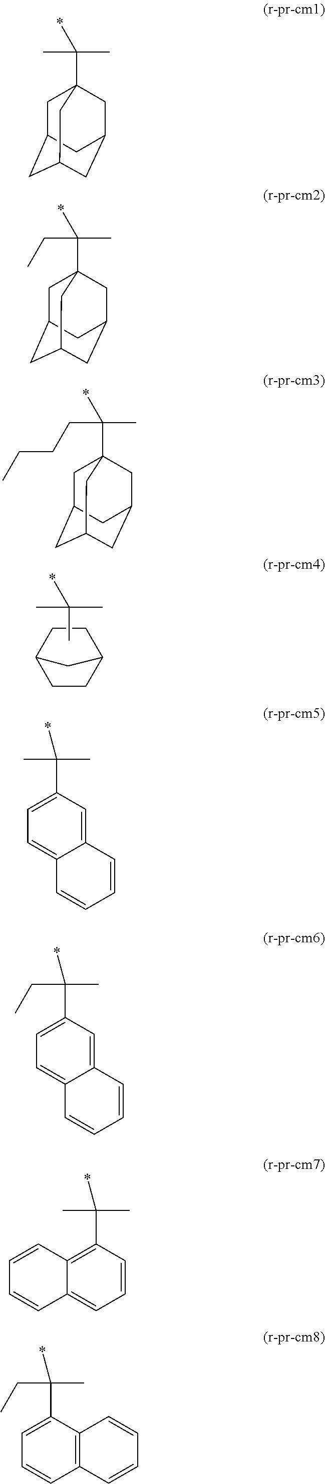

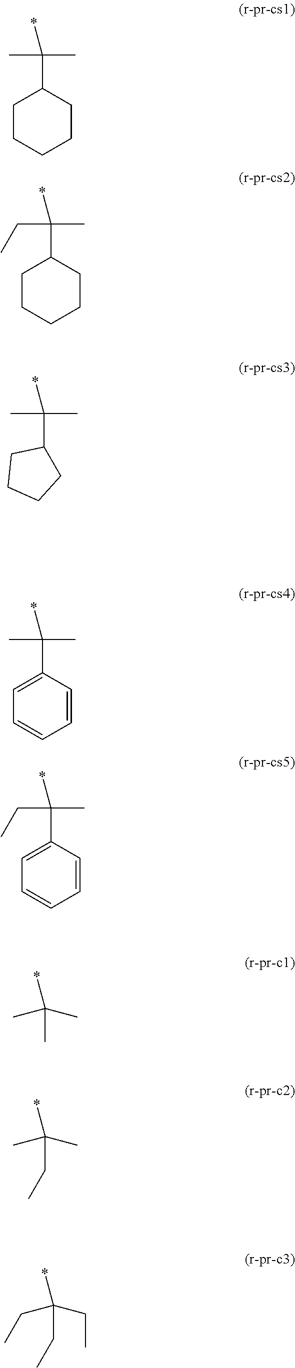

Tertiary Alkyloxycarbonyl-Type Acid Dissociable Group:

Examples of the acid dissociable group for protecting a hydroxy group as a polar group include acid dissociable groups (hereinafter, for convenience, also referred to as “tertiary alkyloxycarbonyl-type acid dissociable group”) represented by General Formula (a1-r-3).

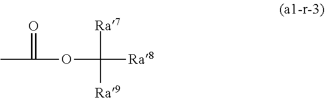

[In the formula, Ra′⁷ to Ra′⁹ each represent an alkyl group.]

In Formula (a1-r-3), Ra′⁷ to Ra′⁹ each independently represent preferably an alkyl group having 1 to 5 carbon atoms and more preferably an alkyl group having 1 to 3 carbon atoms.

Further, the total number of carbon atoms in each alkyl group is preferably 3 to 7, more preferably 3 to 5, and most preferably 3 or 4.

Examples of the constitutional unit (a1) include: a constitutional unit derived from acrylic acid ester in which the hydrogen atom bonded to the carbon atom at the α-position may be substituted with a substituent; a constitutional unit derived from acrylamide; a constitutional unit in which at least a part of hydrogen atoms from a hydroxy group of a constitutional unit derived from hydroxystyrene or a hydroxystyrene derivative are protected by the substituent including an acid decomposable group; and a constitutional unit in which at least a part of hydrogen atoms from —C(═O)—OH of a constitutional unit derived from vinylbenzoic acid or a vinylbenzoic acid derivative are protected by the substituent including an acid decomposable group.

Among the above, the constitutional unit (a1) is preferably a constitutional unit derived from the acrylic acid ester in which the hydrogen atom bonded to the carbon atom at the α-position may be substituted with a substituent. Preferred specific examples of such a constitutional unit (a1) include constitutional units represented by General Formula (a1-1) or (a1-2).

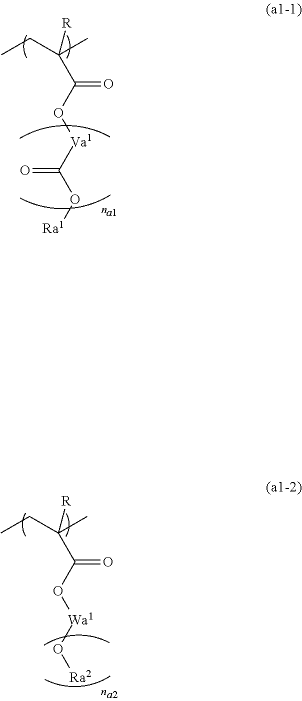

[In the formula, R represents a hydrogen atom, an alkyl group having 1 to 5 carbon atoms, or a halogenated alkyl group having 1 to 5 carbon atoms. Va¹ represents a divalent hydrocarbon group which may have an ether bond. nₐ₁ represents an integer of 0 to 2. Ra¹ represents an acid dissociable group represented by General Formula (a1-r-1) or (a1-r-2). Wa¹ represents a (nₐ₂+1)-valent hydrocarbon group, nₐ₂ represents an integer of 1 to 3, and Ra² represents an acid dissociable group represented by General Formula (a1-r-1) or (a1-r-3).]

In Formula (a1-1), the alkyl group having 1 to 5 carbon atoms as R is preferably a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group. The halogenated alkyl group having 1 to 5 carbon atoms is a group in which a part or all hydrogen atoms in the alkyl group having 1 to 5 carbon atoms have been substituted with halogen atoms. The halogen atom is particularly preferably a fluorine atom.

R is preferably a hydrogen atom, an alkyl group having 1 to 5 carbon atoms, or a fluorinated alkyl group having 1 to 5 carbon atoms, and most preferably a hydrogen atom or a methyl group in terms of industrial availability.

In Formula (a1-1), the divalent hydrocarbon group as Va¹ may be an aliphatic hydrocarbon group or an aromatic hydrocarbon group.

The aliphatic hydrocarbon group as the divalent hydrocarbon group represented by Va¹ may be saturated or unsaturated. In general, the aliphatic hydrocarbon group is preferably saturated.

More specific examples of the aliphatic hydrocarbon group include a linear or branched aliphatic hydrocarbon group and an aliphatic hydrocarbon group containing a ring in the structure thereof.

The linear aliphatic hydrocarbon group described above has preferably 1 to 10 carbon atoms, more preferably 1 to 6 carbon atoms, still more preferably 1 to 4 carbon atoms, and most preferably 1 to 3 carbon atoms. The linear aliphatic hydrocarbon group is preferably a linear alkylene group, and specific examples thereof include a methylene group [—CH₂—], an ethylene group [—(CH₂)₂-], a trimethylene group [—(CH₂)₃-], a tetramethylene group [—(CH₂)₄-], and a pentamethylene group [—(CH₂)₅-].

The branched aliphatic hydrocarbon group described above has preferably 2 to 10 carbon atoms, more preferably 3 to 6 carbon atoms, still more preferably 3 or 4 carbon atoms, and most preferably 3 carbon atoms. The branched aliphatic hydrocarbon group is preferably a branched alkylene group, and specific examples thereof include alkylalkylene groups; for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. The alkyl group in the alkylalkylene group is preferably a linear alkyl group having 1 to 5 carbon atoms.

Examples of the aliphatic hydrocarbon group containing a ring in the structure thereof include an alicyclic hydrocarbon group (a group in which two hydrogen atoms have been removed from an aliphatic hydrocarbon ring), a group in which the alicyclic hydrocarbon group is bonded to the terminal of the above-described linear or branched aliphatic hydrocarbon group, and a group in which the alicyclic hydrocarbon group is interposed in the above-described linear or branched aliphatic hydrocarbon group. Examples of the above-described linear or branched aliphatic hydrocarbon group include the same group as the above-described linear aliphatic hydrocarbon group or above-described branched aliphatic hydrocarbon group.

The alicyclic hydrocarbon group has preferably 3 to 20 carbon atoms and more preferably 3 to 12 carbon atoms.

The alicyclic hydrocarbon group may be monocyclic or polycyclic. The monocyclic alicyclic hydrocarbon group is preferably a group in which two hydrogen atoms have been removed from a monocycloalkane. The monocycloalkane has preferably 3 to 6 carbon atoms, and specific examples thereof include cyclopentane, and cyclohexane. The polycyclic alicyclic hydrocarbon group is preferably a group in which two hydrogen atoms have been removed from a polycycloalkane. The polycycloalkane is preferably a group having 7 to 12 carbon atoms, and specific examples thereof include adamantane, norbornane, isobornane, tricyclodecane, and tetracyclododecane.

The aromatic hydrocarbon group as the divalent hydrocarbon group represented by Va¹ is a hydrocarbon group having an aromatic ring.

The aromatic hydrocarbon group has preferably 3 to 30 carbon atoms, more preferably 5 to 30 carbon atoms, still more preferably 5 to 20 carbon atoms, particularly preferably 6 to 15 carbon atoms, and most preferably 6 to 12 carbon atoms. However, the number of carbon atoms in a substituent is not included in the number of carbon atoms. Specific examples of the aromatic ring which the aromatic hydrocarbon group has include: aromatic hydrocarbon rings such as benzene, biphenyl, fluorene, naphthalene, anthracene, and phenanthrene; and aromatic hetero rings in which a part of carbon atoms constituting the above-described aromatic hydrocarbon rings have been substituted with hetero atoms. Examples of the hetero atom in the aromatic hetero rings include an oxygen atom, a sulfur atom, and a nitrogen atom.

Specific examples of the aromatic hydrocarbon group include: a group in which two hydrogen atoms have been removed from the above-described aromatic hydrocarbon ring (an arylene group); and a group in which one hydrogen atom of a group (an aryl group) formed by removing one hydrogen atom from the aromatic hydrocarbon ring has been substituted with an alkylene group (for example, a group formed by further removing one hydrogen atom from an aryl group of an arylalkyl group such as a benzyl group, a phenethyl group, a 1-naphthylmethyl group, a 2-naphthylmethyl group, a 1-naphthylethyl group, or a 2-naphthylethyl group). The alkylene group (an alkyl chain in the arylalkyl group) has preferably 1 to 4 carbon atoms, more preferably 1 or 2 carbon atoms, and particularly preferably 1 carbon atom.

In Formula (a1-1), Ra¹ is an acid dissociable group represented by Formula (a1-r-1) or (a1-r-2).

In Formula (a1-2), the (nₐ₂₊₁)-valent hydrocarbon group as Wa¹ may be an aliphatic hydrocarbon group or an aromatic hydrocarbon group. The aliphatic hydrocarbon group indicates a hydrocarbon group that has no aromaticity and may be saturated or unsaturated. In general, it is preferable that the aliphatic hydrocarbon group is saturated. Examples of the aliphatic hydrocarbon group include a linear or branched aliphatic hydrocarbon group, an aliphatic hydrocarbon group containing a ring in the structure thereof, and a combination of the linear or branched aliphatic hydrocarbon group and the aliphatic hydrocarbon group containing a ring in the structure thereof. The valency of nₐ₂+1 is preferably divalent, trivalent, or tetravalent, and is more preferably divalent or trivalent.

In Formula (a1-2), Ra² is an acid dissociable group represented by General Formula (a1-r-1) or (a1-r-3).

Specific examples of the constitutional unit represented by Formula (a1-1) are as follows. In the following formulae, Ra represents a hydrogen atom, a methyl group, or a trifluoromethyl group.

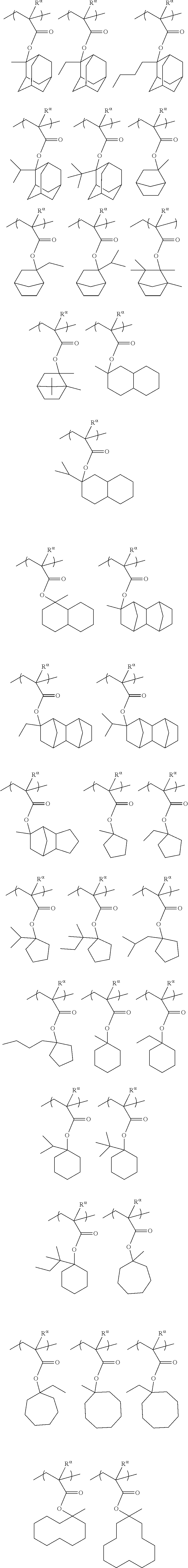

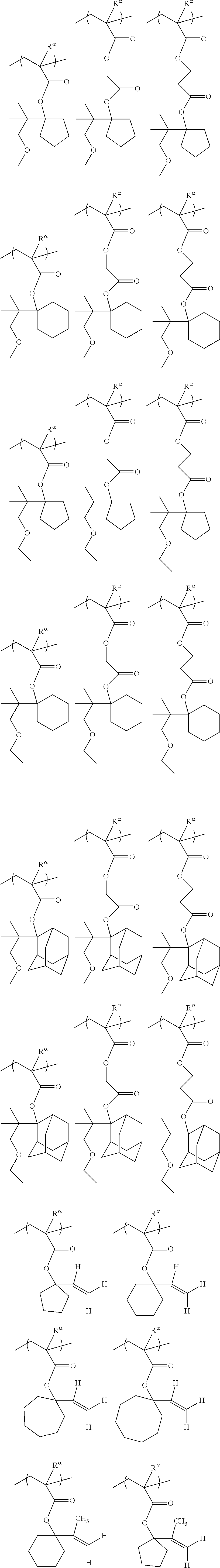

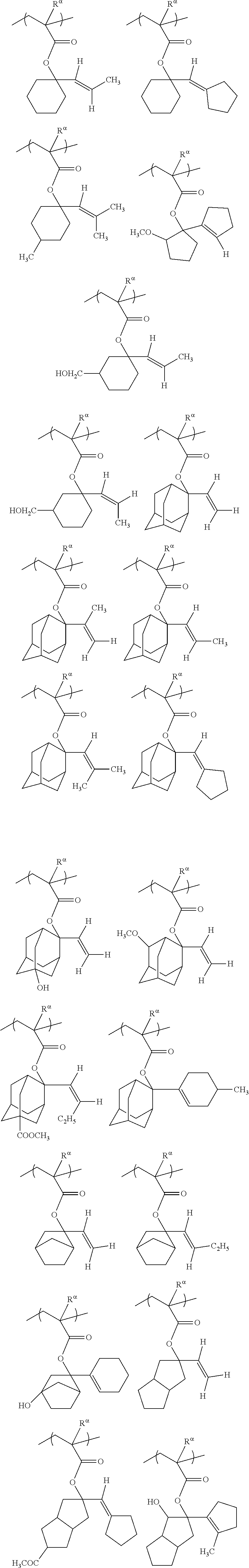

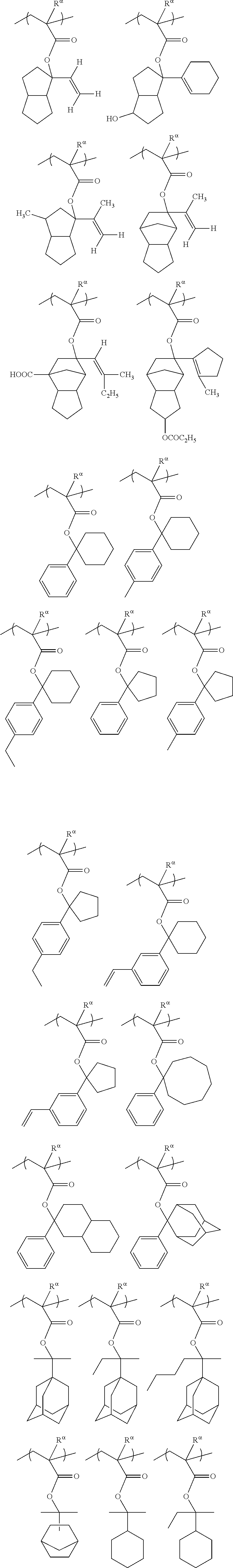

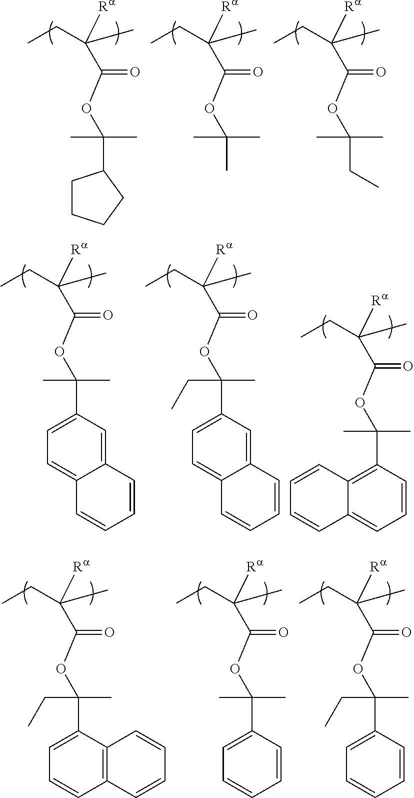

The constitutional unit (a1) which the component (A1) has may be one kind or may be two or more kinds.

The constitutional unit (a1) is more preferably a constitutional unit represented by Formula (a1-1) since lithography characteristics (sensitivity, shape, and the like) in lithography with electron beams or EUV rays can be more easily increased.

Among these, the constitutional unit (a1) particularly preferably includes a constitutional unit represented by General Formula (a1-1-1).

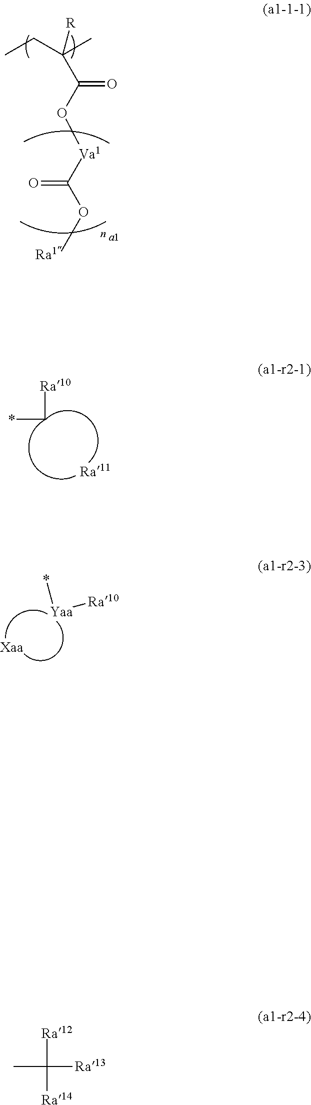

[In Formula, Ra¹″ represents an acid dissociable group represented by General Formula (a1-r2-1), (a1-r2-3), or (a1-r2-4.]

[In Formula (a1-1-1), R, Va¹, and nₐ₁ are respectively the same as R, Va¹, and nₐ₁ in Formula (a1-1).

The description for the acid dissociable group represented by General Formula (a1-r2-1), (a1-r2-3), or (a1-r2-4) is as described above. Among them, an acid dissociable group represented by General Formula (a1-r2-1) or (a1-r2-3) is preferable, and it is more preferable to select a group in which the acid dissociable group is a cyclic group, due to that fact that the reactivity can be increased, which is suitable for EB or EUV.

In Formula (a1-1-1), Ra¹″ is preferably, among the above, an acid dissociable group represented by General Formula (a1-r2-1).

The proportion of the constitutional unit (a1) in the component (A1) is preferably 5% to 80% by mole, more preferably 10% to 75% by mole, still more preferably 30% to 70% by mole, and particularly preferably 40% to 60% by mole, with respect to the total amount (100% by mole) of all constitutional units constituting the component (A1).

In a case where the proportion of the constitutional unit (a1) is set within the preferred range described above, the efficiency of the deprotection reaction and the solubility of the developing solution can be appropriately ensured, and thus the effects of the present invention can be more easily obtained.

<<Other Constitutional Units>>

The component (A1) may have other constitutional units as necessary in addition to the constitutional unit (a1) described above.

Examples of the other constitutional units include: a constitutional unit (a0) represented by General Formula (a10-1) described later; a constitutional unit (a2) containing a lactone-containing cyclic group, a —SO₂-containing cyclic group, or a carbonate-containing cyclic group; a constitutional unit (a3) containing a polar group-containing aliphatic hydrocarbon group; a constitutional unit (a4) containing an acid non-dissociable aliphatic cyclic group; and a constitutional unit (st) derived from styrene or a derivative thereof.

In regard to constitutional unit (a10):

The constitutional unit (a10) is a constitutional unit represented by General Formula (a10-1).

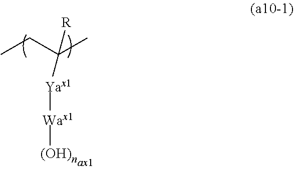

[In the formula, R represents a hydrogen atom, an alkyl group having 1 to 5 carbon atoms, or a halogenated alkyl group having 1 to 5 carbon atoms. Ya^{x1} represents a single bond or a divalent linking group. Wa^{x1} represents an aromatic hydrocarbon group which may have a substituent. nₐₓ₁ represents an integer of 1 or more.]

In Formula (a10-1), R represents a hydrogen atom, an alkyl group having 1 to 5 carbon atoms, or a halogenated alkyl group having 1 to 5 carbon atoms.

The alkyl group having 1 to 5 carbon atoms as R is preferably a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group.

The halogenated alkyl group having 1 to 5 carbon atoms as R is a group in which a part or all hydrogen atoms of the above-described alkyl group having 1 to 5 carbon atoms have been substituted with halogen atoms. The halogen atom is particularly preferably a fluorine atom.

R is preferably a hydrogen atom, an alkyl group having 1 to 5 carbon atoms, or a fluorinated alkyl group having 1 to 5 carbon atoms, more preferably a hydrogen atom, a methyl group, or trifluoromethyl group, still more preferably a hydrogen atom or a methyl group, and particularly preferably a methyl group, in terms of industrial availability.

In Formula (a10-1), Ya^{x1} represents a single bond or a divalent linking group.

In the chemical formulae described above, the divalent linking group as Ya^{x1} is not particularly limited, and examples thereof include, as a suitable linking group, a divalent hydrocarbon group which may have a substituent and a divalent linking group containing a hetero atom.

Divalent Hydrocarbon Group which May have Substituent:

In a case where Ya^{x1} represents a divalent hydrocarbon group which may have a substituent, the hydrocarbon group may be an aliphatic hydrocarbon group or an aromatic hydrocarbon group.

Aliphatic Hydrocarbon Group as Ya^{x1}

The aliphatic hydrocarbon group indicates a hydrocarbon group that has no aromaticity. The aliphatic hydrocarbon group may be saturated or unsaturated. In general, the aliphatic hydrocarbon group is preferably saturated. Examples of the aliphatic hydrocarbon group include a linear or branched aliphatic hydrocarbon group, and an aliphatic hydrocarbon group containing a ring in the structure thereof.

Linear or Branched Aliphatic Hydrocarbon Group

The linear aliphatic hydrocarbon group has preferably 1 to 10 carbon atoms, more preferably 1 to 6 carbon atoms, still more preferably 1 to 4 carbon atoms, and most preferably 1 to 3 carbon atoms.

The linear aliphatic hydrocarbon group is preferably a linear alkylene group, and specific examples thereof include a methylene group [—CH₂—], an ethylene group [—(CH₂)₂—], a trimethylene group [—(CH₂)₃-], a tetramethylene group [—(CH₂)₄-], and a pentamethylene group [—(CH₂)₅-].

The branched aliphatic hydrocarbon group has preferably 2 to 10 carbon atoms, more preferably 3 to 6 carbon atoms, still more preferably 3 or 4 carbon atoms, and most preferably 3 carbon atoms.

The branched aliphatic hydrocarbon group is preferably a branched alkylene group, and specific examples thereof include alkylalkylene groups; for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. The alkyl group in the alkylalkylene group is preferably a linear alkyl group having 1 to 5 carbon atoms.

The linear or branched aliphatic hydrocarbon group may or may not have a substituent. Examples of the substituent include a fluorine atom, a fluorinated alkyl group having 1 to 5 carbon atoms, which has been substituted with a fluorine atom, and a carbonyl group.

Aliphatic Hydrocarbon Group Containing Ring in Structure Thereof

Examples of the aliphatic hydrocarbon group containing a ring in the structure thereof include a cyclic aliphatic hydrocarbon group which may have a substituent containing a hetero atom in the ring structure thereof (a group in which two hydrogen atoms have been removed from an aliphatic hydrocarbon ring), a group in which the cyclic aliphatic hydrocarbon group is bonded to the terminal of a linear or branched aliphatic hydrocarbon group, and a group in which the cyclic aliphatic hydrocarbon group is interposed in a linear or branched aliphatic hydrocarbon group. Examples of the linear or branched aliphatic hydrocarbon group include the same groups as those described above.

The cyclic aliphatic hydrocarbon group has preferably 3 to 20 carbon atoms and more preferably 3 to 12 carbon atoms.

The cyclic aliphatic hydrocarbon group may be a polycyclic group or a monocyclic group. The monocyclic alicyclic hydrocarbon group is preferably a group in which two hydrogen atoms have been removed from a monocycloalkane. The monocycloalkane has preferably 3 to 6 carbon atoms, and specific examples thereof include cyclopentane and cyclohexane. The polycyclic alicyclic hydrocarbon group is preferably a group in which two hydrogen atoms have been removed from a polycycloalkane. The polycycloalkane is preferably a group having 7 to 12 carbon atoms, and specific examples of the polycycloalkane include adamantane, norbornane, isobornane, tricyclodecane, and tetracyclododecane.

The cyclic aliphatic hydrocarbon group may or may not have a substituent. Examples of the substituent include an alkyl group, an alkoxy group, a halogen atom, a halogenated alkyl group, a hydroxy group, and a carbonyl group.

The alkyl group as the substituent is preferably an alkyl group having 1 to 5 carbon atoms, and more preferably a methyl group, an ethyl group, a propyl group, an n-butyl group, or a tert-butyl group.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and still more preferably a methoxy group or an ethoxy group.

The halogen atom as the substituent is preferably a fluorine atom.

Examples of the halogenated alkyl group as the substituent include groups in which a part or all hydrogen atoms in the above-described alkyl groups have been substituted with the above-described halogen atoms.

In the cyclic aliphatic hydrocarbon group, a part of carbon atoms constituting the ring structure thereof may be substituted with a substituent containing a hetero atom. The substituent containing a hetero atom is preferably —O—, —C(═O)—O—, —S—, —S(═O)₂—, or —S(═O)₂—O—.

Aromatic Hydrocarbon Group as Ya^{x1}

The aromatic hydrocarbon group is a hydrocarbon group having at least one aromatic ring.

The aromatic ring is not particularly limited as long as it is a cyclic conjugated system having (4n+2) π electrons, and may be monocyclic or polycyclic. The aromatic ring has preferably 5 to 30 carbon atoms, more preferably 5 to 20 carbon atoms, still more preferably 6 to 15 carbon atoms, and particularly preferably 6 to 12 carbon atoms. However, the number of carbon atoms in a substituent is not included in the number of carbon atoms.

Specific examples of the aromatic ring include: aromatic hydrocarbon rings such as benzene, naphthalene, anthracene, and phenanthrene; and aromatic hetero rings in which a part of carbon atoms constituting the above-described aromatic hydrocarbon rings have been substituted with hetero atoms. Examples of the hetero atom in the aromatic hetero rings include an oxygen atom, a sulfur atom, and a nitrogen atom. Specific examples of the aromatic hetero ring include a pyridine ring and a thiophene ring.

Specific examples of the aromatic hydrocarbon group include a group in which two hydrogen atoms have been removed from the above-described aromatic hydrocarbon ring or aromatic hetero ring (an arylene group or a heteroarylene group); a group in which two hydrogen atoms have been removed from an aromatic compound having two or more aromatic rings (such as biphenyl or fluorene); and a group in which one hydrogen atom of a group (an aryl group or a heteroaryl group) obtained by removing one hydrogen atom from the above-described aromatic hydrocarbon ring or aromatic hetero ring has been substituted with an alkylene group (for example, a group obtained by further removing one hydrogen atom from an aryl group in an arylalkyl group such as a benzyl group, a phenethyl group, a 1-naphthylmethyl group, a 2-naphthylmethyl group, a 1-naphthylethyl group, or a 2-naphthylethyl group). The alkylene group bonded to the aryl group or the heteroaryl group has preferably 1 to 4 carbon atoms, more preferably 1 or 2 carbon atoms, and particularly preferably 1 carbon atom.

With respect to the aromatic hydrocarbon group, the hydrogen atom that the aromatic hydrocarbon group has may be substituted with a substituent. For example, the hydrogen atom bonded to the aromatic ring in the aromatic hydrocarbon group may be substituted with a substituent. Examples of substituents include an alkyl group, an alkoxy group, a halogen atom, a halogenated alkyl group, and a hydroxy group.

The alkyl group as the substituent is preferably an alkyl group having 1 to 5 carbon atoms, and more preferably a methyl group, an ethyl group, a propyl group, an n-butyl group, or a tert-butyl group.

Examples of the alkoxy group, the halogen atom, and the halogenated alkyl group, as the substituent, include those exemplified as the substituent that is substituted for a hydrogen atom that the cyclic aliphatic hydrocarbon group has.

Divalent Linking Group Containing Hetero Atom

In a case where Ya^{x1} represents a divalent linking group containing a hetero atom, preferred examples of the linking group include —O—, —C(═O)—O—, —O—C(═O)—, —C(═O)—, —O—C(═O)—O— —C(═O)—NH—, —NH—, —NH—C(═NH)— (H may be substituted with a substituent such as an alkyl group, an acyl group, or the like), —S—, —S(═O)₂—, —S(═O)₂—O—, and a group represented by General Formula; —Y²¹—O—Y²², —Y²¹—O—, —Y²¹—C(═O)—O—, —C(═O)—O—Y²¹—, —[Y²¹—C(═O)—O]_{m″}—Y²², —Y²¹—O—C(═O)—Y²²— or —Y²¹—S(═O)₂—O—Y²²— [in the formulae, Y²¹ and Y²² each independently represent a divalent hydrocarbon group which may have a substituent, O represents an oxygen atom, and m″ represents an integer of 0 to 3].

In a case where the divalent linking group containing a hetero atom described above is —C(═O)—NH—, —C(═O)—NH—C(═O)—, —NH—, or —NH—C(═NH)—, H in these group may be substituted with a substituent such as an alkyl group, and an acyl group. The substituent (an alkyl group, an acyl group, or the like) has preferably 1 to 10 carbon atoms, more preferably 1 to 8 carbon atoms, and particularly preferably 1 to 5 carbon atoms.

In General Formula —Y²¹—O—Y²²—, —Y²¹—O—, —Y²¹—C(═O)—O—, —C(═O)—O—Y²¹—, —[Y²¹—C(═O)—O]_{m″}—Y²², —Y²¹—O—C(═O)—Y²²—, or —Y²¹—S(═O)₂—O—Y²²—, Y²¹ and Y²² each independently represent a divalent hydrocarbon group which may have a substituent. Examples of the divalent hydrocarbon group include the same groups as those (divalent hydrocarbon groups which may have a substituent) mentioned in the description of the above-described divalent linking group as Ya^{x1}.

Y²¹ is preferably a linear aliphatic hydrocarbon group, more preferably a linear alkylene group, still more preferably a linear alkylene group having 1 to 5 carbon atoms, and particularly preferably a methylene group or an ethylene group.

Y²² is preferably a linear or branched aliphatic hydrocarbon group and more preferably a methylene group, an ethylene group, or an alkylmethylene group. The alkyl group in the alkylmethylene group is preferably a linear alkyl group having 1 to 5 carbon atoms, more preferably a linear alkyl group having 1 to 3 carbon atoms, and most preferably a methyl group.

In the group represented by Formula —[Y²¹—C(═O)—O]ₘ″—Y²²—, m″ represents an integer of 0 to 3, preferably an integer of 0 to 2, more preferably 0 or 1, and particularly preferably 1. In other words, the group represented by Formula —[Y²¹—C(═O)—O]ₘ″-Y²²— is particularly preferably a group represented by Formula —Y²¹—C(═O)—O—Y²²—. Among them, a group represented by Formula —(CH₂)_{a′}—C(═O)—O—(CH₂)_{b′}— is preferable. In the formula, a′ represents an integer of 1 to 10, preferably an integer of 1 to 8, more preferably an integer of 1 to 5, still more preferably 1 or 2, and most preferably 1. b′ represents an integer of 1 to 10, preferably an integer of 1 to 8, more preferably an integer of 1 to 5, still more preferably 1 or 2, and most preferably 1.

Among the above, Ya^{x1} is preferably a single bond, an ester bond [—C(═O)—O—, —O—C(═O)—], an ether bond (—O—), a linear or branched alkylene group, or a combination thereof, and more preferably a single bond or an ester bond [—C(═O)—O—, —O—C(═O)—].

In Formula (a10-1), Wa^{x1} represents an aromatic hydrocarbon group which may have a substituent.

Examples of the aromatic hydrocarbon group as Wa^{x1} include groups in which (nₐₓ₁+1) hydrogen atoms have been removed from an aromatic ring which may have a substituent. The aromatic ring is not particularly limited as long as it is a cyclic conjugated system having (4n+2) π electrons and may be monocyclic or polycyclic. The aromatic ring has preferably 5 to 30 carbon atoms, more preferably 5 to 20 carbon atoms, still more preferably 6 to 15 carbon atoms, and particularly preferably 6 to 12 carbon atoms. Specific examples of the aromatic ring include aromatic hydrocarbon rings such as benzene, naphthalene, anthracene, and phenanthrene; and aromatic hetero rings in which a part of carbon atoms constituting the above-described aromatic hydrocarbon rings have been substituted with hetero atoms. Examples of the hetero atom in the aromatic hetero rings include an oxygen atom, a sulfur atom, and a nitrogen atom. Specific examples of the aromatic hetero ring include a pyridine ring and a thiophene ring.

Examples of the aromatic hydrocarbon group as Wa^{x1} also include groups in which (nₐₓ₁+1) hydrogen atoms have been removed from an aromatic compound (for example, biphenyl and fluorene) containing an aromatic ring which may have two or more substituents.

Among the above, Wa^{x1} is preferably a group in which (nₐₓ₁+1) hydrogen atoms have been removed from benzene, naphthalene, anthracene, or biphenyl, more preferably a group in which (nₐₓ₁+1) hydrogen atoms have been removed from benzene or naphthalene, and still more preferably a group in which (nₐₓ₁+1) hydrogen atoms have been removed from benzene.

The aromatic hydrocarbon group as Wa^{x1} may or may not have a substituent. Examples of the substituent include an alkyl group, an alkoxy group, a halogen atom, and a halogenated alkyl group. Examples of the alkyl group, the alkoxy group, the halogen atom, and the halogenated alkyl group, as the substituent, include the same groups as those described as the substituent for the cyclic aliphatic hydrocarbon group as Ya^{x1}. The substituent is preferably a linear or branched alkyl group having 1 to 5 carbon atoms, more preferably a linear or branched alkyl group having 1 to 3 carbon atoms, still more preferably an ethyl group or a methyl group, and particularly preferably a methyl group. The aromatic hydrocarbon group as Wa^{x1} preferably has no substituent.

In Formula (a10-1), nₐₓ₁ represents an integer of 1 or more, preferably an integer of 1 to 10, more preferably an integer of 1 to 5, still more preferably 1, 2, or 3, and particularly preferably 1 or 2.

Specific examples of the constitutional unit (a10) represented by Formula (a10-1) are as follows.

In the following formulae, R^{α} represents a hydrogen atom, a methyl group, or a trifluoromethyl group.

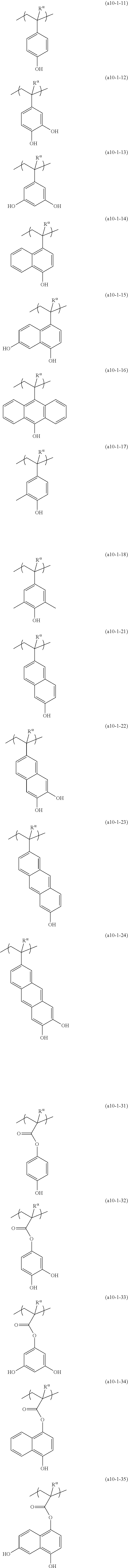

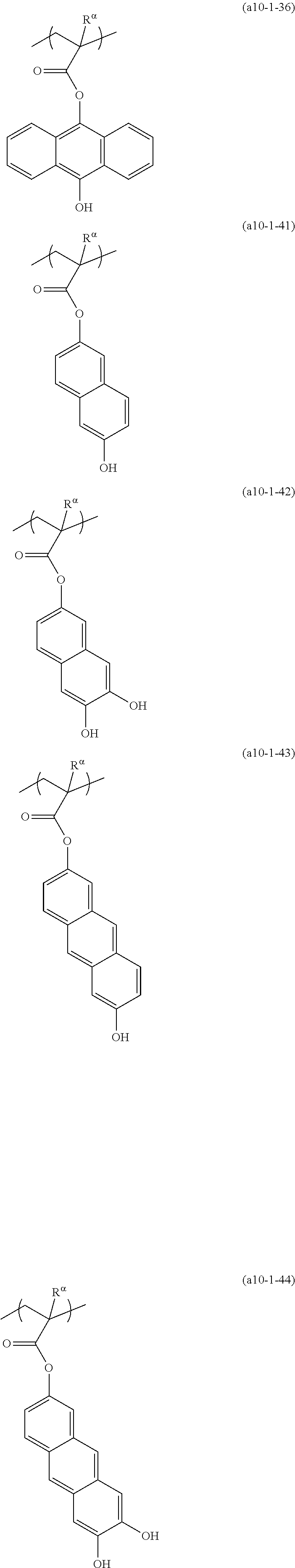

The constitutional unit (a10) which the component (A1) has may be one kind or may be two or more kinds.

In a case where the component (A1) has the constitutional unit (a10), the proportion of the constitutional unit (a10) in the component (A1) is preferably 5% to 80% by mole, more preferably 10% to 75% by mole, and still more preferably 30% to 70% by mole, and particularly preferably 40% to 60% by mole, with respect to the total amount (100% by mole) of all constitutional units constituting the component (A1).

In a case where the proportion of the constitutional unit (a10) is set within the preferred range described above, the efficiency of supplying protons in the resist film can be improved and the solubility of the developing solution can be appropriately ensured, and thus the effects of the present invention can be more easily obtained.

In Regard to Constitutional Unit (a2):

In addition to the constitutional unit (a1), the component (A1) may further have a constitutional unit (a2) (however, a constitutional unit corresponding to the constitutional unit (a1) is excluded) containing a lactone-containing cyclic group, a —SO₂— containing cyclic group, or a carbonate-containing cyclic group.

In a case where the component (A1) is used for forming a resist film, the lactone-containing cyclic group, the —SO₂— containing cyclic group, or the carbonate-containing cyclic group in the constitutional unit (a2) is effective for improving the adhesiveness of the resist film to the substrate. Further, due to having the constitutional unit (a2), lithography characteristics can be improved, for example, by the effects obtained by appropriately adjusting the acid diffusion length, increasing the adhesiveness of the resist film to the substrate, and appropriately adjusting the solubility during development.

The term “lactone-containing cyclic group” indicates a cyclic group that contains a ring (lactone ring) containing a —O—C(═O)— in the ring skeleton. In a case where the lactone ring is counted as the first ring and the group contains only the lactone ring, the group is referred to as the monocyclic group. Further, in a case where the group has other ring structures, the group is referred to as the polycyclic group regardless of the structures. The lactone-containing cyclic group may be a monocyclic group or a polycyclic group.

The lactone-containing cyclic group for the constitutional unit (a2) is not particularly limited, and any constitutional unit may be used. Specific examples thereof include groups respectively represented by General Formulae (a2-r-1) to (a2-r-7).

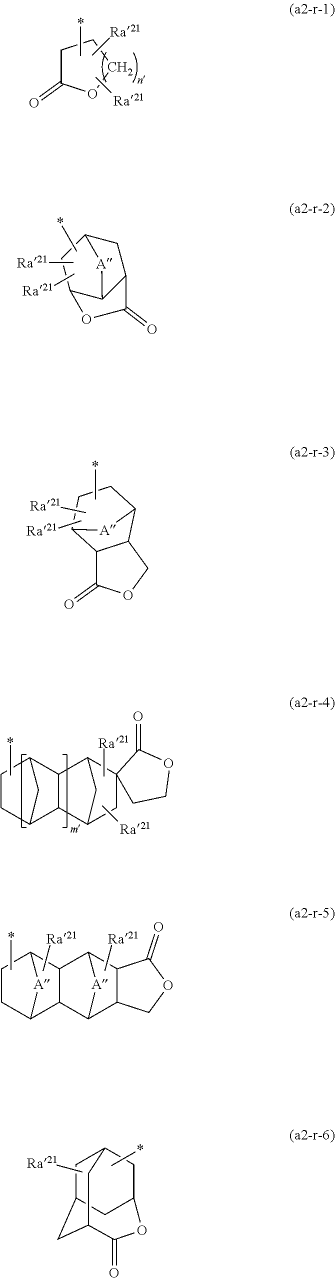

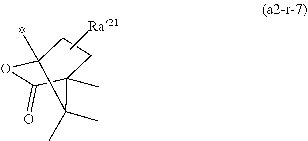

[In the formulae, each Ra′²¹ independently represent a hydrogen atom, an alkyl group, an alkoxy group, a halogen atom, a halogenated alkyl group, a hydroxy group, —COOR″, —OC(═O)R″, a hydroxyalkyl group, or a cyano group; R″ represents a hydrogen atom, an alkyl group, a lactone-containing cyclic group, a carbonate-containing cyclic group, or a —SO₂— containing cyclic group; A″ represents an oxygen atom, a sulfur atom, or an alkylene group having 1 to 5 carbon atoms, which may contain an oxygen atom (—O—) or a sulfur atom (—S—); and n′ represents an integer of 0 to 2, and m′ is 0 or 1.]

In General Formulae (a2-r-1) to (a2-r-7), the alkyl group as Ra′²¹ is preferably an alkyl group having 1 to 6 carbon atoms. The alkyl group is preferably a linear alkyl group or a branched alkyl group. Specific examples thereof include a methyl group, an ethyl group, a propyl group, an isopropyl group, an n-butyl group, an isobutyl group, a tert-butyl group, a pentyl group, an isopentyl group, a neopentyl group, and a hexyl group. Among these, a methyl group or ethyl group is preferable, and a methyl group is particularly preferable.

The alkoxy group as Ra′²¹ is preferably an alkoxy group having 1 to 6 carbon atoms. Further, the alkoxy group is preferably a linear or branched alkoxy group. Specific examples of the alkoxy group include groups formed by linking the above-described alkyl group mentioned as the alkyl group represented by Ra′²¹ to an oxygen atom (—O—).

The Halogen Atom as Ra′²¹ is Preferably a Fluorine Atom.

Examples of the halogenated alkyl group as Ra′²¹ include groups in which a part or all hydrogen atoms in the above-described alkyl group as Ra′²¹ have been substituted with the above-described halogen atoms. The halogenated alkyl group is preferably a fluorinated alkyl group and particularly preferably a perfluoroalkyl group.

In —COOR″ and —OC(═O)R″ as Ra′²¹, both R″'s represent a hydrogen atom, an alkyl group, a lactone-containing cyclic group, a carbonate-containing cyclic group, or a —SO₂— containing cyclic group.

The alkyl group as R″ may be linear, branched, or cyclic, and preferably has 1 to 15 carbon atoms.

In a case where R″ represents a linear or branched alkyl group, it is preferably an alkyl group having 1 to 10 carbon atoms, more preferably an alkyl group having 1 to 5 carbon atoms, and particularly preferably a methyl group or an ethyl group.

In a case where R″ represents a cyclic alkyl group, the number of carbon atoms thereof is preferably 3 to 15, more preferably 4 to 12, and most preferably 5 to 10. Specific examples thereof include: a group in which one or more hydrogen atoms have been removed from a monocycloalkane which may or may not be substituted with a fluorine atom or a fluorinated alkyl group; and a group in which one or more hydrogen atoms have been removed from polycycloalkanes such as a bicycloalkane, a tricycloalkane, and a tetracycloalkane. More specific examples thereof include: a group in which one or more hydrogen atoms have been removed from monocycloalkanes such as cyclopentane and cyclohexane; and a group in which one or more hydrogen atoms have been removed from polycycloalkanes such as adamantane, norbornane, isobornane, tricyclodecane, and tetracyclododecane.

Examples of the lactone-containing cyclic group as R″ include the same groups as those respectively represented by General Formulae (a2-r-1) to (a2-r-7).

The carbonate-containing cyclic group as R″ has the same definition as that for the carbonate-containing cyclic group described below. Specific examples of the carbonate-containing cyclic group include groups respectively represented by General Formulae (ax3-r-1) to (ax3-r-3).

The —SO₂— containing cyclic group as R″ has the same definition as that for the —SO₂— containing cyclic group described below. Specific examples of the —SO₂— containing cyclic group include groups respectively represented by General Formulae (a5-r-1) to (a5-r-4).

The hydroxyalkyl group as Ra′²¹ has preferably 1 to 6 carbon atoms, and specific examples thereof include groups in which at least one hydrogen atom in the alkyl group as Ra′²¹ has been substituted with a hydroxy group.

In General Formulae (a2-r-2), (a2-r-3), and (a2-r-5), as the alkylene group having 1 to 5 carbon atoms as A″, a linear or branched alkylene group is preferable, and examples thereof include a methylene group, an ethylene group, an n-propylene group, and an isopropylene group. Specific examples of the alkylene group that contains an oxygen atom or a sulfur atom include groups in which —O— or —S— is interposed in the terminal of the alkylene group or between the carbon atoms of the alkylene group, and examples thereof include —O—CH₂—, —CH₂—O—CH₂—, —S—CH₂—, and —CH₂—S—CH₂—. A″ is preferably an alkylene group having 1 to 5 carbon atoms or —O—, more preferably an alkylene group having 1 to 5 carbon atoms, and most preferably a methylene group.

Specific examples of the groups respectively represented by General Formulae (a2-r-1) to (a2-r-7) are as follows.

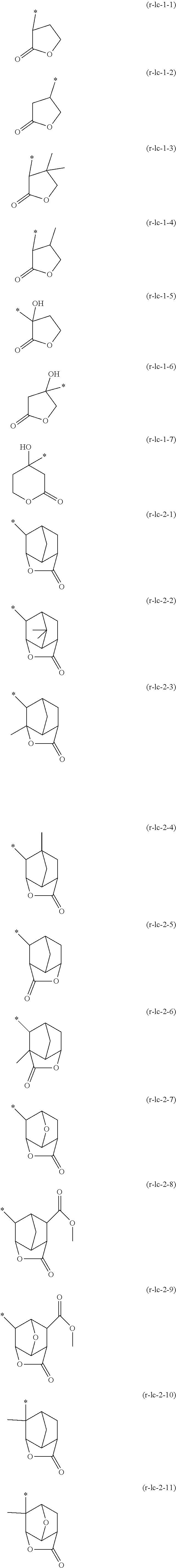

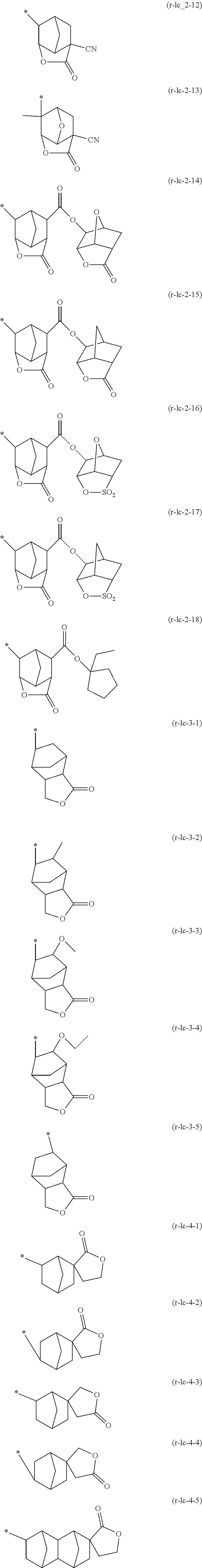

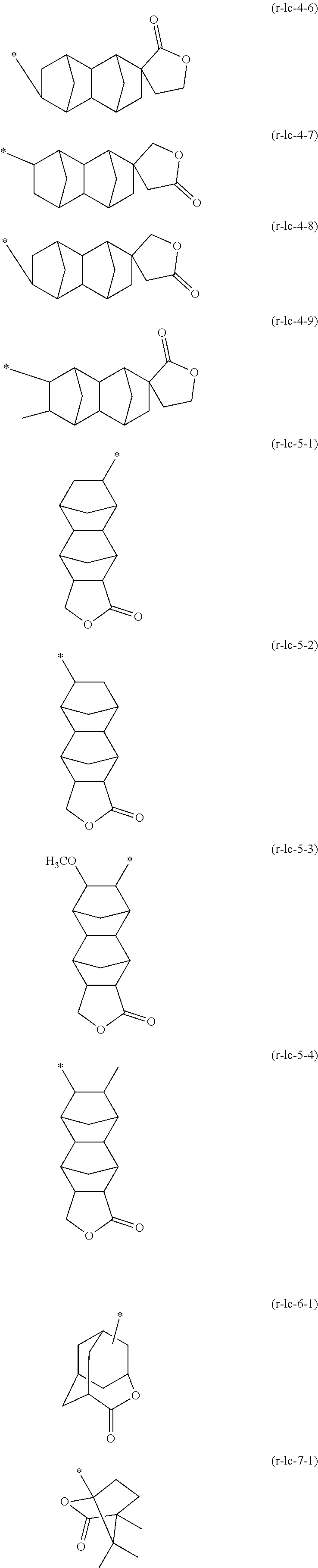

The “—SO₂— containing cyclic group” indicates a cyclic group having a ring containing —SO₂— in the ring skeleton thereof. Specifically, the —SO₂— containing cyclic group is a cyclic group in which the sulfur atom (S) in —SO₂— forms a part of the ring skeleton of the cyclic group. In a case where the ring containing —SO₂— in the ring skeleton thereof is counted as the first ring and the group contains only the ring, the group is referred to as the monocyclic group. Further, in a case where the group has other ring structures, the group is referred to as the polycyclic group regardless of the structures. The —SO₂— containing cyclic group may be a monocyclic group or a polycyclic group. The —SO₂— containing cyclic group is particularly preferably a cyclic group containing —O—SO₂— in the ring skeleton thereof, that is, a cyclic group containing a sultone ring in which —O—S— in the —O—SO₂— group forms a part of the ring skeleton thereof.

More specific examples of the —SO₂— containing cyclic group include groups respectively represented by General Formulae (a5-r-1) to (a5-r-4).

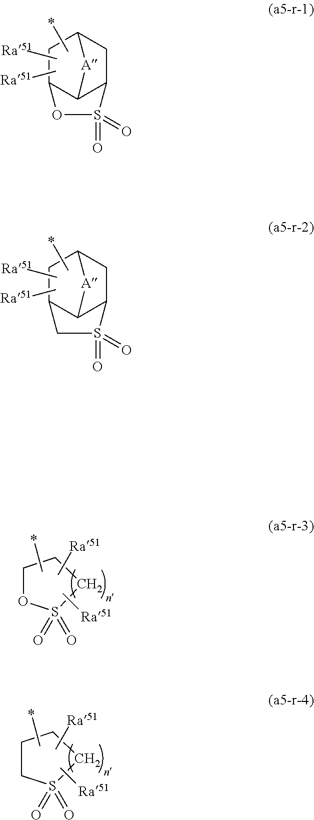

[In the formulae, each Ra′⁵¹ independently represent a hydrogen atom, an alkyl group, an alkoxy group, a halogen atom, a halogenated alkyl group, a hydroxy group, —COOR″, —OC(═O)R″, a hydroxyalkyl group, or a cyano group; R″ represents a hydrogen atom, an alkyl group, a lactone-containing cyclic group, a carbonate-containing cyclic group, or a —SO₂— containing cyclic group; A″ represents an oxygen atom, a sulfur atom, or an alkylene group having 1 to 5 carbon atoms, which may contain an oxygen atom or a sulfur atom; and n′ represents an integer of 0 to 2.]

In General Formulae (a5-r-1) and (a5-r-2), A″ is the same as A″ in General Formulae (a2-r-2), (a2-r-3) and (a2-r-5).

Examples of the alkyl group, the alkoxy group, the halogen atom, the halogenated alkyl group, —COOR″, —OC(═O)R″, and the hydroxyalkyl group, as Ra′⁵¹, include the same groups as those described above in the explanation of Ra′²¹ in General Formulae (a2-r-1) to (a2-r-7).

Specific examples of the groups respectively represented by General Formulae (a5-r-1) to (a5-r-4) areas follows. In the following formulae, “Ac” represents an acetyl group.

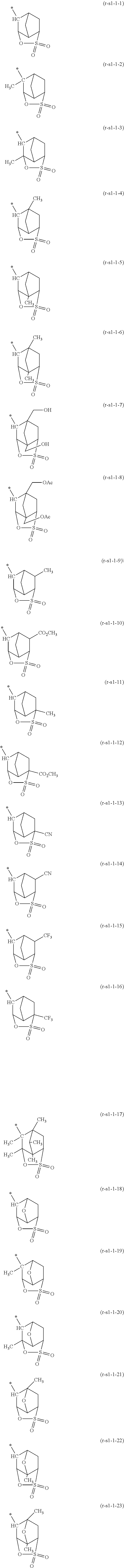

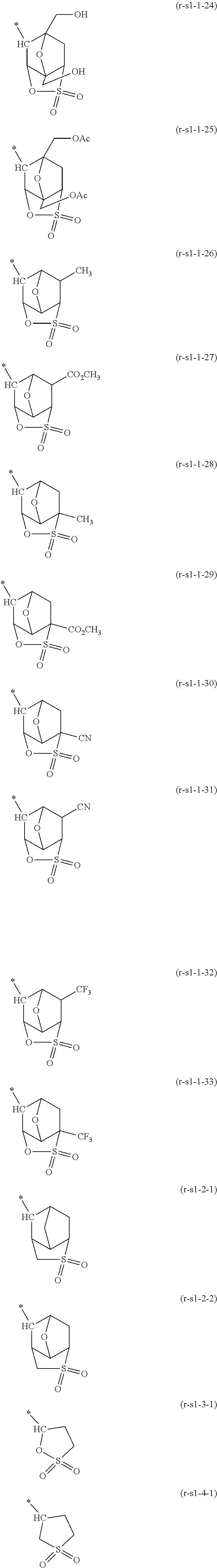

The “carbonate-containing cyclic group” indicates a cyclic group having a ring (a carbonate ring) containing —O—C(═O)—O— in the ring skeleton thereof. In a case where the carbonate ring is counted as the first ring and the group contains only the carbonate ring, the group is referred to as the monocyclic group. Further, in a case where the group has other ring structures, the group is referred to as the polycyclic group regardless of the structures. The carbonate-containing cyclic group may be a monocyclic group or a polycyclic group.

The carbonate ring-containing cyclic group is not particularly limited, and any group may be used. Specific examples thereof include groups respectively represented by General Formulae (ax3-r-1) to (ax3-r-3).

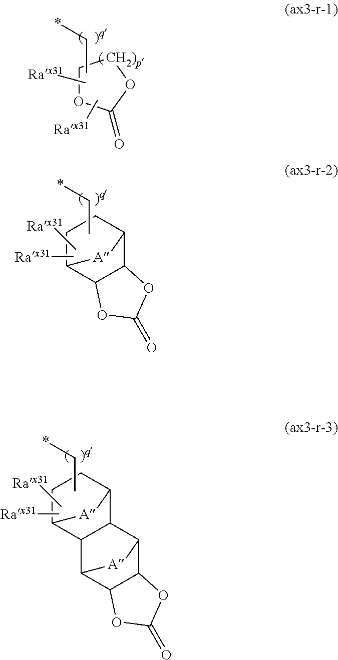

[In the formulae, each Ra′^{x31} independently represents a hydrogen atom, an alkyl group, an alkoxy group, a halogen atom, a halogenated alkyl group, a hydroxy group, —COOR″, —OC(═O)R″, a hydroxyalkyl group, or a cyano group; R″ represents a hydrogen atom, an alkyl group, a lactone-containing cyclic group, a carbonate-containing cyclic group, or a —SO₂— containing cyclic group; A″ represents an oxygen atom, a sulfur atom, or an alkylene group having 1 to 5 carbon atoms, which may contain an oxygen atom or a sulfur atom; and p′ represents an integer of 0 to 3, and q′ is 0 or 1.]

In General Formulae (ax3-r-2) and (ax3-r-3), A″ is the same as A″ in General Formulae (a2-r-2), (a2-r-3) and (a2-r-5).

Examples of the alkyl group, the alkoxy group, the halogen atom, the halogenated alkyl group, —COOR″, —OC(═O)R″, and the hydroxyalkyl group as Ra′31 include the same groups as those described above in the explanation of Ra′²¹ in General Formulae (a2-r-1) to (a2-r-7).

Specific examples of the groups respectively represented by General Formulae (ax3-r-1) to (ax3-r-3) are as follows.

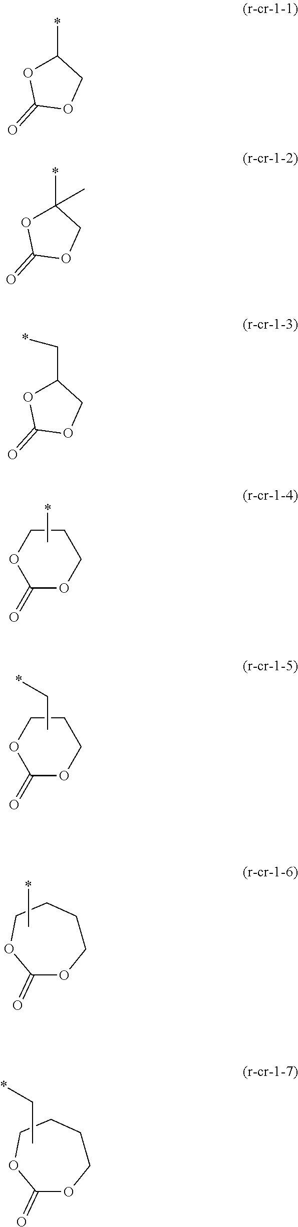

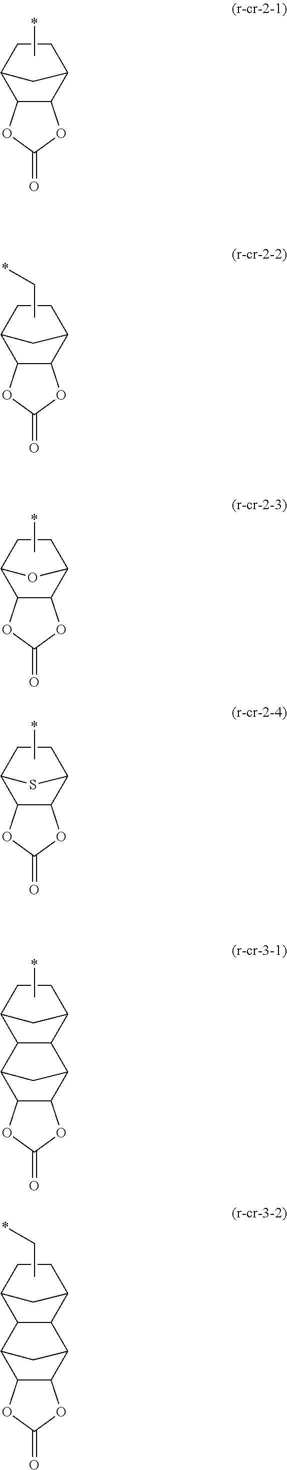

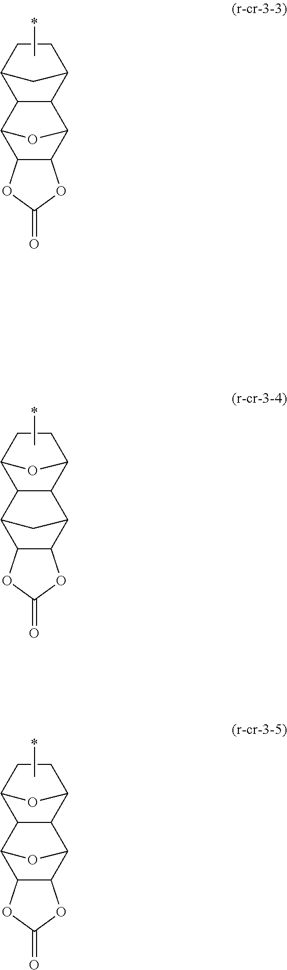

Among them, the constitutional unit (a2) is preferably a constitutional unit derived from the acrylic acid ester in which the hydrogen atom bonded to the carbon atom at the α-position may be substituted with a substituent.

The constitutional unit (a2) is preferably a constitutional unit represented by General Formula (a2-1).

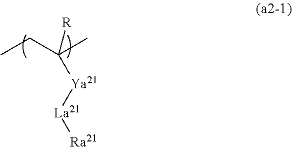

[In the formula, R represents a hydrogen atom, an alkyl group having 1 to 5 carbon atoms, or a halogenated alkyl group having 1 to 5 carbon atoms. Ya²¹ represents a single bond or a divalent linking group. La²¹ represents —O—, —COO—, —CON(R^{αx})—, —OCO—, —CONHCO— or —CONHCS—, and R′ represents a hydrogen atom or a methyl group. However, in a case where La²¹ represents —O—, Ya²¹ does not represent —CO—. Ra²¹ represents a lactone-containing cyclic group, a carbonate-containing cyclic group, or a —SO₂— containing cyclic group.]

In Formula (a2-1), R is the same as the above. R is preferably a hydrogen atom, an alkyl group having 1 to 5 carbon atoms, or a fluorinated alkyl group having 1 to 5 carbon atoms, and particularly preferably a hydrogen atom or a methyl group in terms of industrial availability.

In Formula (a2-1), the divalent linking group as Ya²¹ is not particularly limited, and suitable examples thereof include a divalent hydrocarbon group which may have a substituent and a divalent linking group having a hetero atom.

Divalent Hydrocarbon Group which May have Substituent:

In a case where Ya²¹ represents a divalent hydrocarbon group which may have a substituent, the hydrocarbon group may be an aliphatic hydrocarbon group or an aromatic hydrocarbon group.

Aliphatic Hydrocarbon Group as Ya²¹

The aliphatic hydrocarbon group indicates a hydrocarbon group that has no aromaticity. The aliphatic hydrocarbon group may be saturated or unsaturated. In general, the aliphatic hydrocarbon group is preferably saturated. Examples of the aliphatic hydrocarbon group include a linear or branched aliphatic hydrocarbon group, and an aliphatic hydrocarbon group containing a ring in the structure thereof.

Linear or Branched Aliphatic Hydrocarbon Group

The linear aliphatic hydrocarbon group has preferably 1 to 10 carbon atoms, more preferably 1 to 6 carbon atoms, still more preferably 1 to 4 carbon atoms, and most preferably 1 to 3 carbon atoms.

The linear aliphatic hydrocarbon group is preferably a linear alkylene group, and specific examples thereof include a methylene group [—CH₂—], an ethylene group [—(CH₂)₂—], a trimethylene group [—(CH₂)₃-], a tetramethylene group [—(CH₂)₄-], and a pentamethylene group [—(CH₂)₅-].

The branched aliphatic hydrocarbon group has preferably 2 to 10 carbon atoms, more preferably 3 to 6 carbon atoms, still more preferably 3 or 4 carbon atoms, and most preferably 3 carbon atoms.

The branched aliphatic hydrocarbon group is preferably a branched alkylene group, and specific examples thereof include alkylalkylene groups; for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. The alkyl group in the alkylalkylene group is preferably a linear alkyl group having 1 to 5 carbon atoms.

The linear or branched aliphatic hydrocarbon group may or may not have a substituent. Examples of the substituent include a fluorine atom, a fluorinated alkyl group having 1 to 5 carbon atoms, which has been substituted with a fluorine atom, and a carbonyl group.

Aliphatic Hydrocarbon Group Containing Ring in Structure Thereof

Examples of the aliphatic hydrocarbon group containing a ring in the structure thereof include a cyclic aliphatic hydrocarbon group which may have a substituent containing a hetero atom in the ring structure thereof (a group in which two hydrogen atoms have been removed from an aliphatic hydrocarbon ring), a group in which the cyclic aliphatic hydrocarbon group is bonded to the terminal of a linear or branched aliphatic hydrocarbon group, and a group in which the cyclic aliphatic hydrocarbon group is interposed in a linear or branched aliphatic hydrocarbon group. Examples of the linear or branched aliphatic hydrocarbon group include the same groups as those described above.

The cyclic aliphatic hydrocarbon group has preferably 3 to 20 carbon atoms and more preferably 3 to 12 carbon atoms.

The cyclic aliphatic hydrocarbon group may be a polycyclic group or a monocyclic group. The monocyclic alicyclic hydrocarbon group is preferably a group in which two hydrogen atoms have been removed from a monocycloalkane. The monocycloalkane has preferably 3 to 6 carbon atoms, and specific examples thereof include cyclopentane and cyclohexane. The polycyclic alicyclic hydrocarbon group is preferably a group in which two hydrogen atoms have been removed from a polycycloalkane. The polycycloalkane is preferably a group having 7 to 12 carbon atoms, and specific examples of the polycycloalkane include adamantane, norbornane, isobornane, tricyclodecane, and tetracyclododecane.

The cyclic aliphatic hydrocarbon group may or may not have a substituent. Examples of the substituent include an alkyl group, an alkoxy group, a halogen atom, a halogenated alkyl group, a hydroxy group, and a carbonyl group.

The alkyl group as the substituent is preferably an alkyl group having 1 to 5 carbon atoms, and more preferably a methyl group, an ethyl group, a propyl group, an n-butyl group, or a tert-butyl group.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and still more preferably a methoxy group or an ethoxy group.

The halogen atom as the substituent is preferably a fluorine atom.

Examples of the halogenated alkyl group as the substituent include groups in which a part or all hydrogen atoms in the above-described alkyl groups have been substituted with the above-described halogen atoms.

In the cyclic aliphatic hydrocarbon group, a part of carbon atoms constituting the ring structure thereof may be substituted with a substituent containing a hetero atom. The substituent containing a hetero atom is preferably —O—, —C(═O)—O—, —S—, —S(═O)₂—, or —S(═O)₂—O—.

Aromatic Hydrocarbon Group as Ya²¹

The aromatic hydrocarbon group is a hydrocarbon group having at least one aromatic ring.

The aromatic ring is not particularly limited as long as it is a cyclic conjugated system having (4n+2) π electrons, and may be monocyclic or polycyclic. The aromatic ring has preferably 5 to 30 carbon atoms, more preferably 5 to 20 carbon atoms, still more preferably 6 to 15 carbon atoms, and particularly preferably 6 to 12 carbon atoms. However, the number of carbon atoms in a substituent is not included in the number of carbon atoms.

Specific examples of the aromatic ring include: aromatic hydrocarbon rings such as benzene, naphthalene, anthracene, and phenanthrene; and aromatic hetero rings in which a part of carbon atoms constituting the above-described aromatic hydrocarbon rings have been substituted with hetero atoms. Examples of the hetero atom in the aromatic hetero rings include an oxygen atom, a sulfur atom, and a nitrogen atom. Specific examples of the aromatic hetero ring include a pyridine ring and a thiophene ring.

Specific examples of the aromatic hydrocarbon group include a group in which two hydrogen atoms have been removed from the above-described aromatic hydrocarbon ring or aromatic hetero ring (an arylene group or a heteroarylene group); a group in which two hydrogen atoms have been removed from an aromatic compound having two or more aromatic rings (such as biphenyl or fluorene); and a group in which one hydrogen atom of a group (an aryl group or a heteroaryl group) obtained by removing one hydrogen atom from the above-described aromatic hydrocarbon ring or aromatic hetero ring has been substituted with an alkylene group (for example, a group obtained by further removing one hydrogen atom from an aryl group in an arylalkyl group such as a benzyl group, a phenethyl group, a 1-naphthylmethyl group, a 2-naphthylmethyl group, a 1-naphthylethyl group, or a 2-naphthylethyl group). The alkylene group bonded to the aryl group or the heteroaryl group has preferably 1 to 4 carbon atoms, more preferably 1 or 2 carbon atoms, and particularly preferably 1 carbon atom.

With respect to the aromatic hydrocarbon group, the hydrogen atom that the aromatic hydrocarbon group has may be substituted with a substituent. For example, the hydrogen atom bonded to the aromatic ring in the aromatic hydrocarbon group may be substituted with a substituent. Examples of substituents include an alkyl group, an alkoxy group, a halogen atom, a halogenated alkyl group, and a hydroxy group.

The alkyl group as the substituent is preferably an alkyl group having 1 to 5 carbon atoms, and more preferably a methyl group, an ethyl group, a propyl group, an n-butyl group, or a tert-butyl group.

Examples of the alkoxy group, the halogen atom, and the halogenated alkyl group, as the substituent, include those exemplified as the substituent that is substituted for a hydrogen atom that the cyclic aliphatic hydrocarbon group has.

Divalent Linking Group Containing Hetero Atom

In a case where Ya²¹ represents a divalent linking group containing a hetero atom, preferred examples of the linking group include —O—, —C(═O)—O—, —O—C(═O)—, —C(═O)—, —O—C(═O)—O— —C(═O)—NH—, —NH—, —NH—C(═NH)— (H may be substituted with a substituent such as an alkyl group, an acyl group, or the like), —S—, —S(═O)₂—, —S(═O)₂—O—, and a group represented by General Formula; —Y²¹—O—Y²², —Y²¹—O—, —Y²¹—C(═O)—O—, —C(═O)—O—Y²¹, —[Y²¹—C(═O)—O]_{m″}—Y²², —Y²¹—O—C(═O)—Y²²— or —Y²¹—S(═O)₂—O—Y²²— [in the formulae, Y²¹ and Y²² each independently represent a divalent hydrocarbon group which may have a substituent, O represents an oxygen atom, and m″ represents an integer of 0 to 3].

In a case where the divalent linking group containing a hetero atom is —C(═O)—NH—, —C(═O)—NH—C(═O)—, —NH—, or —NH—C(═NH)—, H in these group may be substituted with a substituent such as an alkyl group, and an acyl group. The substituent (an alkyl group, an acyl group, or the like) has preferably 1 to 10 carbon atoms, more preferably 1 to 8 carbon atoms, and particularly preferably 1 to 5 carbon atoms.

In General Formula —Y²¹—O—Y²²—, —Y²¹—O—, —Y²¹—C(═O)—O—, —C(═O)—O—Y²¹—[Y²¹—C(═O)—O]_{m″}—Y²², —Y²¹—O—C(═O)—Y²²—, or —Y²¹—S(═O)₂—O—Y²²—, Y²¹ and Y²² each independently represent a divalent hydrocarbon group which may have a substituent. Examples of the divalent hydrocarbon group include the same groups as those (divalent hydrocarbon groups which may have a substituent) mentioned in the description of the above-described divalent linking group as Ya²¹

Y²¹ is preferably a linear aliphatic hydrocarbon group, more preferably a linear alkylene group, still more preferably a linear alkylene group having 1 to 5 carbon atoms, and particularly preferably a methylene group or an ethylene group.

Y²² is preferably a linear or branched aliphatic hydrocarbon group and more preferably a methylene group, an ethylene group, or an alkylmethylene group. The alkyl group in the alkylmethylene group is preferably a linear alkyl group having 1 to 5 carbon atoms, more preferably a linear alkyl group having 1 to 3 carbon atoms, and most preferably a methyl group.

In the group represented by Formula —[Y²¹—C(═O)—O]ₘ″-Y²²—, m″ represents an integer of 0 to 3, preferably an integer of 0 to 2, more preferably 0 or 1, and particularly preferably 1. In other words, the group represented by Formula —[Y²¹—C(═O)—O]ₘ″-Y²²— is particularly preferably a group represented by Formula —Y²¹—C(═O)—O—Y²²—. Among them, a group represented by Formula —(CH₂)_{a′}—C(═O)—O—(CH₂)_{b′}— is preferable. In the formula, a′ represents an integer of 1 to 10, preferably an integer of 1 to 8, more preferably an integer of 1 to 5, still more preferably 1 or 2, and most preferably 1. b′ represents an integer of 1 to 10, preferably an integer of 1 to 8, more preferably an integer of 1 to 5, still more preferably 1 or 2, and most preferably 1.

Among the above, Ya²¹ is preferably a single bond, an ester bond [—C(═O)—O—], an ether bond (—O—), a linear or branched alkylene group, or a combination thereof.

In Formula (a2-1), Ra²¹ represents a lactone-containing cyclic group, a —SO₂— containing cyclic group, or a carbonate-containing cyclic group.

Suitable examples of the lactone-containing cyclic group, the —SO₂— containing cyclic group, and the carbonate-containing cyclic group as Ra²¹ respectively include groups respectively represented by General Formulae (a2-r-1) to (a2-r-7), groups respectively represented by General Formulae (a5-r-1) to (a5-r-4), and groups respectively represented by General Formulae (ax3-r-1) to (ax3-r-3) described above.

Among them, a lactone-containing cyclic group or a —SO₂— containing cyclic group is preferable, and groups respectively represented by General Formula (a2-r-1), (a2-r-2), (a2-r-6), or (a5-r-1) are more preferable. Specifically, groups respectively represented by any one of Chemical Formulae (r-1c-1-1) to (r-1c-1-7), (r-1c-2-1) to (r-1c-2-18), (r-1c-6-1), (r-s1-1-1), and (r-s1-1-18) are more preferable.

The constitutional unit (a2) which the component (A1) has may be one kind or may be two or more kinds.

In a case where the component (A1) has the constitutional unit (a2), the proportion of the constitutional unit (a2) is preferably 5% to 60% by mole, more preferably 10% to 60% by mole, still more preferably 20% to 55% by mole, and particularly preferably 30% to 50% by mole, with respect to the total amount (100% by mole) of all constitutional units constituting the component (A1).

In a case where the proportion of the constitutional unit (a2) is equal to or greater than the lower limit of the above-described preferred range, the effect obtained by allowing the component (A1) to contain the constitutional unit (a2) can be sufficiently achieved by the effect described above. In a case where the proportion of the constitutional unit (a2) is equal to or lower than the upper limit of the above-described preferred range, balance with other constitutional units can be obtained, and various lithography characteristics are improved.

In Regard to Constitutional Unit (a3):

In addition to the constitutional unit (a1), the component (A1) may further have a constitutional unit (a3) (however, a constitutional unit corresponding to the constitutional unit (a2) is excluded) containing a polar group-containing aliphatic hydrocarbon group. In a case where the component (A1) has the constitutional unit (a3), the hydrophilicity of the component (A) is increased, which contributes to an improvement in resolution. Further, the acid diffusion length can be appropriately adjusted.

Examples of the polar group include a hydroxy group, a cyano group, a carboxy group, or a hydroxyalkyl group in which a part of hydrogen atoms of the alkyl group have been substituted with fluorine atoms. Among these, a hydroxy group is particularly preferable.

Examples of the aliphatic hydrocarbon group include a linear or branched hydrocarbon group (preferably alkylene group) having 1 to 10 carbon atoms, and a cyclic aliphatic hydrocarbon group (cyclic group). The cyclic group may be a monocyclic group or a polycyclic group. For example, these cyclic groups can be properly selected from a large number of groups that have been proposed for a resin for a resist composition for an ArF excimer laser.

In a case where the cyclic group is a monocyclic group, the monocyclic group more preferably has 3 to 10 carbon atoms. Among them, constitutional units derived from the acrylic acid ester that includes an aliphatic monocyclic group containing a hydroxy group, cyano group, carboxy group, or a hydroxyalkyl group in which a part of hydrogen atoms of the alkyl group have been substituted with fluorine atoms are more preferable. Examples of the monocyclic group include groups in which two or more hydrogen atoms have been removed from a monocycloalkane. Specific examples of the monocyclic group include groups in which two or more hydrogen atoms have been removed from monocycloalkanes such as cyclopentane, cyclohexane, and cyclooctane. Among these monocyclic groups, a group in which two or more hydrogen atoms have been removed from cyclopentane or a group in which two or more hydrogen atoms have been removed from cyclohexane are industrially preferable.

In a case where the cyclic group is a polycyclic group, the polycyclic group is more preferably has 7 to 30 carbon atoms. Among them, constitutional units derived from the acrylic acid ester that includes an aliphatic polycyclic group containing a hydroxy group, cyano group, carboxy group, or a hydroxyalkyl group in which a part of hydrogen atoms of the alkyl group have been substituted with fluorine atoms are more preferable. Examples of the polycyclic group include groups in which two or more hydrogen atoms have been removed from a bicycloalkane, a tricycloalkane, a tetracycloalkane, or the like. Specific examples thereof include groups in which two or more hydrogen atoms have been removed from polycycloalkanes such as adamantane, norbornane, isobornane, tricyclodecane, and tetracyclododecane. Among these polycyclic groups, a group in which two or more hydrogen atoms have been removed from adamantane, a group in which two or more hydrogen atoms have been removed from norbornane, and a group in which two or more hydrogen atoms have been removed from tetracyclododecane are preferred industrially.

The constitutional unit (a3) is not particularly limited, and any constitutional unit may be used as long as the constitutional unit contains a polar group-containing aliphatic hydrocarbon group.

The constitutional unit (a3) is preferably a constitutional unit which contains a polar group-containing aliphatic hydrocarbon group, which is a constitutional unit derived from the acrylic acid ester in which the hydrogen atom bonded to the carbon atom at the α-position may be substituted with a substituent.

In a case where the hydrocarbon group in the polar group-containing aliphatic hydrocarbon group is a linear or branched hydrocarbon group having 1 to 10 carbon atoms, the constitutional unit (a3) is preferably a constitutional unit derived from a hydroxyethyl ester of acrylic acid.

Further, examples of the constitutional unit (a3) include, as a preferred constitutional unit: in a case where the hydrocarbon group in the polar group-containing aliphatic hydrocarbon group is a polycyclic group, a constitutional unit represented by Formula (a3-1), a constitutional unit represented by Formula (a3-2), and a constitutional unit represented by Formula (a3-3); and in a case where the hydrocarbon group is a monocyclic group, a constitutional unit represented by Formula (a3-4).

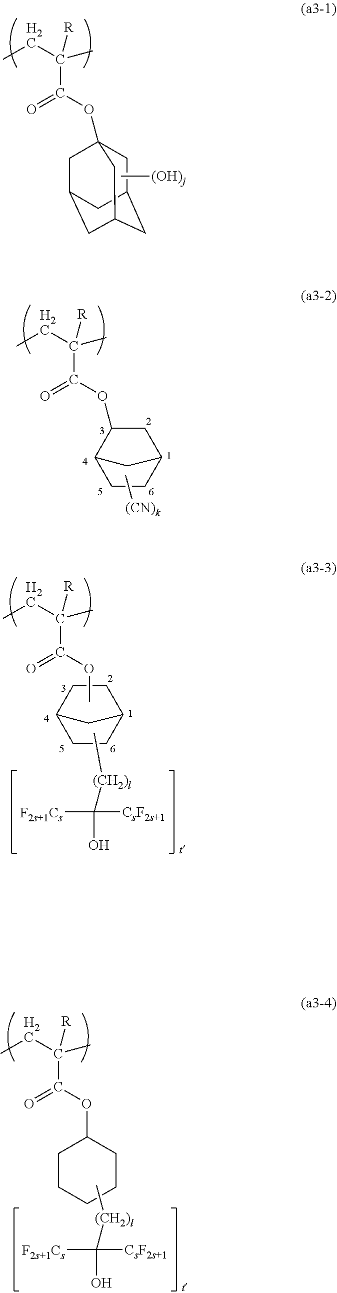

[In the formulae, R is the same as the above, j represents an integer of 1 to 3, k represents an integer of 1 to 3, t′ represents an integer of 1 to 3, l represents an integer of 0 to 5, and s represents an integer of 1 to 3.]

In Formula (a3-1), j represents preferably 1 or 2 and more preferably 1. In a case where j represents 2, it is preferable that the hydroxy groups are bonded to the 3-position and the 5-position of the adamantyl group. In a case where j represents 1, it is preferable that the hydroxy group is bonded to the 3-position of the adamantyl group. It is preferable that j represents 1, and it is particularly preferable that the hydroxy group is bonded to the 3-position of the adamantyl group.

In Formula (a3-2), k represents preferably 1. The cyano group is preferably bonded to the 5-position or the 6-position of the norbornyl group.

In Formula (a3-3), it is preferable that t′ represents 1. It is preferable that 1 represents 1. It is preferable that s represents 1. Further, it is preferable that a 2-norbornyl group or 3-norbornyl group is bonded to the terminal of the carboxy group of the acrylic acid. It is preferable that the fluorinated alkyl alcohol is bonded to the 5-position or the 6-position of the norbornyl group.

In Formula (a3-4), it is preferable that t′ represents 1 or 2. It is preferable that 1 represents 0 or 1. It is preferable that s represents 1. It is preferable that the fluorinated alkyl alcohol is bonded to the 3-position or the 5-position of the cyclohexyl group.

The constitutional unit (a3) which the component (A1) has may be one kind or may be two or more kinds.

In a case where the component (A1) has the constitutional unit (a3), the proportion of the constitutional unit (a3) is preferably 1% to 30% by mole, more preferably 2% to 25% by mole, and still more preferably 5% to 20% by mole, with respect to the total amount (100% by mole) of all constitutional units constituting the component (A1).

In a case where the proportion of the constitutional unit (a3) is equal to or greater than the lower limit of the above-described preferred range, the effect obtained by allowing the component (A1) to contain the constitutional unit (a3) can be sufficiently achieved by the effect described above. In a case where the proportion of the constitutional unit (a3) is equal to or lower than the upper limit of the above-described preferred range, balance with other constitutional units can be obtained, and various lithography characteristics are improved.

In Regard to Constitutional Unit (a4):

In addition to the constitutional unit (a1), the component (A1) may further have a constitutional unit (a4) containing an acid non-dissociable aliphatic cyclic group.

In a case where the component (A1) has the constitutional unit (a4), the dry etching resistance of the formed resist pattern is improved. Further, the hydrophobicity of the component (A) is improved. The improvement in hydrophobicity contributes to the improvement in resolution, resist pattern shape, and the like, particularly in the case of a solvent developing process. The “acid non-dissociable cyclic group” in the constitutional unit (a4) is a cyclic group that remains in the constitutional unit without being dissociated even when an acid acts in a case where the acid is generated in the resist composition upon exposure (for example, in a case where an acid is generated from the constitutional unit generating an acid upon exposure or the component (B)).

The constitutional unit (a4) is preferably, for example, a constitutional unit derived from the acrylic acid ester containing an acid non-dissociable aliphatic cyclic group. As the cyclic group, a large number of cyclic groups conventionally known as the cyclic groups which are used as a resin component of a resist composition for an ArF excimer laser, a KrF excimer laser (preferably an ArF excimer laser), or the like can be used.

The cyclic group is preferably at least one selected from a tricyclodecyl group, an adamantyl group, a tetracyclododecyl group, an isobornyl group, and a norbomyl group, from the viewpoint of industrial availability. These polycyclic groups may have, as a substituent, a linear or branched alkyl group having 1 to 5 carbon atoms.

Specific examples of the constitutional unit (a4) include constitutional units respectively represented by General Formulae (a4-1) to (a4-7).

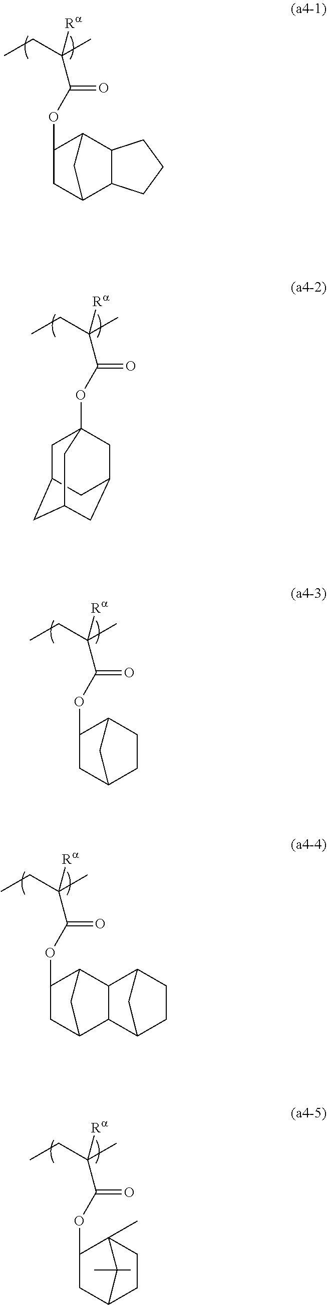

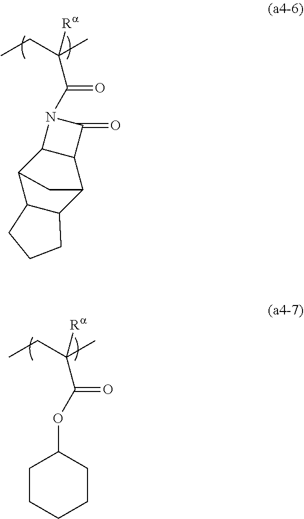

[In the formula, R^{α} is the same as the above.]

The constitutional unit (a4) which the component (A) has may be one kind or may be two or more kinds.

In a case where the component (A1) has the constitutional unit (a4), the proportion of the constitutional unit (a4) is preferably 1% to 40% by mole and more preferably 5% to 20% by mole, with respect to the total amount (100% by mole) of all constitutional units constituting the component (A1).

In a case where the proportion of the constitutional unit (a4) is equal to or greater than the lower limit of the preferred range, the effect obtained by allowing the component (A1) to contain the constitutional unit (a4) can be sufficiently achieved. In a case where the proportion of the constitutional unit (a4) is equal to or lower than the upper limit of the preferred range, the balance with other constitutional units is obtained easily.

In Regard to Constitutional Unit (St):

The constitutional unit (st) is a constitutional unit derived from styrene or a styrene derivative. A “constitutional unit derived from styrene” means a constitutional unit that is formed by the cleavage of an ethylenic double bond of styrene. A “constitutional unit derived from a styrene derivative” means a constitutional unit (however, a constitutional unit corresponding to the constitutional unit (a10) is excluded) formed by the cleavage of an ethylenic double bond of a styrene derivative.

The “styrene derivative” means a compound in which at least a part of hydrogen atoms of styrene are substituted with a substituent. Examples of the styrene derivative include a derivative in which the hydrogen atom at the α-position of styrene is substituted with a substituent, a derivative in which one or more hydrogen atoms of the benzene ring of styrene are substituted with a substituent, and a derivative in which the hydrogen atom at the α-position of styrene and one or more hydrogen atoms of the benzene ring are substituted with a substituent.

Examples of the substituent that is substituted for the hydrogen atom at the α-position of styrene include an alkyl group having 1 to 5 carbon atoms and a halogenated alkyl group having 1 to 5 carbon atoms.

The alkyl group having 1 to 5 carbon atoms is preferably a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group.

The halogenated alkyl group having 1 to 5 carbon atoms is a group in which a part or all hydrogen atoms in the alkyl group having 1 to 5 carbon atoms have been substituted with halogen atoms. The halogen atom is particularly preferably a fluorine atom.

The substituent that is substituted for the hydrogen atom at the α-position of styrene is preferably an alkyl group having 1 to 5 carbon atoms or a fluorinated alkyl group having 1 to 5 carbon atoms, more preferably an alkyl group having 1 to 3 carbon atoms or a fluorinated alkyl group having 1 to 3 carbon atoms, and still more preferably a methyl group from the viewpoint of industrial availability.

Examples of the substituent that is substituted for the hydrogen atom of the benzene ring of styrene include an alkyl group, an alkoxy group, a halogen atom, and a halogenated alkyl group.

The alkyl group as the substituent is preferably an alkyl group having 1 to 5 carbon atoms, and more preferably a methyl group, an ethyl group, a propyl group, an n-butyl group, or a tert-butyl group.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and still more preferably a methoxy group or an ethoxy group.

The halogen atom as the substituent is preferably a fluorine atom.

Examples of the halogenated alkyl group as the substituent include groups in which a part or all hydrogen atoms in the above-described alkyl groups have been substituted with the above-described halogen atoms.

The substituent that is substituted for the hydrogen atom of the benzene ring of styrene, an alkyl group having 1 to 5 carbon atoms is preferable, a methyl group or an ethyl group is more preferable, and a methyl group is still more preferable.

The constitutional unit (st) is preferably a constitutional unit derived from styrene or a constitutional unit derived from a styrene derivative in which the hydrogen atom at the α-position of styrene is substituted with an alkyl group having 1 to 5 carbon atoms or a halogenated alkyl group having 1 to 5 carbon atoms, more preferably a constitutional unit derived from styrene, or a constitutional unit derived from a styrene derivative in which the hydrogen atom at the α-position of styrene is substituted with a methyl group, and still more preferably a constitutional unit derived from styrene.

The constitutional unit (st) which the component (A1) has may be one kind or may be two or more kinds.

In a case where the component (A1) has the constitutional unit (st), the proportion of the constitutional unit (st) is preferably 1% to 30% by mole and more preferably 3% to 20% by mole, with respect to the total amount (100% by mole) of all constitutional units constituting the component (A1).

The component (A1) contained in the resist composition may be used alone or in a combination of two or more kinds thereof.

In the resist composition of the present embodiment, as the component (A1), a high molecular compound having a repeated structure of the constitutional unit (a1).

An example of the preferred component (A1) contains a high molecular compound having a repeated structure of the constitutional unit (a1) and the constitutional unit (a10).

In this case, the proportion of the constitutional unit (a1) in the high molecular compound is preferably 5% to 80% by mole, more preferably 10% to 75% by mole, still more preferably 30% to 70% by mole, and particularly preferably 40% to 60% by mole, with respect to the total amount (100% by mole) of all constitutional units constituting the high molecular compound.

In addition, the proportion of the constitutional unit (a10) in the high molecular compound is preferably 5% to 80% by mole, more preferably 10% to 75% by mole, still more preferably 30% to 70% by mole, and particularly preferably 40% to 60% by mole, with respect to the total amount (100% by mole) of all constitutional units constituting the high molecular compound.

The molar ratio (constitutional unit (a1):constitutional unit (a10)) of the constitutional unit (a1) to the constitutional unit (a10) in the high molecular compound is preferably 2:8 to 8:2, more preferably 3:7 to 7:3, and still more preferably 4:6 to 6:4.

The component (A1) can be produced by dissolving, in a polymerization solvent, each monomer from which the constitutional unit is derived, adding thereto a radical polymerization initiator such as azobisisobutyronitrile (AIBN) or dimethyl azobisisobutyrate (for example, V-601) to perform polymerization.

Alternatively, the component (A1) can be produced by dissolving, in a polymerization solvent, a monomer from which the constitutional unit (a1) is derived and optionally a monomer from which a constitutional unit other than the constitutional unit (a1) is derived, and adding thereto a radical polymerization initiator such as that described above to perform polymerization, and then performing a deprotection reaction.

Further, a —C(CF₃)₂—OH group may be introduced into the terminal of the component (A1) during the polymerization using in combination with a chain transfer agent such as HS—CH₂—CH₂—CH₂—C(CF₃)₂—OH. As described above, a copolymer into which a hydroxyalkyl group, formed by substitution of a part of hydrogen atoms in the alkyl group with fluorine atoms, has been introduced is effective for reducing development defects and reducing line edge roughness (LER: uneven irregularities of a line side wall).

The weight-average molecular weight (Mw) (based on the polystyrene-equivalent value determined by gel permeation chromatography (GPC)) of the component (A1), which is not particularly limited, is preferably 1,000 to 50,000, more preferably 2,000 to 30,000, and still more preferably 3,000 to 20,000.

In a case where Mw of the component (A1) is equal to or lower than the upper limit of this preferred range, the resist composition exhibits a solubility in a solvent for a resist, which is enough for using the resist composition as a resist composition. On the other hand, in a case where Mw of the component (A1) is equal to or greater than the lower limit of this preferred range, dry etching resistance and the cross-sectional shape of the resist pattern become excellent.

Further, the dispersity (Mw/Mn) of the component (A1) is not particularly limited but is preferably 1.0 to 4.0, more preferably 1.0 to 3.0, and particularly preferably 1.0 to 2.0. Mn represents the number average molecular weight.

In Regard to Component (A2)

In the resist composition of the present embodiment, a base material component (hereinafter, referred to as “component (A2)”) exhibiting changed solubility in a developing solution under action of acid, which does not correspond to the component (A1), may be used in combination as the component (A).

The component (A2) is not particularly limited and may be freely selected and used from a large number of conventionally known base material components for the chemical amplification type resist composition.

As the component (A2), a high molecular compound or a low molecular compound may be used alone or in a combination of two or more kinds thereof.

The proportion of the component (A1) in the component (A) is preferably 25% by mass or more, more preferably 50% by mass or more, and still more preferably 75% by mass or more, and may be 100% by mass, with respect to the total mass of the component (A). In a case where the proportion is 25% by mass or more, a resist pattern having various excellent lithography characteristics, such as high sensitivity, improvement in resolution or roughness can be easily formed.

The content of the component (A) in the resist composition of the present embodiment may be adjusted depending on the resist film thickness to be formed and the like.

<<Acid Generator Component (B)>>

In addition to the component (A), the resist composition of the present embodiment further contains an acid generator component (B) generating an acid upon exposure.

The component (B) is not particularly limited, and those which have been proposed as an acid generator for a chemical amplification type resist composition in the related art can be used.

Examples of the acid generator are numerous and include onium salt-based acid generators such as iodonium salts and sulfonium salts; oxime sulfonate-based acid generators; diazomethane-based acid generators such as bisalkyl or bisaryl sulfonyl diazomethanes and poly(bis-sulfonyl)diazomethanes; nitrobenzylsulfonate-based acid generators; iminosulfonate-based acid generators; and disulfone-based acid generators.

Examples of the onium salt-based acid generator include a compound represented by General Formula (b-1) (hereinafter, also referred to as “component (b-1)”), a compound represented by General Formula (b-2) (hereinafter, also referred to as “component (b-2)”), and a compound represented by General Formula (b-3) (hereinafter, also referred to as “component (b-3)”).

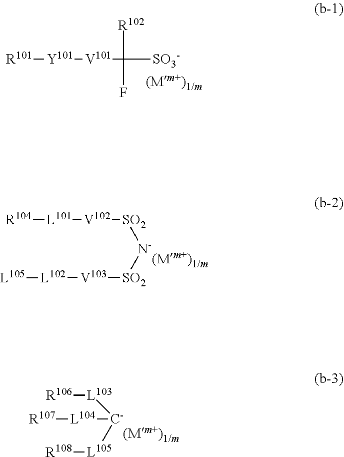

[In the formulae, R¹⁰¹ and R¹⁰⁴ to R¹⁰⁸ each independently represent a cyclic group which may have a substituent, a chain-like alkyl group which may have a substituent, or a chain-like alkenyl group which may have a substituent. R¹⁰⁴ and R¹⁰⁵ may be bonded to each other to form a ring structure. R¹⁰² represents a fluorinated alkyl group having 1 to 5 carbon atoms or a fluorine atom. Y¹⁰¹ represents a divalent linking group containing an oxygen atom or a single bond. V¹⁰¹ to V¹⁰³ each independently represent a single bond, an alkylene group, or a fluorinated alkylene group. L¹⁰¹ and L¹⁰² each independently represent a single bond or an oxygen atom. L¹⁰³ to L¹⁰⁵ each independently represent a single bond, —CO—, or —SO₂—. m represents an integer of 1 or more, and M′ represents an m-valent onium cation.]

{Anion Moiety}

Anion in Component (b-1)

In Formula (b-1), R¹⁰¹ represents a cyclic group which may have a substituent, a chain-like alkyl group which may have a substituent, or a chain-like alkenyl group which may have a substituent.

Cyclic Group which May have Substituent:

The cyclic group is preferably a cyclic hydrocarbon group, and the cyclic hydrocarbon group may be an aromatic hydrocarbon group or an aliphatic hydrocarbon group. The aliphatic hydrocarbon group indicates a hydrocarbon group that has no aromaticity. The aliphatic hydrocarbon group may be saturated or unsaturated. In general, it is preferable that the aliphatic hydrocarbon group is saturated.

The aromatic hydrocarbon group as R¹⁰¹ is a hydrocarbon group having an aromatic ring. The aromatic hydrocarbon group has preferably 3 to 30 carbon atoms, more preferably 5 to 30, still more preferably 5 to 20, particularly preferably 6 to 15, and most preferably 6 to 10. Here, the number of carbon atoms in a substituent is not included in the number of carbon atoms.

Specific examples of the aromatic ring which the aromatic hydrocarbon group has as R¹⁰¹ include benzene, fluorene, naphthalene, anthracene, phenanthrene, biphenyl, and an aromatic hetero ring in which a part of carbon atoms constituting any of these aromatic rings have been substituted with hetero atoms. Examples of the hetero atom in the aromatic hetero rings include an oxygen atom, a sulfur atom, and a nitrogen atom.

Specific examples of the aromatic hydrocarbon group as R¹⁰¹ include a group in which one hydrogen atom has been removed from the above-described aromatic ring (an aryl group, for example, a phenyl group and a naphthyl group) and a group in which one hydrogen atom in the aromatic ring has been substituted with an alkylene group (for example, arylalkyl groups such as a benzyl group, a phenethyl group, a 1-naphthylmethyl group, a 2-naphthylmethyl group, 1-naphthylethyl group, and a 2-naphthylethyl group). The alkylene group (an alkyl chain in the arylalkyl group) has preferably 1 to 4 carbon atoms, more preferably 1 or 2 carbon atoms, and particularly preferably 1 carbon atom.

Examples of the cyclic aliphatic hydrocarbon group as R¹¹ include aliphatic hydrocarbon groups containing a ring in the structure thereof.

Examples of the aliphatic hydrocarbon group containing a ring in the structure thereof include an alicyclic hydrocarbon group (a group in which one hydrogen atom has been removed from an aliphatic hydrocarbon ring), a group in which the alicyclic hydrocarbon group is bonded to the terminal of a linear or branched aliphatic hydrocarbon group, and a group in which the alicyclic hydrocarbon group is interposed in a linear or branched aliphatic hydrocarbon group.

The alicyclic hydrocarbon group has preferably 3 to 20 carbon atoms and more preferably 3 to 12 carbon atoms.

The alicyclic hydrocarbon group may be a polycyclic group or a monocyclic group. The monocyclic alicyclic hydrocarbon group is preferably a group in which one or more hydrogen atoms have been removed from a monocycloalkane. The monocycloalkane has preferably 3 to 6 carbon atoms, and specific examples thereof include cyclopentane and cyclohexane. The polycyclic alicyclic hydrocarbon group is preferably a group in which one or more hydrogen atoms have been removed from a polycycloalkane, and the number of carbon atoms of the polycycloalkane is preferably 7 to 30. Among them, the polycycloalkane is more preferably polycycloalkanes having a crosslinked ring-based polycyclic skeleton, such as adamantane, norbornane, isobornane, tricyclodecane, and tetracyclododecane, and polycycloalkanes having a condensed ring-based polycyclic skeleton, such as a cyclic group having a steroid skeleton.

Among them, the cyclic aliphatic hydrocarbon group as R⁰ is preferably a group in which one or more hydrogen atoms have been removed from a monocycloalkane or a polycycloalkane, more preferably a group in which one hydrogen atom has been removed from a polycycloalkane, particularly preferably an adamantyl group or a norbornyl group, and most preferably an adamantyl group.

The linear aliphatic hydrocarbon group which may be bonded to the alicyclic hydrocarbon group has preferably 1 to 10 carbon atoms, more preferably 1 to 6 carbon atoms, still more preferably 1 to 4 carbon atoms, and most preferably 1 to 3 carbon atoms. The linear aliphatic hydrocarbon group is preferably a linear alkylene group, and specific examples thereof include a methylene group [—CH₂—], an ethylene group [—(CH₂)₂—], a trimethylene group [—(CH₂)₃-], a tetramethylene group [—(CH₂)₄-], and a pentamethylene group [—(CH₂)₅-].

The branched aliphatic hydrocarbon group which may be bonded to the alicyclic hydrocarbon group has preferably 2 to 10 carbon atoms, more preferably 3 to 6 carbon atoms, still more preferably 3 or 4 carbon atoms, and most preferably 3 carbon atoms. The branched aliphatic hydrocarbon group is preferably a branched alkylene group, and specific examples thereof include alkylalkylene groups; for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. The alkyl group in the alkylalkylene group is preferably a linear alkyl group having 1 to 5 carbon atoms.

The cyclic hydrocarbon group as R¹⁰¹ may contain a hetero atom like a hetero ring or the like. Specific examples thereof include lactone-containing cyclic groups respectively represented by General Formulae (a2-r-1) to (a2-r-7), —SO₂— containing cyclic groups respectively represented by General Formulae (a5-r-1) to (a5-r-4), and other heterocyclic groups respectively represented by Chemical Formulae (r-hr-1) to (r-hr-16). In the formulae, * represents a bond that binds to Y¹⁰¹ in Formula (b-1).

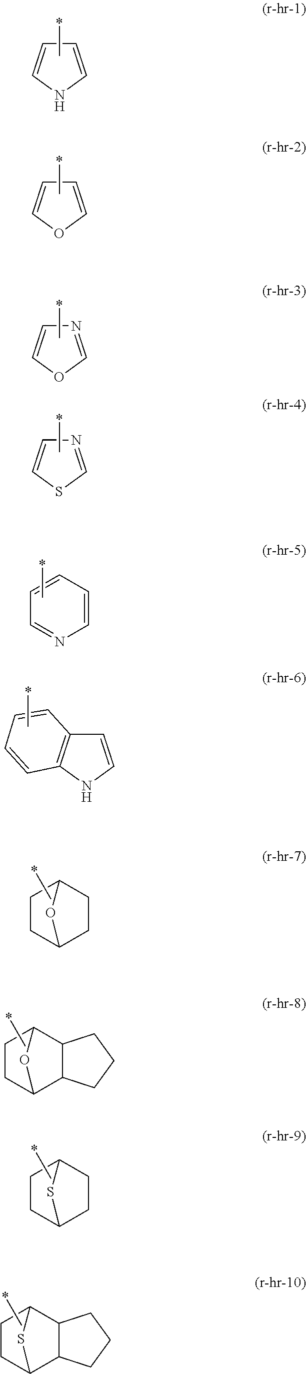

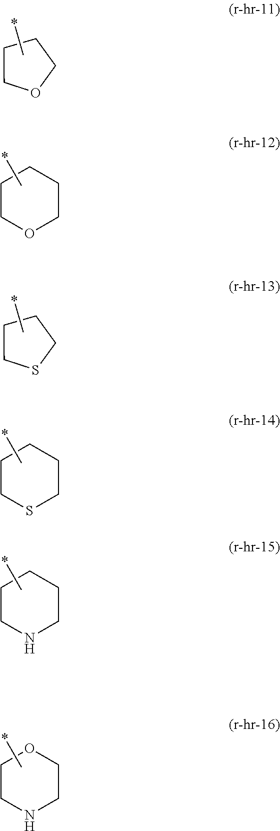

Examples of the substituent for the cyclic group as R¹⁰¹ include an alkyl group, an alkoxy group, a halogen atom, a halogenated alkyl group, a hydroxy group, a carbonyl group, and a nitro group. The alkyl group as the substituent is preferably an alkyl group having 1 to 5 carbon atoms, and a methyl group, an ethyl group, a propyl group, an n-butyl group, or a tert-butyl group is most preferable.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and most preferably a methoxy group or an ethoxy group.

The halogen atom as the substituent is preferably a fluorine atom.

Examples of the above-described halogenated alkyl group as the substituent include groups in which a part or all hydrogen atoms in an alkyl group having 1 to 5 carbon atoms such as a methyl group, an ethyl group, a propyl group, an n-butyl group, or a tert-butyl group have been substituted with the above-described halogen atoms.

The carbonyl group as the substituent is a group that is substituted for a methylene group (—CH₂—) constituting the cyclic hydrocarbon group.

The cyclic hydrocarbon group as R¹⁰¹ may be a condensed ring type group containing a condensed ring in which an aliphatic hydrocarbon ring and an aromatic ring are condensed. Examples of the condensed ring include condensed rings in which one or more aromatic rings are condensed with a polycycloalkane having a crosslinked ring-based polycyclic skeleton. Specific examples of the crosslinked ring-based polycycloalkane include bicycloalkanes such as bicyclo[2.2.1]heptane (norbornane) and bicyclo[2.2.2]octane. The condensed ring type group is preferably a group containing a condensed ring in which two or three aromatic rings are condensed with a bicycloalkane and more preferably a group containing a condensed ring in which two or three aromatic rings are condensed with bicyclo[2.2.2]octane. Specific examples of the condensed ring type group as R¹⁰¹ include those represented by Formulae (r-br-1) to (r-br-2). In the formulae, * represents a bond that binds to Y¹⁰¹ in Formula (b-1).

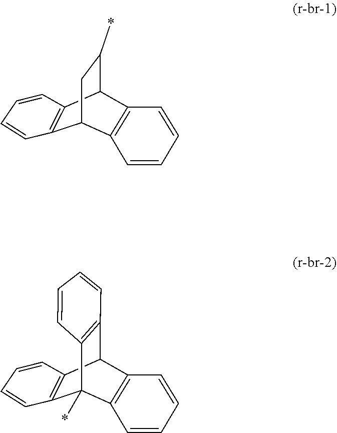 [SMILES: *C1CC2c3ccccc3C1c1ccccc12 ; *C12c3ccccc3C(c3ccccc31)c1ccccc12]

Examples of the substituent which the condensed ring type group as R¹⁰¹ may have include an alkyl group, an alkoxy group, a halogen atom, a halogenated alkyl group, a hydroxy group, a carbonyl group, a nitro group, an aromatic hydrocarbon group, and an alicyclic hydrocarbon group.

Examples of the alkyl group, the alkoxy group, the halogen atom, and the halogenated alkyl group, as the substituent for the condensed ring type group, include the same groups as those described as the substituent for the cyclic group as R¹⁰¹.

Examples of the aromatic hydrocarbon group as the substituent for the condensed ring type group include a group in which one hydrogen atom has been removed from the above-described aromatic ring (an aryl group, for example, a phenyl group and a naphthyl group), a group in which one hydrogen atom in the aromatic ring has been substituted with an alkylene group (for example, arylalkyl groups such as a benzyl group, a phenethyl group, a 1-naphthylmethyl group, a 2-naphthylmethyl group, 1-naphthylethyl group, and a 2-naphthylethyl group), and heterocyclic groups respectively represented by Formulae (r-hr-1) to (r-hr-6).

Examples of the alicyclic hydrocarbon group as the substituent for the condensed ring type group include: a group in which one hydrogen atom has been removed from monocycloalkanes such as cyclopentane and cyclohexane; a group in which one hydrogen atom has been removed from polycycloalkanes such as adamantane, norbomane, isobomane, tricyclodecane, and tetracyclodecane; lactone-containing cyclic groups respectively represented by General Formulae (a2-r-1) to (a2-r-7); —SO₂— containing cyclic groups respectively represented by General Formulae (a5-r-1) to (a5-r-4); and heterocyclic groups respectively represented by Formulae (r-hr-7) to (r-hr-16).

Chain-Like Alkyl Group which May have Substituent:

The chain-like alkyl group as R¹⁰¹ may be linear or branched.

The linear alkyl group has preferably 1 to 20 carbon atoms, more preferably 1 to 15 carbon atoms, and most preferably 1 to 10 carbon atoms.

The branched alkyl group has preferably 3 to 20 carbon atoms, more preferably 3 to 15, and most preferably 3 to 10. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

Chain-Like Alkenyl Group which May have Substituent:

A chain-like alkenyl group as R¹⁰¹ may be linear or branched, and the number of carbon atoms thereof is preferably 2 to 10, more preferably 2 to 5, still more preferably 2 to 4, and particularly preferably 3. Examples of the linear alkenyl group include a vinyl group, a 1-propenyl group, a 2-propenyl group (allyl group), and a butynyl group. Examples of the branched alkenyl group include a 1-methylvinyl group, a 1-methylpropenyl group, and a 2-methylpropenyl group.

Among the above, as the chain-like alkenyl group, a linear alkenyl group is preferable, a vinyl group or a propenyl group is more preferable, and a vinyl group is particularly preferable.

Examples of the substituent for the chain-like alkyl group or alkenyl group as R¹⁰¹ include an alkoxy group, a halogen atom, a halogenated alkyl group, a hydroxy group, a carbonyl group, a nitro group, an amino group, and a cyclic group as R¹⁰¹.

Among the above, R¹⁰¹ is preferably a cyclic group which may have a substituent and more preferably a cyclic hydrocarbon group which may have a substituent. More specifically, groups in which one or more hydrogen atoms have been removed from a phenyl group, a naphthyl group, or a polycycloalkane, lactone-containing cyclic groups respectively represented by General Formulae (a2-r-1) to (a2-r-7), and —SO₂— containing cyclic groups respectively represented by General Formulae (a5-r-1) to (a5-r-4) are preferable.

In Formula (b-1), Y¹⁰¹ represents a single bond or a divalent linking group containing an oxygen atom.

In a case where Y¹⁰¹ represents a divalent linking group containing an oxygen atom, Y¹⁰¹ may contain an atom other than an oxygen atom. Examples of the atom other than an oxygen atom include a carbon atom, a hydrogen atom, a sulfur atom, and a nitrogen atom.

Examples of the divalent linking group containing an oxygen atom include: non-hydrocarbon-based oxygen atom-containing linking groups such as an oxygen atom (an ether bond; —O—), an ester bond (—C(═O)—O—), an oxycarbonyl group (—O—C(═O)—), an amide bond (—C(═O)—NH—), a carbonyl group (—C(═O)—), and a carbonate bond (—O—C(═O)—O—); and a combination of the non-hydrocarbon-based oxygen atom-containing linking groups and an alkylene group. A sulfonyl group (—SO₂—) may be further linked to this combination. Examples of the divalent linking group containing an oxygen atom include linking groups respectively represented by General Formulae (y-a1-1) to (y-a1-7).

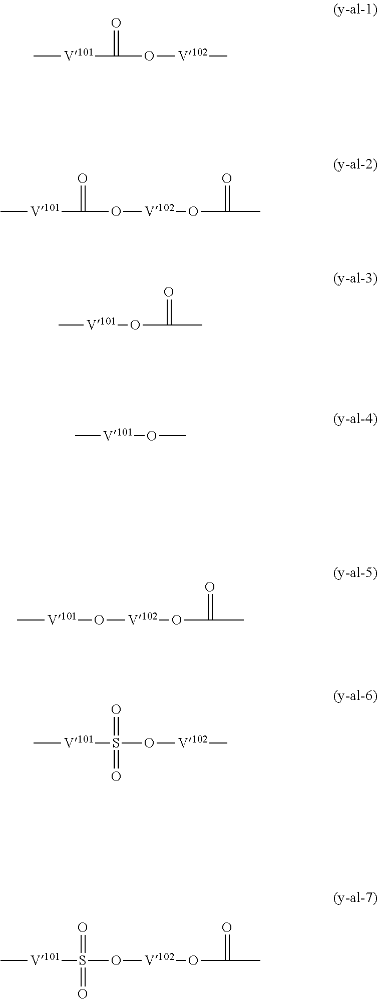

[In the formulae, V′¹⁰¹ represents a single bond or an alkylene group having 1 to 5 carbon atoms, and V′¹⁰² represents a divalent saturated hydrocarbon group having 1 to 30 carbon atoms.]

The divalent saturated hydrocarbon group as V′¹⁰² is preferably an alkylene group having 1 to 30 carbon atoms, more preferably an alkylene group having 1 to 10 carbon atoms, and still more preferably an alkylene group having 1 to 5 carbon atoms.

The alkylene group as V′¹⁰¹ and V′¹⁰² may be a linear alkylene group or a branched alkylene group, and preferably a linear alkylene group.

Specific examples of the alkylene group as V′¹⁰¹ and V′¹⁰² include a methylene group [—CH₂—]; an alkylmethylene group such as —CH(CH₃)—, —CH(CH₂CH₃)—, —C(CH₃)₂—, —C(CH₃)(CH₂CH₃)—, —C(CH₃)(CH₂CH₂CH₃)—, or —C(CH₂CH₃)₂—; an ethylene group [—CH₂CH₂—]: an alkylethylene group such as —CH(CH₃)CH₂—, —CH(CH₃)CH(CH₃)—, —C(CH₃)₂CH₂—, or —CH(CH₂CH₃)CH₂—; a trimethylene group (n-propylene group) [—CH₂CH₂CH₂—]; an alkyltrimethylene group such as —CH(CH₃)CH₂CH₂— or —CH₂CH(CH₃)CH₂—; a tetramethylene group [—CH₂CH₂CH₂CH₂—]; an alkyltetramethylene group such as —CH(CH₃)CH₂CH₂CH₂—, —CH₂CH(CH₃)CH₂CH₂—; and a pentamethylene group [—CH₂CH₂CH₂CH₂CH₂—].

Further, a part of methylene groups in the alkylene group as V′¹⁰¹ and V′¹⁰² may be substituted with a divalent aliphatic cyclic group having 5 to 10 carbon atoms. The aliphatic cyclic group is preferably a divalent group in which one hydrogen atom has been removed from the cyclic aliphatic hydrocarbon group (a monocyclic aliphatic hydrocarbon group or a polycyclic aliphatic hydrocarbon group) as Ra′³ in Formula (a1-r-1), and more preferably a cyclohexylene group, a 1,5-adamantylene group, or a 2,6-adamantylene group.

Y¹⁰¹ represents preferably a divalent linking group containing an ester bond or a divalent linking group containing an ether bond and more preferably linking groups respectively represented by Formulae (y-a1-1) to (y-a1-5).

In Formula (b-1), V ° 1 represents a single bond, an alkylene group, or a fluorinated alkylene group. The alkylene group and the fluorinated alkylene group as V¹⁰¹ preferably have 1 to 4 carbon atoms. Examples of the fluorinated alkylene group as V¹⁰¹ include groups in which a part or all hydrogen atoms in the alkylene group as V¹⁰¹ have been substituted with fluorine atoms. Among them, V¹⁰¹ is preferably a single bond or a fluorinated alkylene group having 1 to 4 carbon atoms.

In Formula (b-1), R¹⁰² represents a fluorine atom or a fluorinated alkyl group having 1 to 5 carbon atoms. R¹⁰² represents preferably a fluorine atom or a perfluoroalkyl group having 1 to 5 carbon atoms and more preferably a fluorine atom.

Specific examples of the anion moiety represented by Formula (b-1) include: in a case where Y¹⁰¹ represents a single bond, fluorinated alkylsulfonate anions such as a trifluoromethanesulfonate anion and a perfluorobutanesulfonate anion; and in a case where Y¹⁰¹ represents a divalent linking group containing an oxygen atom, anions represented by Formulae (an-1) to (an-3).

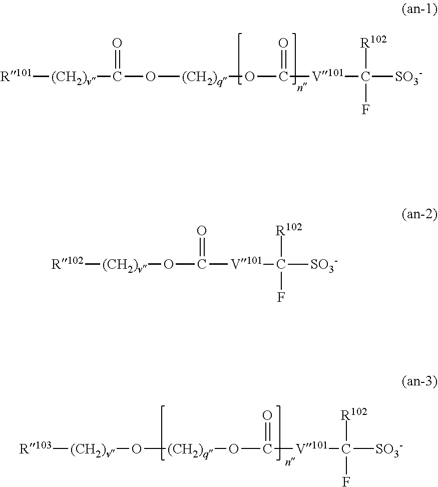

[In the formula, R″¹⁰¹ represents an aliphatic cyclic group which may have a substituent, monovalent heterocyclic groups respectively represented by Chemical Formulae (r-hr-1) to (r-hr-6), a condensed ring type group represented by Formula (r-br-1) or (r-br-2), and a chain-like alkyl group which may have a substituent. R″¹⁰² is an aliphatic cyclic group which may have a substituent, a condensed ring type group represented by Formula (r-br-1) or (r-br-2), lactone-containing cyclic groups respectively represented by General Formulae (a2-r-1), (a2-r-3) to (a2-r-7), or —SO₂— containing cyclic groups respectively represented by General Formulae (a5-r-1) to (a5-r-4). R″¹⁰³ represents an aromatic cyclic group which may have a substituent, an aliphatic cyclic group which may have a substituent, or a chain-like alkenyl group which may have a substituent. V″¹⁰¹ represents a single bond, an alkylene group having 1 to 4 carbon atoms, or a fluorinated alkylene group having 1 to 4 carbon atoms. R¹⁰² represents a fluorine atom or a fluorinated alkyl group having 1 to 5 carbon atoms. v″ each independently represents an integer of 0 to 3, q″ each independently represents an integer of 0 to 20, and n″ represents 0 or 1.]

The aliphatic cyclic group as R″¹⁰¹, R″¹⁰², and R″¹⁰³ which may have a substituent is preferably a group exemplified as the cyclic aliphatic hydrocarbon group as R¹⁰¹ in Formula (b-1). Examples of the substituent include the same groups as the substituent with which the cyclic aliphatic hydrocarbon group as R¹⁰¹ in Formula (b-1) may be substituted.

The aromatic cyclic group as R″¹⁰³, which may have a substituent, is preferably a group exemplified as the aromatic hydrocarbon group for the cyclic hydrocarbon group, as R¹⁰¹ in Formula (b-1). Examples of the substituent include the same group as the substituent with which the aromatic hydrocarbon group as R¹⁰¹ in Formula (b-1) may be substituted.

The chain-like alkyl group as R″¹⁰¹ which may have a substituent is preferably a group exemplified as the chain-like alkyl group as R¹⁰¹ in Formula (b-1).

The chain-like alkenyl group as R″¹⁰³ which may have a substituent is preferably a group exemplified as the chain-like alkenyl group as R¹⁰¹ in Formula (b-1).

Anion in component (b-2) In Formula (b-2), R¹⁰⁴ and R¹⁰⁵ each independently represent a cyclic group which may have a substituent, a chain-like alkyl group which may have a substituent, or a chain-like alkenyl group which may have a substituent, and R¹⁰⁴ and R¹⁰⁵ each have the same definition as that for R¹⁰¹ in Formula (b-1). R¹⁰⁴ and R¹⁰⁵ may be bonded to each other to form a ring.

As R¹⁰⁴ and R¹⁰⁵, a chain-like alkyl group which may have a substituent is preferable, and a linear or branched alkyl group or a linear or branched fluorinated alkyl group is more preferable.

The chain-like alkyl group has preferably 1 to 10 carbon atoms, more preferably 1 to 7 carbon atoms, and still more preferably 1 to 3 carbon atoms. It is preferable that the number of carbon atoms in the chain-like alkyl group as R¹⁰⁴ and R¹⁰⁵ is small because the solubility in a solvent for a resist is also excellent in the range of the number of carbon atoms. Further, in the chain-like alkyl group as R¹⁰⁴ and R¹⁵, it is preferable that the number of hydrogen atoms substituted with fluorine atoms is large because the acid strength increases and the transparency to high energy radiation of 250 nm or less or electron beams is improved. The proportion of fluorine atoms in the chain-like alkyl group, that is, the fluorination ratio is preferably 70% to 100% and more preferably 90% to 100%, and it is most preferable that the chain-like alkyl group is a perfluoroalkyl group in which all hydrogen atoms are substituted with fluorine atoms.

In Formula (b-2), V¹⁰² and V¹⁰³ each independently represent a single bond, an alkylene group, or a fluorinated alkylene group, and V¹⁰² and V¹⁰³ each have the same definition as that for V¹⁰¹ in Formula (b-1).

In Formula (b-2), L¹⁰¹ and L¹⁰² each independently represent a single bond or an oxygen atom.

Anion in Component (b-3)

In Formula (b-3), R¹⁰⁶ to R¹⁰⁸ each independently represent a cyclic group which may have a substituent, a chain-like alkyl group which may have a substituent, or a chain-like alkenyl group which may have a substituent, and each example thereof is the same as R¹⁰¹ in Formula (b-1).

In Formula (b-3), L¹⁰³ to L¹⁰⁵ each independently represent a single bond, —CO—, or —SO₂—.

Among the above, the anion moiety of the component (B) is preferably an anion in the component (b-1). Among these, an anion represented by anyone of General Formulae (an-1) to (an-3) is preferable, an anion represented by any one of General Formula (an-1) or (an-2) is more preferable, and an anion represented by General Formula (an-2) is particularly preferable.

{Cation Moiety}

In Formulae (b-1), (b-2), and (b-3), M′^{m+} represents an m-valent onium cation. Among these, a sulfonium cation and an iodonium cation are preferable. m represents an integer of 1 or more.

Examples of the preferred cation moiety ((M′^{m+})_{1/m}) include organic cations respectively represented by General Formulae (ca-1) to (ca-5).

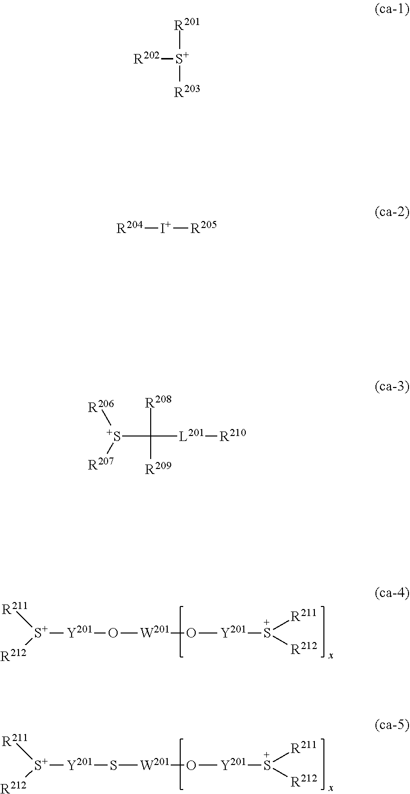

[In the formula, R²⁰¹ to R²⁰⁷ and R²¹¹ to R²¹² each independently represent an aryl group, an alkyl group, or an alkenyl group, which may have a substituent. R²⁰¹ to R²⁰³, R²⁰⁶ to R²⁰⁷, and R²¹¹ to R²¹² may be bonded to each other to form a ring together with the sulfur atoms in the formulae. R²⁰⁸ and R²⁰⁹ each independently represent a hydrogen atom or an alkyl group having 1 to 5 carbon atoms. R²¹⁰ represents an aryl group which may have a substituent, an alkyl group which may have a substituent, an alkenyl group which may have a substituent, or a —SO₂— containing cyclic group which may have a substituent. L²⁰¹ represents —C(═O)— or —C(═O)—O—. Each Y²⁰¹ independently represent an arylene group, an alkylene group, or an alkenylene group. x represents 1 or 2. W²⁰¹ represents an (x+1)-valent linking group.]

In General Formulae (ca-1) to (ca-5), examples of the aryl group as R²⁰¹ to R²⁰⁷, R²¹¹, and R²¹² include an unsubstituted aryl group having 6 to 20 carbon atoms, and a phenyl group or a naphthyl group is preferable.

The alkyl group as R²⁰¹ to R²⁰⁷, R²¹¹, and R²¹² is a chain-like or cyclic alkyl group, and the number of carbon atoms thereof is preferably 1 to 30.

The alkenyl group as R²⁰¹ to R²⁰⁷, R²¹¹, and R²¹² preferably has 2 to 10 carbon atoms.

Examples of the substituent which R²⁰¹ to R²⁰⁷ and R²¹⁰ to R²¹² may have include an alkyl group, a halogen atom, a halogenated alkyl group, a carbonyl group, a cyano group, an amino group, an aryl group, and groups respectively represented by General Formulae (ca-r-1) to (ca-r-7).

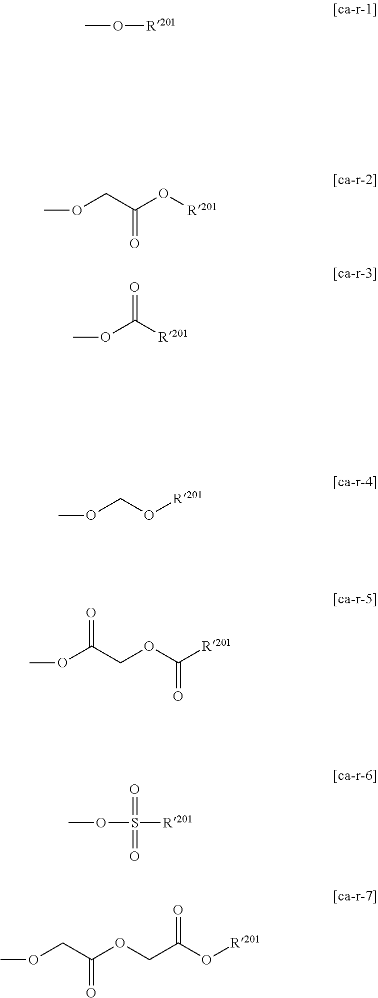

[In the formulae, R′²⁰¹ s each independently represent a hydrogen atom, a cyclic group which may have a substituent, a chain-like alkyl group which may have a substituent, or a chain-like alkenyl group which may have a substituent.]

Cyclic Group which May have Substituent:

The cyclic group is preferably a cyclic hydrocarbon group, and the cyclic hydrocarbon group may be an aromatic hydrocarbon group or an aliphatic hydrocarbon group. The aliphatic hydrocarbon group indicates a hydrocarbon group that has no aromaticity. The aliphatic hydrocarbon group may be saturated or unsaturated. In general, it is preferable that the aliphatic hydrocarbon group is saturated.

The aromatic hydrocarbon group as R′²⁰¹ is a hydrocarbon group having an aromatic ring. The aromatic hydrocarbon group has preferably 3 to 30 carbon atoms, more preferably 5 to 30 carbon atoms, still more preferably 5 to 20 carbon atoms, particularly preferably 6 to 15 carbon atoms, and most preferably 6 to 10 carbon atoms. However, the number of carbon atoms in a substituent is not included in the number of carbon atoms.

Specific examples of the aromatic ring which the aromatic hydrocarbon group has as R′²⁰¹ include benzene, fluorene, naphthalene, anthracene, phenanthrene, biphenyl, and an aromatic hetero ring in which a part of carbon atoms constituting any of these aromatic rings have been substituted with hetero atoms. Examples of the hetero atom in the aromatic hetero rings include an oxygen atom, a sulfur atom, and a nitrogen atom.

Specific examples of the aromatic hydrocarbon group as R′²⁰¹ include a group in which one hydrogen atom has been removed from the above-described aromatic ring (an aryl group, for example, a phenyl group and a naphthyl group) and a group in which one hydrogen atom in the aromatic ring has been substituted with an alkylene group (for example, arylalkyl groups such as a benzyl group, a phenethyl group, a 1-naphthylmethyl group, a 2-naphthylmethyl group, 1-naphthylethyl group, and a 2-naphthylethyl group). The alkylene group (an alkyl chain in the arylalkyl group) has preferably 1 to 4 carbon atoms, more preferably 1 or 2 carbon atoms, and particularly preferably 1 carbon atom.

Examples of the cyclic aliphatic hydrocarbon group as R′²⁰¹ include an aliphatic hydrocarbon group containing a ring in the structure thereof.

Examples of the aliphatic hydrocarbon group containing a ring in the structure thereof include an alicyclic hydrocarbon group (a group in which one hydrogen atom has been removed from an aliphatic hydrocarbon ring), a group in which the alicyclic hydrocarbon group is bonded to the terminal of a linear or branched aliphatic hydrocarbon group, and a group in which the alicyclic hydrocarbon group is interposed in a linear or branched aliphatic hydrocarbon group.

The alicyclic hydrocarbon group has preferably 3 to 20 carbon atoms and more preferably 3 to 12 carbon atoms.

The alicyclic hydrocarbon group may be a polycyclic group or a monocyclic group. The monocyclic alicyclic hydrocarbon group is preferably a group in which one or more hydrogen atoms have been removed from a monocycloalkane. The monocycloalkane has preferably 3 to 6 carbon atoms, and specific examples thereof include cyclopentane and cyclohexane. The polycyclic alicyclic hydrocarbon group is preferably a group in which one or more hydrogen atoms have been removed from a polycycloalkane, and the number of carbon atoms of the polycycloalkane is preferably 7 to 30. Among them, the polycycloalkane is more preferably polycycloalkanes having a crosslinked ring-based polycyclic skeleton, such as adamantane, norbornane, isobornane, tricyclodecane, and tetracyclododecane, and polycycloalkanes having a condensed ring-based polycyclic skeleton, such as a cyclic group having a steroid skeleton.

Among them, the cyclic aliphatic hydrocarbon group as R′²⁰¹ is preferably a group in which one or more hydrogen atoms have been removed from a monocycloalkane or a polycycloalkane, more preferably a group in which one hydrogen atom has been removed from a polycycloalkane, particularly preferably an adamantyl group or a norbornyl group, and most preferably an adamantyl group.

The linear or branched aliphatic hydrocarbon group which may be bonded to the alicyclic hydrocarbon group has preferably 1 to 10 carbon atoms, more preferably 1 to 6 carbon atoms, still more preferably 1 to 4 carbon atoms, and particularly preferably 1 to 3 carbon atoms.

The linear aliphatic hydrocarbon group is preferably a linear alkylene group, and specific examples thereof include a methylene group [—CH₂—], an ethylene group [—(CH₂)₂—], a trimethylene group [—(CH₂)₃-], a tetramethylene group [—(CH₂)₄-], and a pentamethylene group [—(CH₂)₅-].

The branched aliphatic hydrocarbon group is preferably a branched alkylene group, and specific examples thereof include alkylalkylene groups; for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. The alkyl group in the alkylalkylene group is preferably a linear alkyl group having 1 to 5 carbon atoms.

The cyclic hydrocarbon group as R′201 may contain a hetero atom like a hetero ring or the like. Specific examples thereof include lactone-containing cyclic groups respectively represented by General Formulae (a2-r-1) to (a2-r-7), —SO₂— containing cyclic groups respectively represented by General Formulae (a5-r-1) to (a5-r-4), and other heterocyclic groups respectively represented by Chemical Formulae (r-hr-1) to (r-hr-16).

Examples of the substituent for the cyclic group as R′²⁰¹ include an alkyl group, an alkoxy group, a halogen atom, a halogenated alkyl group, a hydroxy group, a carbonyl group, and a nitro group.

The alkyl group as the substituent is preferably an alkyl group having 1 to 5 carbon atoms, and a methyl group, an ethyl group, a propyl group, an n-butyl group, or a tert-butyl group is most preferable.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and most preferably a methoxy group or an ethoxy group.

The halogen atom as the substituent is preferably a fluorine atom.

Examples of the above-described halogenated alkyl group as the substituent include groups in which a part or all hydrogen atoms in alkyl groups having 1 to 5 carbon atoms such as a methyl group, an ethyl group, a propyl group, an n-butyl group, and a tert-butyl group have been substituted with the above-described halogen atoms.

The carbonyl group as the substituent is a group that is substituted for a methylene group (—CH₂—) constituting the cyclic hydrocarbon group.

Chain-like alkyl group which may have substituent:

The chain-like alkyl group as R′²⁰¹ may be linear or branched.

The linear alkyl group has preferably 1 to 20 carbon atoms, more preferably 1 to 15 carbon atoms, and most preferably 1 to 10 carbon atoms.

The branched alkyl group has preferably 3 to 20 carbon atoms, more preferably 3 to 15 carbon atoms, and most preferably 3 to 10 carbon atoms. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

Chain-like alkenyl group which may have substituent:

The chain-like alkenyl group as R′²⁰¹ may be linear or branched, and has preferably 2 to 10 carbon atoms, more preferably 2 to 5 carbon atoms, still more preferably 2 to 4 carbon atoms, and particularly preferably 3 carbon atoms. Examples of the linear alkenyl group include a vinyl group, a 1-propenyl group, a 2-propenyl group (allyl group), and a butynyl group. Examples of the branched alkenyl group include a 1-methylvinyl group, a 1-methylpropenyl group, and a 2-methylpropenyl group.

Among the above, as the chain-like alkenyl group, a linear alkenyl group is preferable, a vinyl group or a propenyl group is more preferable, and a vinyl group is particularly preferable.

Examples of the substituent for the chain-like alkyl group or alkenyl group as R′²⁰¹ include an alkoxy group, a halogen atom, a halogenated alkyl group, a hydroxy group, a carbonyl group, a nitro group, an amino group, and a cyclic group as R′201.

Examples of the cyclic group which may have a substituent, the chain-like alkyl group which may have a substituent, or the chain-like alkenyl group which may have a substituent, as R′²⁰¹ include the same groups as the acid dissociable groups represented by Formula (a1-r-2), as the cyclic group which may have a substituent or the chain-like alkyl group which may have a substituent, in addition to the groups described above.

Among them, R′²⁰¹ is preferably a cyclic group which may have a substituent and more preferably a cyclic hydrocarbon group which may have a substituent. More specifically, groups in which one or more hydrogen atoms have been removed from a phenyl group, a naphthyl group, or a polycycloalkane; lactone-containing cyclic groups respectively represented by General Formulae (a2-r-1) to (a2-r-7); and —SO₂— containing cyclic groups respectively represented by General Formulae (a5-r-1) to (a5-r-4) are preferable.

In General Formula (ca-1) to (ca-5), the substituent which R²⁰¹ to R²⁰⁷ and R²¹⁰ to R²¹² may have is preferably, among the above, an electron-withdrawing group. The electron-withdrawing group may be one kind or two or more kinds.

Examples of the electron-withdrawing group include an acyl group, a methanesulfonyl group (mesyl group), a halogen atom, a halogenated alkyl group, a halogenated alkoxy group, a halogenated aryloxy group halide, a halogenated alkylamino group, a halogenated alkylthio group, a cyano group, a nitro group, a dialkylphosphono group, a diarylphosphono group, an alkylsulfonyl group, an arylsulfonyl group, a sulfonyloxy group, an acylthio group, a sulfamoyl group, a thiocianate group, and a thiocarbonyl group.

Among the above, a fluorine atom or a fluorinated alkyl group is preferable from the viewpoint of increasing sensitivity. The fluorinated alkyl group is preferably a fluorinated alkyl group having 1 to 5 carbon atoms.

In a case where the electron-withdrawing group is a fluorine atom or a fluorinated alkyl group, the number of fluorine atoms in the cation moiety of the component (B) is preferably 1 to 9, more preferably 2 to 6, and still more preferably 3 or 4.

The more the fluorine atoms are, the better the sensitivity is. However, in a case where the number of fluorine atoms is equal to or smaller than the upper limit of the preferred range, the solubility of the resist composition with each component in the developing solution is maintained, and the worsening of roughness is easily suppressed.

In General Formulae (ca-1) to (ca-5), in a case where R²⁰¹ to R²⁰³, R²⁰⁶ and R²⁰⁷, and R²¹ and R²¹² are bonded to each other to form a ring together with a sulfur atom in the formula, these groups may be bonded through a hetero atom such as a sulfur atom, an oxygen atom or a nitrogen atom, or a functional group such as a carbonyl group, —SO—, —SO₂—, —SO₃—, —COO—, —CONH— or —N(RN)— (here, RN represents an alkyl group having 1 to 5 carbon atoms). As the ring to be formed, a ring containing the sulfur atom in the formula in the ring skeleton thereof is preferably a 3- to 10-membered ring and particularly preferably a 5- to 7-membered ring, including the sulfur atom. Specific examples of the ring to be formed include a thiophene ring, a thiazole ring, a benzothiophene ring, a dibenzothiophene ring, a 9H-thioxanthene ring, a thioxanthone ring, a thianthrene ring, a phenoxathiin ring, a tetrahydrothiophenium ring, and a tetrahydrothiopyranium ring.

R²⁰⁸ and R²⁰⁹ each independently represent a hydrogen atom or an alkyl group having 1 to 5 carbon atoms and are preferably a hydrogen atom or an alkyl group having 1 to 3 carbon atoms. In a case where R²⁰⁸ and R²⁰⁹ each independently represent an alkyl group, R²⁰⁸ and R²⁰⁹ may be bonded to each other to form a ring.

R²¹⁰ represents an aryl group which may have a substituent, an alkyl group which may have a substituent, an alkenyl group which may have a substituent, or a —SO₂— containing cyclic group which may have a substituent.

Examples of the aryl group as R²¹⁰ include an unsubstituted aryl group having 6 to 20 carbon atoms, and a phenyl group or a naphthyl group is preferable.

The alkyl group as R²¹⁰ is preferably a chain-like or cyclic alkyl group having 1 to 30 carbon atoms.

The alkenyl group as R²¹⁰ preferably has 2 to 10 carbon atoms. The —SO₂— containing cyclic group which may have a substituent, as R²¹⁰, is preferably a “—SO₂— containing polycyclic group” and more preferably a group represented by General Formula (a5-r-1).

Each Y²⁰¹ independently represent an arylene group, an alkylene group, or an alkenylene group.

Examples of the arylene group as Y²⁰¹ include groups in which one hydrogen atom has been removed from an aryl group mentioned as the aromatic hydrocarbon group represented by R¹⁰¹ in Formula (b-1) described above.

Examples of the alkylene group and alkenylene group as Y²⁰¹ include groups in which one hydrogen atom has been removed from the chain-like alkyl group or the chain-like alkenyl group as R¹⁰¹ in Formula (b-1) described above.

In Formula (ca-4), x represents 1 or 2.

W²⁰¹ represents an (x+1)-valent linking group, that is, a divalent or trivalent linking group.

The divalent linking group as W²⁰¹ is preferably a divalent hydrocarbon group which may have a substituent, and an example thereof include the same divalent hydrocarbon group (which may have a substituent) as Ya²¹ in General Formula (a2-1) described above. The divalent linking group as W²⁰¹ may be linear, branched, or cyclic, and preferably cyclic. Among them, a group in which two carbonyl groups are combined at both terminals of an arylene group is preferable. Examples of the arylene group include a phenylene group and a naphthylene group, and a phenylene group is particularly preferable.

Examples of the trivalent linking group as W²⁰¹ include a group in which one hydrogen atom has been removed from the above-described divalent linking group as W²⁰¹ and a group in which the divalent linking group has been bonded to another divalent linking group. The trivalent linking group as W²⁰¹ is preferably a group in which two carbonyl groups are bonded to an arylene group.

Suitable examples of the cation represented by Formula (ca-1) are as follows.

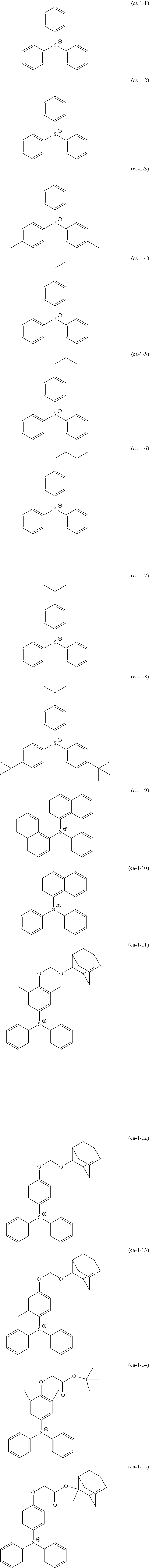

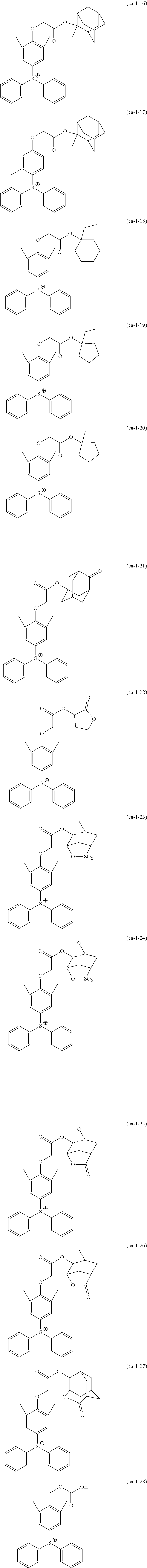

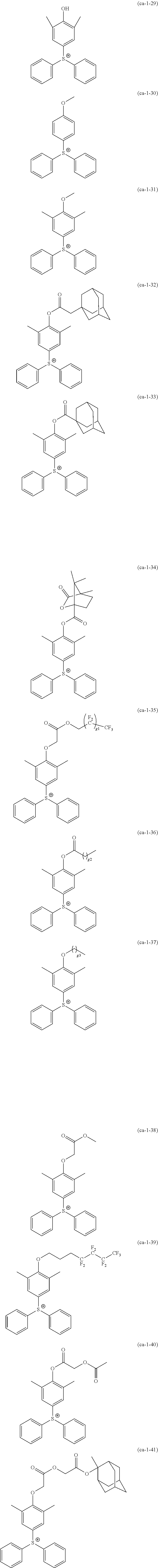

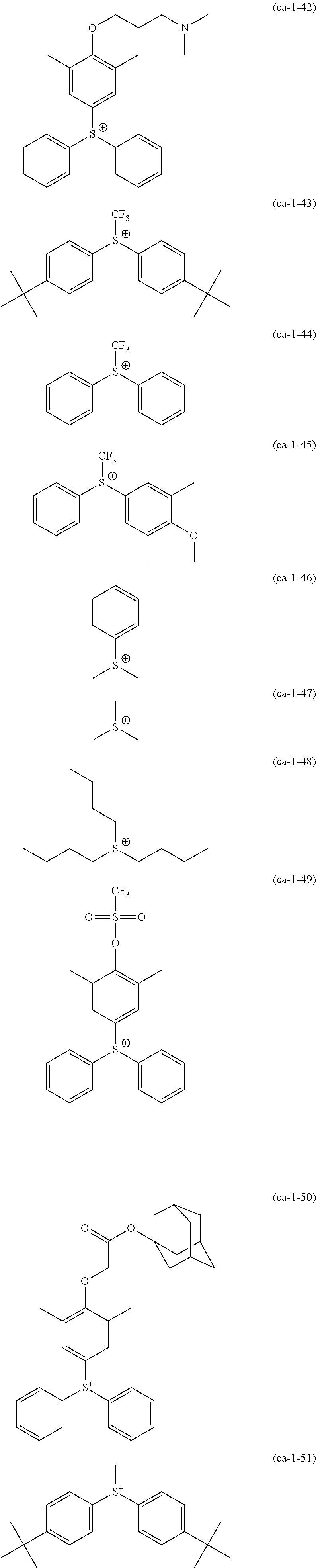

[In the formula, g1, g2, and g3 represent the numbers of repetitions, g1 represents an integer of 1 to 5, g2 represents an integer of 0 to 20, and g3 represents an integer of 0 to 20.]

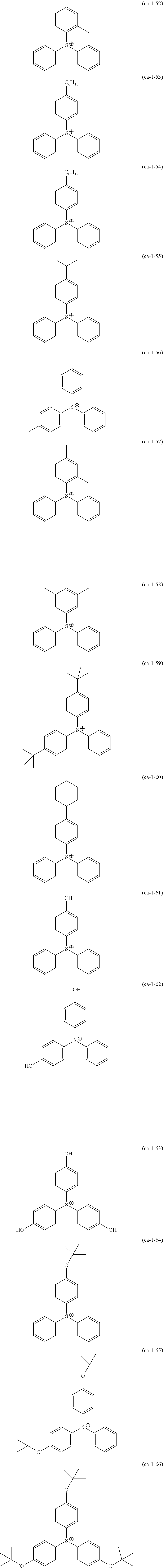

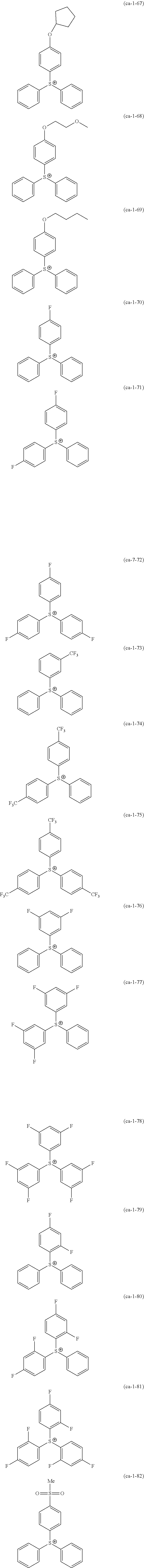

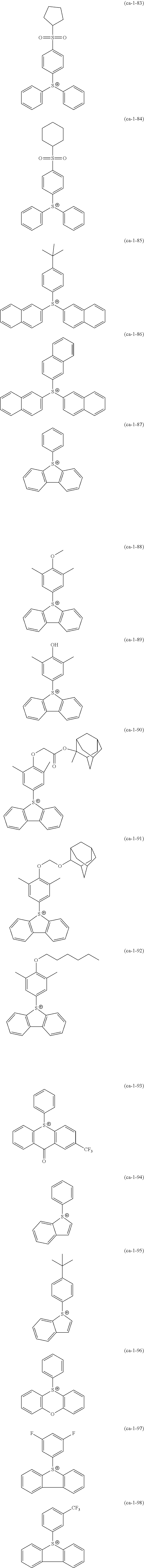

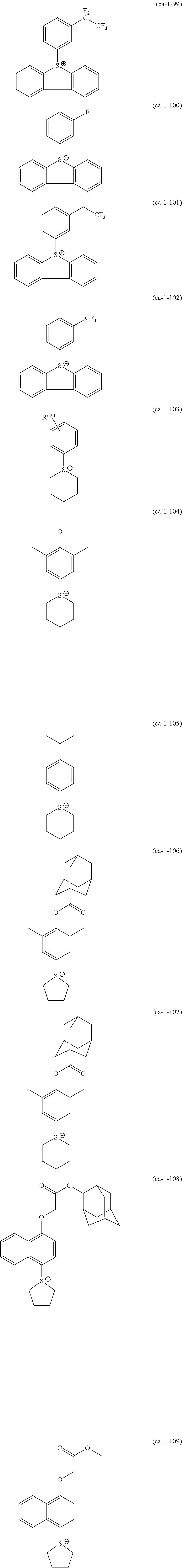

[In the formula, R″²⁰¹ represents a hydrogen atom or a substituent, and the substituent is the same as that mentioned as the substituent that R²⁰¹ to R²⁰⁷ and R²¹⁰ to R²¹² may have.]

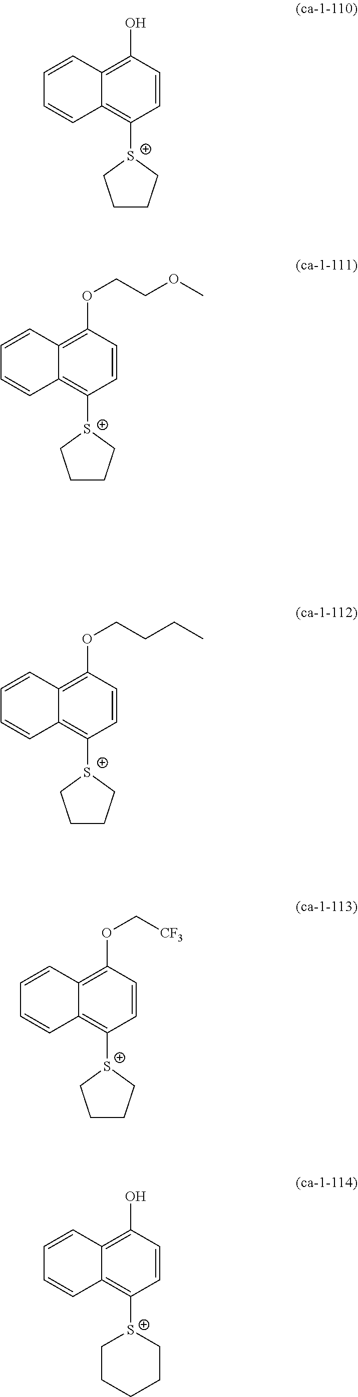 [SMILES: Oc1ccc([S+]2CCCC2)c2ccccc12 ; COCCOc1ccc([S+]2CCCC2)c2ccccc12 ; CCCCOc1ccc([S+]2CCCC2)c2ccccc12 ; FC(F)(F)COc1ccc([S+]2CCCC2)c2ccccc12 ; Oc1ccc([S+]2CCCCC2)c2ccccc12]

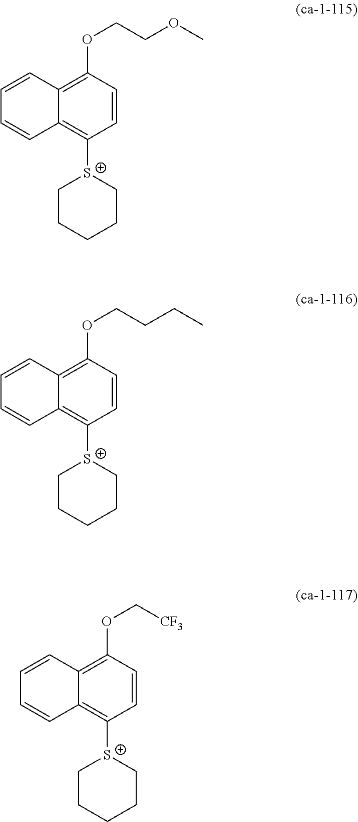 [SMILES: COCCOc1ccc([S+]2CCCCC2)c2ccccc12 ; CCCCOc1ccc([S+]2CCCCC2)c2ccccc12 ; FC(F)(F)COc1ccc([S+]2CCCCC2)c2ccccc12]

Specific examples of the suitable cation represented by Formula (ca-2) include a diphenyliodonium cation and a bis(4-tert-butylphenyl)iodonium cation.

Specific examples of the suitable cation represented by Formula (ca-3) include cations respectively represented by Formulae (ca-3-1) and (ca-3-6).

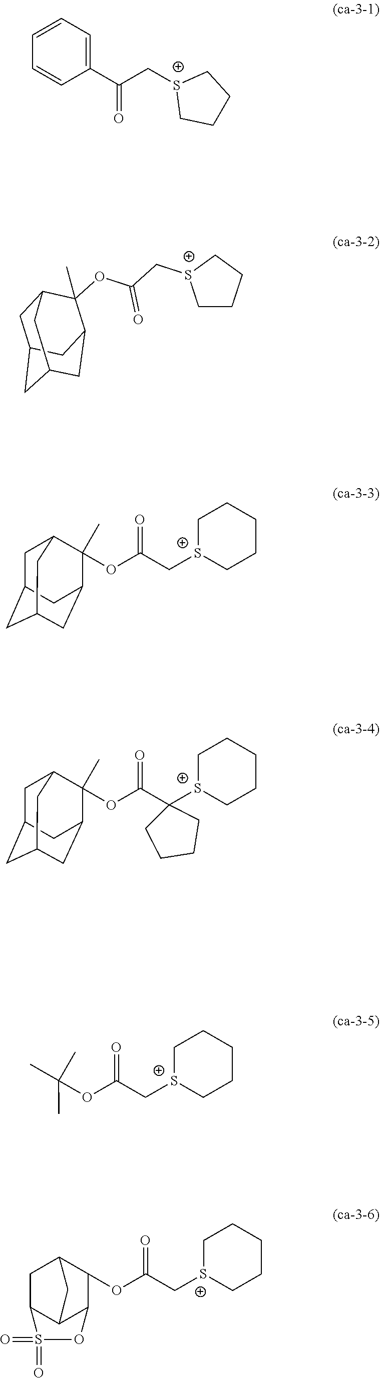 [SMILES: O=C(C[S+]1CCCC1)c1ccccc1 ; CC1(OC(=O)C[S+]2CCCC2)C2CC3CC(C2)CC1C3 ; CC1(OC(=O)C[S+]2CCCCC2)C2CC3CC(C2)CC1C3 ; CC1(OC(=O)C2([S+]3CCCCC3)CCCC2)C2CC3CC(C2)CC1C3 ; CC(C)(C)OC(=O)C[S+]1CCCCC1 ; O=C(C[S+]1CCCCC1)OC1C2CC3C1OS(=O)(=O)C3C2]

Specific examples of the suitable cation represented by Formula (ca-4) include cations respectively represented by Formulae (ca-4-1) and (ca-4-2).

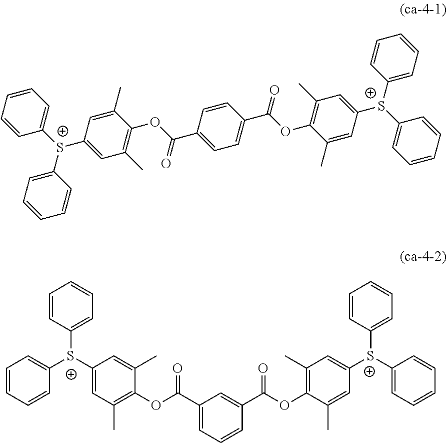 [SMILES: Cc1cc([S+](c2ccccc2)c2ccccc2)cc(C)c1OC(=O)c1ccc(C(=O)Oc2c(C)cc([S+](c3ccccc3)c3ccccc3)cc2C)cc1 ; Cc1cc([S+](c2ccccc2)c2ccccc2)cc(C)c1OC(=O)c1cccc(C(=O)Oc2c(C)cc([S+](c3ccccc3)c3ccccc3)cc2C)c1]

Specific examples of the suitable cation represented by Formula (ca-5) include cations respectively represented by General Formulae (ca-5-1) to (ca-5-3).

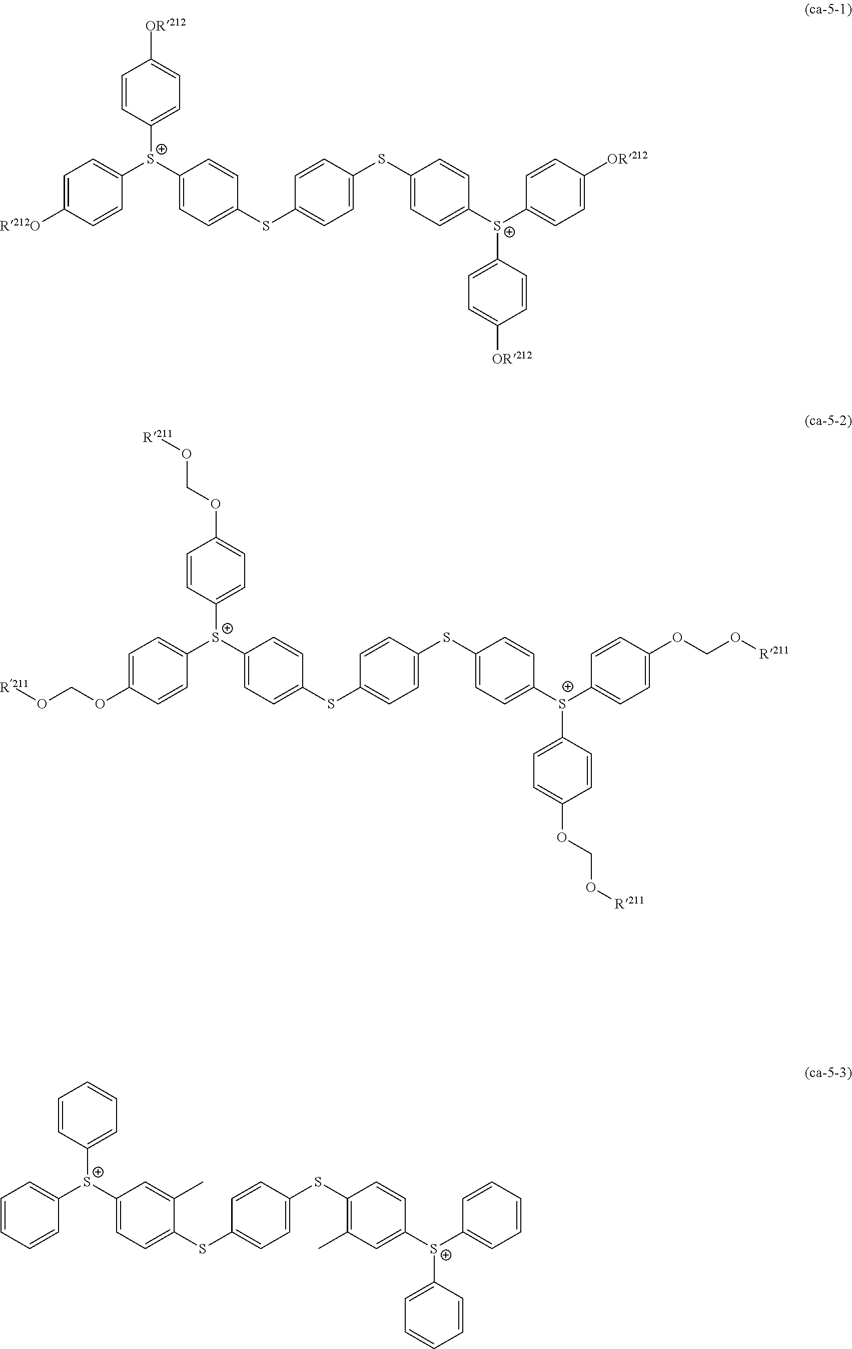

In the resist composition of the present embodiment, the cation moiety of the component (B) is preferably an organic cation having an electron-withdrawing group and more preferably an organic cation having an electron-withdrawing group in any one of organic cations respectively represented by General Formulae (ca-1) to (ca-5).

In the resist composition of the present embodiment, the cation moiety of the component (B) is preferably, among the above, a cation represented by General Formula (ca-1), which has an electron-withdrawing group. That is, a cation represented by any one of Chemical Formulae (ca-1-43) to (ca-1-45), (ca-1-70) to (ca-1-84), and (ca-1-97) to (ca-1-102) is preferable, and a cation represented by Chemical Formula (ca-1-72), (ca-1-73), or (ca-1-98) is more preferable.

In the resist composition of the present embodiment, the component (B) is preferably, among the above, a compound represented by General Formula (b-1-1) (hereinafter, also referred to as “component (b-1-1)”).

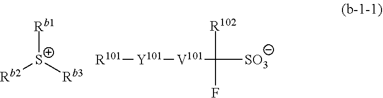

[In the formula, R^{b1} represents an aryl group having an electron-withdrawing group. R^{b2} and R^{b3} each independently represent an aryl group which may independently have a substituents, or R^{b2} and R^{b3} are bonded to each other to form a ring together with the sulfur atom in the formula. R¹⁰¹ represents a cyclic group which may have a substituent, a chain-like alkyl group which may have a substituent, or a chain-like alkenyl group which may have a substituent. R¹⁰² represents a fluorinated alkyl group having 1 to 5 carbon atoms or a fluorine atom. Y¹⁰¹ represents a divalent linking group containing an oxygen atom or a single bond. V ° 1 represents a single bond or an oxygen atom.]

{Anion Moiety in Component (b-1-1)}

The anion moiety in the component (b-1-1) is the same as the anion in the component (b-1) described above.

{Cation Moiety in Component (b-1-1)}

R^{b1} represents an aryl group having an electron-withdrawing group. Examples of the aryl group as R^{b1} include the same aryl groups as those as R²⁰¹ to R²⁰³ in Formula (ca-1). In addition, examples of the electron-withdrawing group include the same electron-withdrawing groups as those which the aryl group may have.

The number of electron-withdrawing groups which the aryl group as R^{b1} has may be one or two or more. In addition, in a case where the aryl group as R^{b1} has a plurality of electron-withdrawing groups, the plurality of electron-withdrawing groups may be the same or different.

R^{b2} and R^{b3} each independently represent an aryl group which may independently have a substituents, or R^{b2} and R^{b3} are bonded to each other to form a ring together with the sulfur atom in the formula. Examples of the aryl group include the same aryl groups as those as R^{b} described above. Examples of the substituent which the aryl group, as R^{b2} and R^{b3}, may have include the same substituents as those which the aryl group, as R²⁰¹ and R²⁰³ in Formula (ca-1) may have.

An example of the ring formed by R^{b2} and R^{b3}, which are bonded to each other, together with the sulfur atom in the formula includes the same ring as that formed by R²⁰¹ to R²⁰³ in Formula (ca-1), which are bonded to each other, together with the sulfur atom in the formula. The formed ring is particularly preferably dibenzothiophene ring.

It is preferable for the cation moiety in the component (b-1-1) to be a ring formed by R^{b2} and R^{b3}, which are bonded to each other, together with the sulfur atom in the formula, from the viewpoint of further improving the sensitivity.

On the other hand, it is preferable for the cation moiety to be aryl groups which may each independently have a substituent and more preferably an aryl group which may have an electron-withdrawing group, from the viewpoint of improving the roughness reducing property.

Specific examples of the component (B) are shown below, but the present invention is not limited thereto.

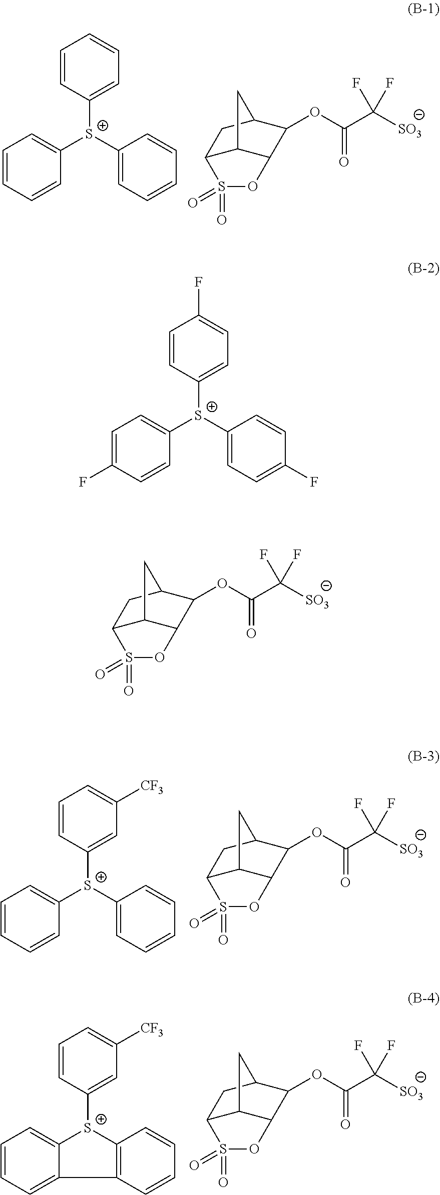

Among the above, the component (B) in the resist composition of the present embodiment is preferably an acid generator represented by Chemical Formula (B-4) from the viewpoint of further improving the sensitivity.

On the other hand, the component (B) is preferably an acid generator represented by Chemical Formula (B-2) or (B-3) from the viewpoint of improving the roughness reducing property.

In the resist composition of the present embodiment, the component (B) may be used alone or in a combination of two or more kinds thereof.

In the resist composition of the present embodiment, the content of the component (B) is preferably less than 50 parts by mass, more preferably 1 to 40 parts by mass, and still more preferably 5 to 25 parts by mass with respect to 100 parts by mass of the component (A).

In a case where the content of the component (B) is equal to or greater than the preferred lower limit, the lithography characteristics such as sensitivity, CDU, pattern collapse, resolution performance, linewise roughness (LWR), and shape are further improved in resist pattern formation.

On the other hand, in a case where the content of the component (B) is equal to or lower than the preferred upper limit, the solubility of the developing solution can be appropriately ensured, and thus the effects of the present invention can be more easily obtained.

<Photodegradable Base (D0)>

In addition to the component (A) and the component (B), the resist composition of the present embodiment further contains a photodegradable base (D0) that is decomposed upon exposure and loses the acid diffusion controllability.

The component (D0) contains a compound represented by General Formula (d0) (hereinafter, also referred to as the component (d0)).

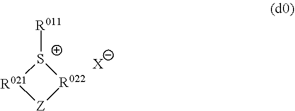

[In the formula, R⁰¹¹ represents an aryl group having an electron-withdrawing group. R⁰²¹ and R⁰²² each independently represent an aryl group which may have a substituent. Z represents a sulfur atom, an oxygen atom, a carbonyl group, or a single bond. X⁻ represents a counter anion.]

{Cation Moiety of Component (d0)}

[In Formula (d0), R⁰¹¹ represents an aryl group having an electron-withdrawing group. Examples of the aryl group include an unsubstituted aryl group having 6 to 20 carbon atoms, and a phenyl group or a naphthyl group is preferable.

In Formula (d0), examples of the electron-withdrawing group which an aryl group in R⁰¹¹ has include an acyl group, a methanesulfonyl group (mesyl group), a halogen atom, a halogenated alkyl group, a halogenated alkoxy group, a halogenated aryloxy group halide, a halogenated alkylamino group, a halogenated alkylthio group, a cyano group, a nitro group, a dialkylphosphono group, a diarylphosphono group, an alkylsulfonyl group, an arylsulfonyl group, a sulfonyloxy group, an acylthio group, a sulfamoyl group, a thiocianate group, and a thiocarbonyl group.

Among the above, a fluorine atom or a fluorinated alkyl group is preferable from the viewpoint of increasing sensitivity. The fluorinated alkyl group is preferably a fluorinated alkyl group having 1 to 5 carbon atoms.

The number of electron-withdrawing groups which the aryl group as R⁰¹¹ has may be one or two or more. In addition, in a case where the aryl group as R⁰¹¹ has a plurality of electron-withdrawing groups, the plurality of electron-withdrawing groups may be the same or different.

R⁰²¹ and R⁰²² each independently represent an aryl group which may have a substituent. Examples of the aryl group include the same aryl groups as those as R⁰¹¹ described above. Examples of the substituent include an alkyl group, a halogen atom, a halogenated alkyl group, a carbonyl group, a cyano group, an amino group, an aryl group, and groups respectively represented by General Formulae (ca-r-1) to (ca-r-7).

R⁰²¹ and R⁰²² form a heterocyclic structure together with the sulfur atom (S) in Formula (d0) through Z in Formula (d0). For example, in a case where both R⁰²¹ and R⁰²² represents a phenyl group and Z represents a single bond, a dibenzothiophene ring is formed.

In Formula (d0), Z represents a sulfur atom, an oxygen atom, a carbonyl group, or a single bond. Among these, Z preferably represents a single bond.

An example of the preferred cation moiety of the component (d0) includes a cation represented by General Formula (d0-c).

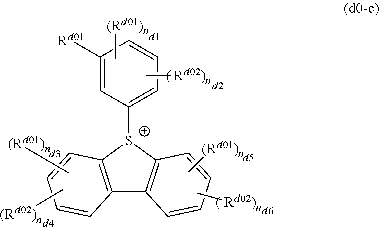

[In the formula, R^{d01} represents a fluorine atom or a fluorinated alkyl group having 1 to 5 carbon atoms. In a case where plurality of R^{d01} are present in the formula, the plurality of R^{d01} may be the same or different from each other. R^{d02} represents an alkyl group having 1 to 5 carbon atoms. In a case where plurality of R^{d01} are present in the formula, the plurality of R^{d01} may be the same or different from each other. n_{d1} represents an integer of 0 to 4. n_{d3} and n_{d5} are each independently represent an integer of 0 to 4. n_{d2} represents an integer of 0 to 4. n_{d4} and n_{d6} are each independently represent an integer of 0 to 4. However, 0≤n_{d1}+n_{d2}≤4, 0≤n_{d3}+n_{d4}≤4, and 0≤n_{d5}+n_{d6}≤4 are satisfied.]

R^{d01} is a fluorine atom or a fluorinated alkyl group having 1 to 5 carbon atoms, preferably a fluorine atom or a fluorinated alkyl group having 1 to 3 carbon atoms, and more preferably a fluorine atom or a trifluoromethyl group.

Among the alkyl groups having 1 to 5 carbon atoms, R^{d02} is preferably a methyl group or an ethyl group.

n_{d1} preferably represents 0 or 1.

n_{d3} and n_{d5} each represents preferably 0, 1, or 2 and more preferably 0.

n_{d2} represents preferably 0 or 1 and more preferably 0.

n_{d4} and n_{d6} each represents preferably 0, 1, or 2 and more preferably 0.

Specific examples of the cations represented by General Formula (d0-c) will be described below.

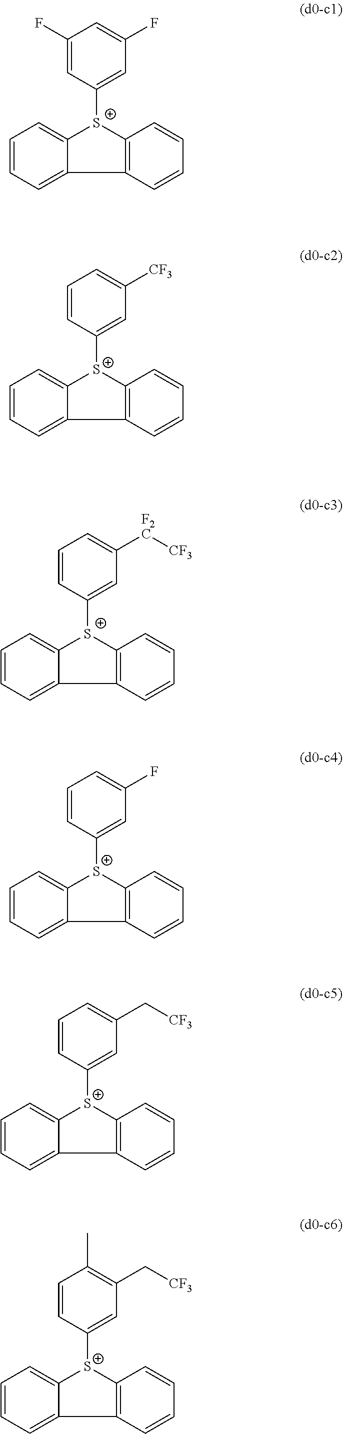

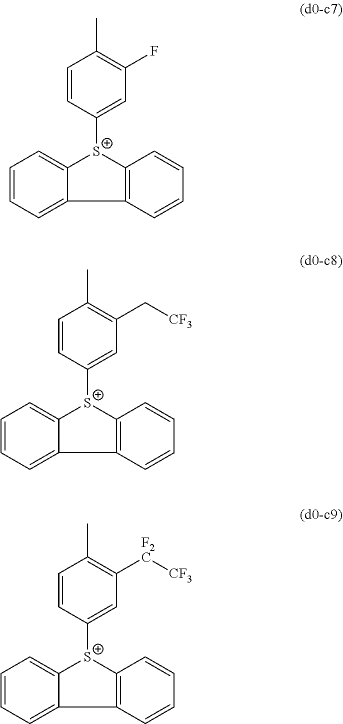

{Anion Moiety of Component (d0)}

In Formula (d0), X⁻ represents a counter anion. X⁻ is not particularly limited, and the anion known as an anion moiety for controlling acid diffusion for a resist composition can be properly used.

An example of X⁻ includes an anion represented by any one of General Formulae (d0-an-1) to (d0-an-3).

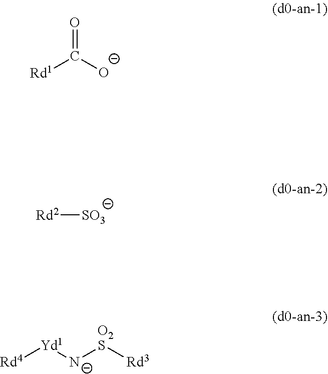

[In the formulae, Rd¹ to Rd⁴ represent a cyclic group which may have a substituent, a chain-like alkyl group which may have a substituent, or a chain-like alkenyl group which may have a substituent. However, a fluorine atom is not bonded to a carbon atom adjacent to a S atom in Rd² in Formula (d0-an-2). Yd¹ represents a single bond or a divalent linking group.]

In Formula (d0-an-1), Rd¹ represents a cyclic group which may have a substituent, a chain-like alkyl group which may have a substituent, or a chain-like alkenyl group which may have a substituent, and each example thereof is the same as R′²⁰¹ described above.

Among these, Rd¹ is preferably an aromatic hydrocarbon group which may have a substituent, an aliphatic cyclic group which may have a substituent, or a chain-like alkyl group which may have a substituent. Examples of the substituent which these groups may have include a hydroxy group, an oxo group, an alkyl group, an aryl group, a fluorine atom, a fluorinated alkyl group, lactone-containing cyclic groups respectively represented by General Formulae (a2-r-1) to (a2-r-7), an ether bond, an ester bond, and a combination thereof. In a case where an ether bond or an ester bond is included as the substituent, the substituent may be bonded through an alkylene group, and the substituent in this case is preferably linking groups respectively represented by Formulae (y-a1-1) to (y-a1-5).

Examples of the aromatic hydrocarbon group preferably include a phenyl group, a naphthyl group, and a polycyclic structure (a polycyclic structure including a bicyclooctane skeleton and a ring structure other than the bicyclooctane skeleton) including a bicyclooctane skeleton.

The aliphatic cyclic group is more preferably a group in which one or more hydrogen atoms have been removed from polycycloalkanes such as adamantane, norbornane, isobornane, tricyclodecane, and tetracyclododecane.

The chain-like alkyl group preferably has 1 to 10 carbon atoms, and specific examples thereof include a linear alkyl group such as a methyl group, an ethyl group, a propyl group, a butyl group, a pentyl group, a hexyl group, a heptyl group, an octyl group, a nonyl group, or a decyl group, and a branched alkyl group such as a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, or a 4-methylpentyl group.

In a case where the chain-like alkyl group is a fluorinated alkyl group having a fluorine atom or a fluorinated alkyl group as a substituent, the fluorinated alkyl group has preferably 1 to 11 carbon atoms, more preferably 1 to 8 carbon atoms, and still more preferably 1 to 4 carbon atoms. The fluorinated alkyl group may contain an atom other than a fluorine atom. Examples of the atom other than a fluorine atom include an oxygen atom, a sulfur atom, and a nitrogen atom.

Rd¹ is preferably a fluorinated alkyl group in which a part or all of the hydrogen atoms constituting a linear alkyl group have been substituted with fluorine atoms and particularly preferably a fluorinated alkyl group in which all of the hydrogen atoms constituting a linear alkyl group have been substituted with fluorine atoms (a linear perfluoroalkyl group).

In Formula (d0-an-1), R^{d1} is preferably, among the above, a cyclic group which may have a substituent and more preferably an aromatic hydrocarbon group which may have a substituent.

Specific examples of the preferred anion represented by Formula (d0-an-1) are as follows.

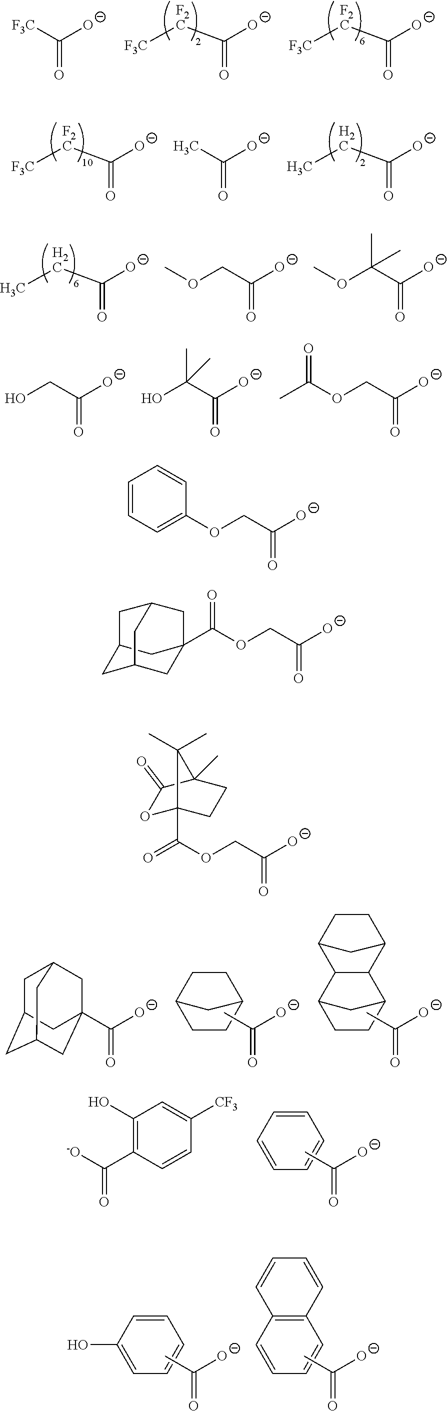

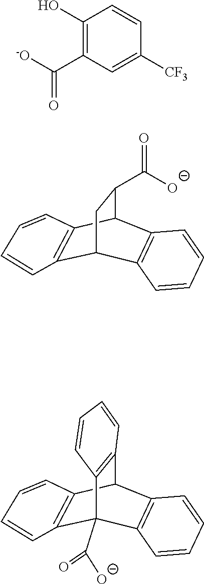

In Formula (d0-an-2), Rd² represents a cyclic group which may have a substituent, a chain-like alkyl group which may have a substituent, or a chain-like alkenyl group which may have a substituent, and an example thereof is the same as R′201 described above.

However, a fluorine atom is not bonded to the carbon atom adjacent to the S atom in Rd² (the carbon atom adjacent to the S atom in Rd² is not substituted with a fluorine atom). As a result, the anion in Formula (d0-an-2) becomes an appropriately weak acid anion, thereby improving the quenching ability of the component (D).

Rd² is preferably a chain-like alkyl group which may have a substituent or an aliphatic cyclic group which may have a substituent. The chain-like alkyl group has preferably 1 to 10 carbon atoms and more preferably 3 to 10 carbon atoms. The aliphatic cyclic group is more preferably a group in which one or more hydrogen atoms have been removed from adamantane, norbornane, isobornane, tricyclodecane, or tetracyclododecane (which may have a substituent) and a group in which one or more hydrogen atoms have been removed from camphor.

The hydrocarbon group as Rd² may have a substituent. Examples of the substituent include the same group as the substituent which the hydrocarbon group (such as an aromatic hydrocarbon group, an aliphatic cyclic group, or a chain-like alkyl group) as Rd¹ in Formula (d0-an-1) may have.

Specific examples of the preferred anion represented by Formula (d0-an-2) are as follows.

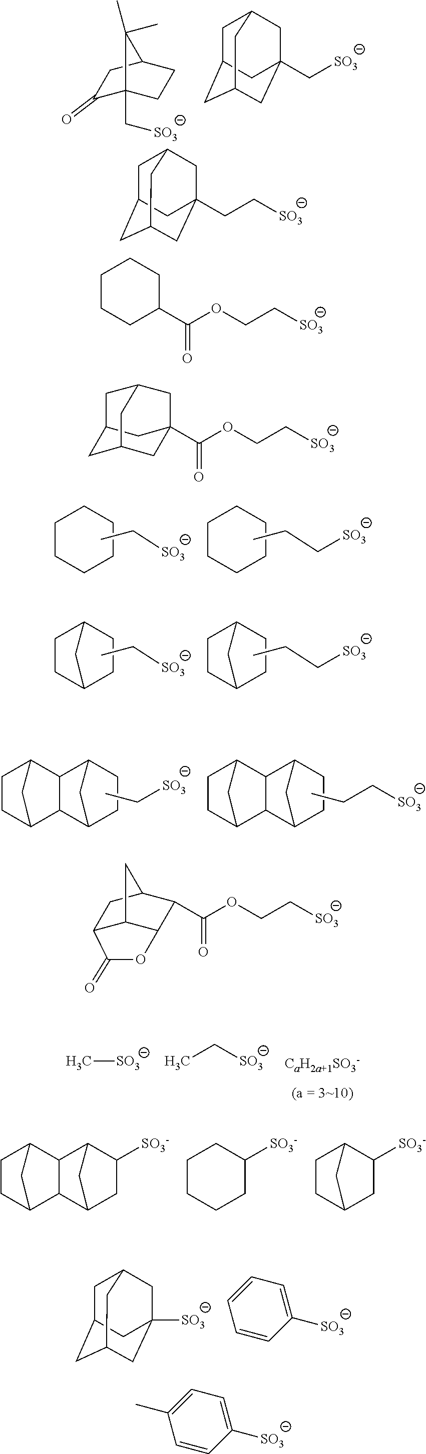

In Formula (d0-an-3), Rd³ represents a cyclic group which may have a substituent, a chain-like alkyl group which may have a substituent, or a chain-like alkenyl group which may have a substituent. An example of Rd³ includes the same group as R′²⁰¹, and a cyclic group containing a fluorine atom, a chain-like alkyl group, or a chain-like alkenyl group is preferable. Among them, a fluorinated alkyl group is preferable, and the same fluorinated alkyl group as that of Rd¹ is more preferable.

In Formula (d0-an-3), Rd⁴ represents a cyclic group which may have a substituent, a chain-like alkyl group which may have a substituent, or a chain-like alkenyl group which may have a substituent, and an example thereof is the same as R′²⁰¹ described above.

Among them, an alkyl group which may have a substituent, an alkoxy group which may have a substituent, an alkenyl group which may have a substituent, or a cyclic group which may have a substituent is preferable.

The alkyl group as Rd⁴ is preferably a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group. A part of hydrogen atoms in the alkyl group as Rd⁴ may be substituted with a hydroxy group, a cyano group, or the like.

The alkoxy group as Rd⁴ is preferably an alkoxy group having 1 to 5 carbon atoms, and specific examples of the alkoxy group having 1 to 5 carbon atoms include a methoxy group, an ethoxy group, an n-propoxy group, an iso-propoxy group, an n-butoxy group, and a tert-butoxy group. Among them, a methoxy group and an ethoxy group are preferable.

Examples of the alkenyl group as Rd⁴ include the same group as the alkenyl groups as R′²⁰¹, and a vinyl group, a propenyl group (an allyl group), a 1-methylpropenyl group, and a 2-methylpropenyl group are preferable. These groups may further have an alkyl group having 1 to 5 carbon atoms or a halogenated alkyl group having 1 to 5 carbon atoms, as a substituent.

Examples of the cyclic group as Rd⁴ include the same groups as the cyclic group as R′²⁰¹ and alicyclic groups in which one or more hydrogen atoms have been removed from cycloalkanes such as cyclopentane, cyclohexane, adamantane, norbornane, isobornane, tricyclodecane, and tetracyclododecane, or aromatic groups such as a phenyl group and a naphthyl group are preferable. In a case where Rd⁴ represents an alicyclic group, the resist composition can be satisfactorily dissolved in an organic solvent, thereby improving the lithography characteristics. In a case where Rd⁴ is an aromatic group, the resist composition is excellent in light absorption efficiency and thus has good sensitivity and lithography characteristics in the lithography using EUV or the like as a light source for exposure.

In Formula (d0-an-3), Yd¹ represents a single bond or a divalent linking group.

The divalent linking group as Yd¹ is not particularly limited, and examples thereof include a divalent hydrocarbon group (an aliphatic hydrocarbon group or an aromatic hydrocarbon group) which may have a substituent and a divalent linking group containing a hetero atom. As these divalent linking groups, the same groups as those described above as the divalent hydrocarbon group which may have a substituent and the divalent linking group containing a hetero atom described above as the divalent linking group as Ya²¹ in Formula (a2-1) can be respectively mentioned.

Yd¹ is preferably a carbonyl group, an ester bond, an amide bond, an alkylene group, or a combination of thereof. The alkylene group is more preferably a linear or branched alkylene group and still more preferably a methylene group or an ethylene group.

Specific examples of the preferred anion moiety represented by Formula (d0-an-3) are as follows.

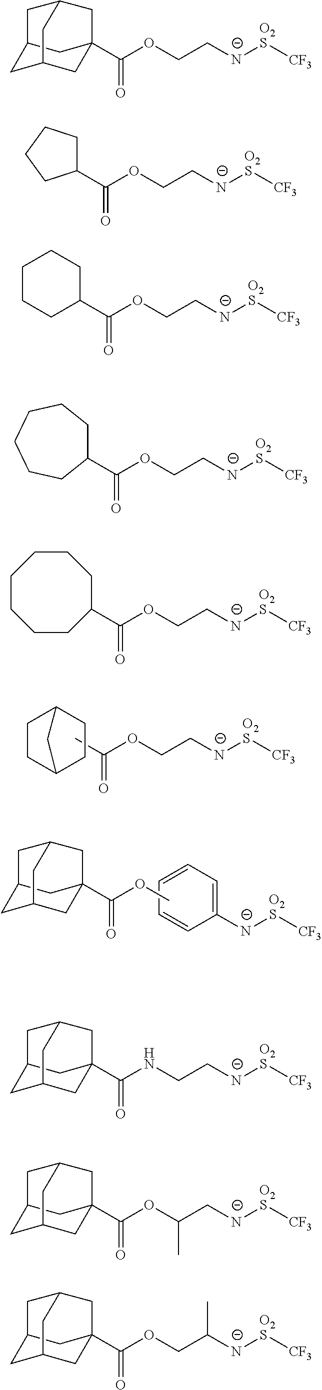

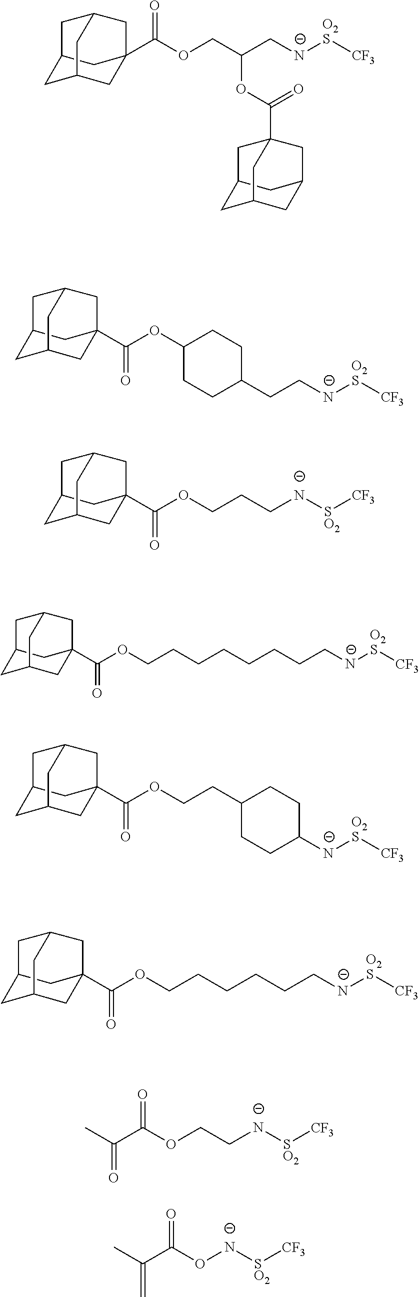

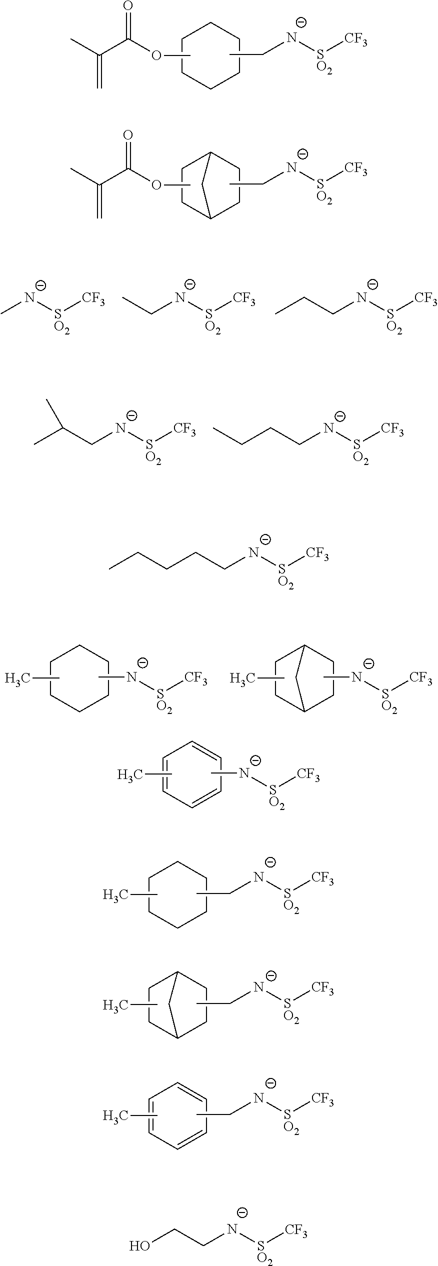

Among the above, the anion moiety of the component (d0) in the resist composition of the present embodiment is preferably an anion represented by General Formula (d0-an-1).

The component (d0) in the resist composition of the present embodiment is preferably a compound represented by General Formula (d0-1-1).

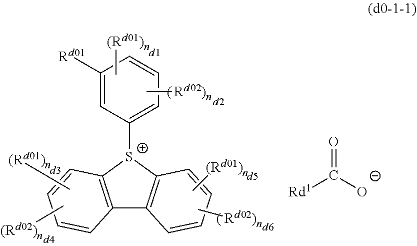

[In the formula, R^{d01} represents a fluorine atom or a fluorinated alkyl group having 1 to 5 carbon atoms. In a case where plurality of R^{d01} are present in the formula, the plurality of R^{d01} may be the same or different from each other. R^{d02} represents an alkyl group having 1 to 5 carbon atoms. In a case where plurality of R^{d02} are present in the formula, the plurality of R^{d01} may be the same or different from each other. n_{d1} represents an integer of 0 to 4. n_{d3} and n_{d5} are each independently represent an integer of 0 to 4. n_{d2} represents an integer of 0 to 4. n_{d4} and n_{d6} are each independently represent an integer of 0 to 4. However, 0≤n_{d1}+n_{d2}≤4, 0≤n_{d3}+n_{d4}≤4, and 0≤n_{d5}+n_{d6}≤4 are satisfied. Rd¹ represents a cyclic group which may have a substituent, a chain-like alkyl group which may have a substituent, or a chain-like alkenyl group which may have a substituent].

Examples of the cation moiety of the compound represented by Formula (d0-1-1) include the same cations as those represented by General Formula (d0-c). Examples of the anion moiety represented by Formula (d0-1-1) include the same anions as those represented by General Formula (d0-an-1).

Specific examples of the component (d0) in the resist composition of the present embodiment are as follows.

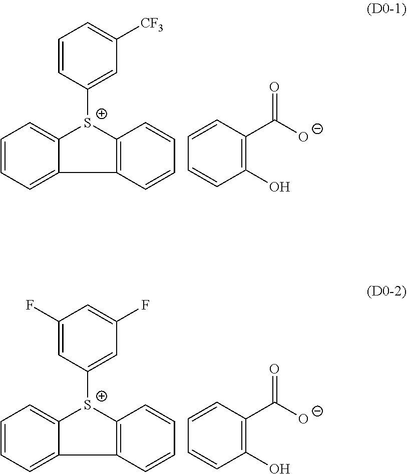 [SMILES: FC(F)(F)c1cccc(-[s+]2c3ccccc3c3ccccc32)c1 ; O=C([O-])c1ccccc1O ; Fc1cc(F)cc(-[s+]2c3ccccc3c3ccccc32)c1 ; O=C([O-])c1ccccc1O]

In the resist composition of the present embodiment, the component (F) may be used alone or in a combination of two or more kinds thereof.

In the resist composition of the present embodiment, the content of the component (D0) is preferably 1 to 25 parts by mass, more preferably 3 to 20 parts by mass, and still more preferably 5 to 15 parts by mass, with respect to 100 parts by mass of the component (A).

In a case where the content of the component (D0) is equal to or greater than the preferred lower limit, excellent lithography characteristics and an excellent resist pattern shape are easily obtained. On the other hand, in a case where the content of the component (D0) is equal to or lower than the upper limit, the sensitivity can be maintained satisfactorily and the throughput is also excellent.

In the resist composition of the present embodiment, the total content of the component (B) and the component (D0) is preferably 5 to 60 parts by mass, more preferably 10 to 50 parts by mass, and still more preferably 15 to 30 parts by mass, and particularly preferably 22 to 25 parts by mass, with respect to 100 parts by mass of the component (A).

In a case where the total content of the component (B) and the component (D0) is within the preferred range described above, particularly excellent lithography characteristics and a particularly excellent resist pattern shape are easily obtained.

In the resist composition of the present embodiment, the content of the acid generator component (B) is preferably higher than the content of the photodegradable base (D0). More specifically, the mixing ratio (mass ratio) of the component (B) to the component (D0), in terms of component (B)/component (D0), is preferably more than 1.0 and 20 or less, more preferably 1.2 or more and 10 or less, and still more preferably 1.4 or more and 5 or less.

In a case where the mixing ratio (mass ratio) of the component (B) to the component (D0) is within the preferred range described above, the sensitivity can be maintained well, and particularly excellent lithography characteristics and a particularly excellent resist pattern shape are easily obtained.

In the resist composition of the present embodiment, the component (D0) is preferably a compound represented by General Formula (d0), but a photodegradable base (D1) (hereinafter, also referred to as “component (D1)”) other than the component (D0) may be contained.

In Regard to Component (D1)

The component (D1) is not particularly limited as long as it does not correspond to the component (D0) and is decomposed upon exposure and loses the acid diffusion controllability. Examples of the component (D1) include compounds composed of an m-valent onium cation represented by M′ in Formula (b-1), Formula (b-2), and Formula (b-3), and an anion represented by any one of General Formulae (d0-an-1) to (d0-an-3).

In a case where the resist composition contains the component (D1), the content of the component (D1) in the resist composition is preferably 0.5 to 35 parts by mass, more preferably 1 to 25 parts by mass, and still more preferably 2 to 20 parts by mass, with respect to 100 parts by mass of the component (A).

In a case where the content of the component (D1) is equal to or greater than the preferred lower limit, excellent lithography characteristics and an excellent resist pattern shape are easily obtained. On the other hand, in a case where the proportion is equal to or less than the upper limit of the preferred range, balance with other components can be obtained, and various lithography characteristics are improved.

In Regard to Component (D2)

The component (D2) is a base component and is a nitrogen-containing organic compound that acts as an acid diffusion controlling agent in the resist composition.

The component (D2) is not particularly limited as long as it acts as an acid diffusion controlling agent and does not correspond to the component (D0) and the component (D1), and examples thereof include an aliphatic amine and an aromatic amine.

Among them, the aliphatic amine is preferably a secondary aliphatic amine or a tertiary aliphatic amine.

The aliphatic amine is an amine having one or more aliphatic groups, and the aliphatic groups preferably have 1 to 12 carbon atoms.

Examples of the aliphatic amines include an amine in which at least one hydrogen atom of ammonia (NH₃) has been substituted with an alkyl group or hydroxyalkyl group having 12 or fewer carbon atoms (an alkylamine or an alkylalcoholamine) and a cyclic amine.

Specific examples of the alkylamine and the alkylalcoholamine include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-hexylamine, tri-n-pentylamine, tri-n-heptylamine, tri-n-octylamine, tri-n-nonylamine, tri-n-decylamine, and tri-n-dodecylamine; and alkylalcoholamines such as diethanolamine, triethanolamine, diisopropanolamine, triisopropanolamine, di-n-octanolamine, and tri-n-octanolamine. Among these, a trialkylamine having 5 to 10 carbon atoms is still more preferable, and tri-n-pentylamine or tri-n-octylamine is particularly preferable.

Examples of the cyclic amine include heterocyclic compounds containing a nitrogen atom as a hetero atom. The heterocyclic compound may be a monocyclic compound (aliphatic monocyclic amine) or a polycyclic compound (aliphatic polycyclic amine).

Specific examples of the aliphatic monocyclic amine include piperidine and piperazine. The aliphatic polycyclic amine preferably has 6 to 10 carbon atoms, and specific examples thereof include 1, 5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine, tris[2-{2-(2-hydroxyethoxy)ethoxy}ethyl]amine, and triethanolamine triacetate, and triethanolamine triacetate is preferable.

Examples of the aromatic amine include 4-dimethylaminopyridine, pyrrole, indole, pyrazole, imidazole, or a derivative thereof, tribenzylamine, an aniline compound, and N-tert-butoxycarbonylpyrrolidine.

The component (D2) may be used alone or in a combination of two or more kinds thereof. Among the above, the component (D2) is preferably an aromatic amine and more preferably an aniline compound. Examples of the aniline compound include 2,6-diisopropylaniline, N,N-dimethylaniline, N,N-dibutylaniline, and N,N-dihexylaniline.

In a case where the resist composition contains the component (D2), the component (D2) in the resist composition is typically used in a range of 0.01 to 5 parts by mass with respect to 100 parts by mass of the component (A). In a case of being set to the preferred range described above, balance with other components can be obtained, and various lithography characteristics are improved.

<<At Least One Compound (E) Selected from the Group Consisting of Organic Carboxylic Acid, Phosphorus Oxo Acid, and Derivatives Thereof>>

For the purpose of preventing any deterioration in sensitivity and improving the resist pattern shape and post-exposure temporal stability, the resist composition of the present embodiment may contain, as an optional component, at least one compound (E) (hereinafter referred to as the component (E)) selected from the group consisting of an organic carboxylic acid, and a phosphorus oxo acid and a derivative thereof.

Suitable examples of the organic carboxylic acid include acetic acid, malonic acid, citric acid, malic acid, succinic acid, benzoic acid, and salicylic acid.

Examples of the phosphorus oxo acid include phosphoric acid, phosphonic acid, and phosphinic acid. Among these, phosphonic acid is particularly preferable.

Examples of the phosphorus oxo acid derivative include esters in which a hydrogen atom in the above-described oxo acids is substituted with a hydrocarbon group. Examples of the hydrocarbon group include an alkyl group having 1 to 5 carbon atoms and an aryl group having 6 to 15 carbon atoms.

Examples of the phosphoric acid derivative include phosphoric acid esters such as di-n-butyl phosphate and diphenyl phosphate.

Examples of the phosphonic acid derivative include phosphonic acid esters such as dimethyl phosphonate, di-n-butyl phosphonate, phenylphosphonic acid, diphenyl phosphonate, and dibenzyl phosphonate.

Examples of the phosphinic acid derivative include a phosphinic acid ester and phenylphosphinic acid.

In the resist composition of the present embodiment, the component (E) may be used alone or in a combination of two or more kinds thereof.

In a case where the resist composition contains the component (E), the content of the component (E) is typically used in a range of 0.01 to 5 parts by mass with respect to 100 parts by mass of the component (A).

<<Fluorine Additive Component (F)>>

The resist composition of the present embodiment may further contain a fluorine additive component (hereinafter, referred to as the “component (F)”) in order to impart water repellency to the resist film or to improve lithography characteristics.

As the component (F), a fluorine-containing high molecular compound described in Japanese Unexamined Patent Application, First Publication No. 2010-002870, Japanese Unexamined Patent Application, First Publication No. 2010-032994, Japanese Unexamined Patent Application, First Publication No. 2010-277043, Japanese Unexamined Patent Application, First Publication No. 2011-13569, or Japanese Unexamined Patent Application, First Publication No. 2011-128226 can be used.

Specific examples of the component (F) include polymers having a constitutional unit (f1) represented by General Formula (f1-1). This polymer is preferably a polymer (homopolymer) consisting of a constitutional unit (f1) represented by Formula (f1-1); a copolymer of the constitutional unit (f1) and the constitutional unit (a1); and a copolymer of the constitutional unit (f1), a constitutional unit derived from acrylic acid or methacrylic acid, and the constitutional unit (a1). The constitutional unit (a1) to be copolymerized with the constitutional unit (f1) is preferably a constitutional unit derived from 1-ethyl-1-cyclooctyl (meth)acrylate and a constitutional unit derived from 1-methyl-1-adamantyl (meth)acrylate.

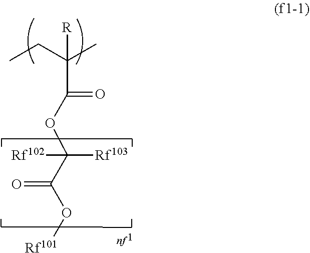

[In the formula, R is the same as that described above. Rf¹⁰² and Rf¹⁰³ each independently represent a hydrogen atom, a halogen atom, an alkyl group having 1 to 5 carbon atoms, or a halogenated alkyl group having 1 to 5 carbon atoms, and Rf¹⁰² and Rf¹⁰³ may be the same or different from each other. nf¹ represents an integer of 0 to 5. Rf¹⁰¹ represents an organic group containing a fluorine atom.]

In Formula (f1-1), R bonded to the carbon atom at the α-position is the same as that described above. R is preferably a hydrogen atom or a methyl group.

In Formula (f1-1), the halogen atom of Rf¹⁰² and Rf¹⁰³ is particularly preferably a fluorine atom. Examples of the alkyl group having 1 to 5 carbon atoms as Rf¹⁰² and Rf¹⁰³ include the same groups as the alkyl group having 1 to 5 carbon atoms as R, and a methyl group or an ethyl group is preferable. Specific examples of the halogenated alkyl group having 1 to 5 carbon atoms as Rf¹⁰² and Rf¹⁰³ include groups in which a part or all hydrogen atoms of the above-described alkyl groups of 1 to 5 carbon atoms have been substituted with halogen atoms. The halogen atom is particularly preferably a fluorine atom. Among them, Rf¹⁰² and Rf¹⁰³ are preferably a hydrogen atom, a fluorine atom, or an alkyl group having 1 to 5 carbon atoms and ore preferably a hydrogen atom, a fluorine atom, a methyl group, or an ethyl group. In Formula (f1-1), nf¹ represents an integer of 0 to 5, preferably an integer of 0 to 3, and more preferably an integer of 1 or 2.

In Formula (f1-1), Rf¹⁰¹ represents an organic group containing a fluorine atom and is preferably a hydrocarbon group containing a fluorine atom.

The hydrocarbon group containing a fluorine atom may be linear, branched, or cyclic, and has preferably 1 to 20 carbon atoms, more preferably 1 to 15 carbon atoms, and particularly preferably 1 to 10 carbon atoms.

In addition, in the hydrocarbon group containing a fluorine atom, preferably 25% or more of the hydrogen atoms in the hydrocarbon group are fluorinated, more preferably 50% or more are fluorinated, and particularly preferably 60% or more are fluorinated, since the hydrophobicity of the resist film at the time of dipping exposure increases.

Among them, Rf¹⁰¹ is preferably a fluorinated hydrocarbon group having 1 to 6 carbon atoms and more preferably a trifluoromethyl group, —CH₂—CF₃, —CH₂—CF₂—CF₃, —CH(CF₃)₂, —CH₂—CH₂—CF₃, and —CH₂—CH₂—CF₂—CF₂—CF₂—CF₃.

The weight-average molecular weight (Mw) (based on the polystyrene-equivalent value determined by gel permeation chromatography) of the component (F) is preferably 1,000 to 50,000, more preferably 5,000 to 40,000, and most preferably 10,000 to 30,000. In a case where the weight-average molecular weight is equal to or lower than the upper limit of the above-described range, the resist composition exhibits a solubility in a solvent for a resist, which is enough for using the resist composition as a resist composition. On the other hand, in a case where the weight-average molecular weight is equal to or greater than the lower limit of the above-described range, water repellency of the resist film is excellent.

Further, the dispersity (Mw/Mn) of the component (F) is preferably 1.0 to 5.0, more preferably 1.0 to 3.0, and most preferably 1.0 to 2.5.

In the resist composition of the present embodiment, the component (F) may be used alone or in a combination of two or more kinds thereof.

In a case where the resist composition contains the component (F), the content of the component (F) is typically used in a proportion of 0.5 to 10 parts by mass, with respect to 100 parts by mass of the component (A).

<<Organic Solvent Component (S)>>

The resist composition of the present embodiment may be produced by dissolving the resist materials in an organic solvent component (hereinafter, referred to as “component (S)”).

The component (S) may be any organic solvent which can dissolve each of the components to be used to obtain a uniform solution, and any organic solvent can be properly selected and used from those which have been conventionally known as solvents for a chemical amplification type resist composition.

Examples of the component (S) include lactones such as γ-butyrolactone; ketones such as acetone, methyl ethyl ketone, cyclohexanone, methyl-n-pentyl ketone, methyl isopentyl ketone, and 2-heptanone; polyhydric alcohols such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkyl ether (such as monomethyl ether, monoethyl ether, monopropyl ether or monobutyl ether) or monophenyl ether of any of these polyhydric alcohols or compounds having an ester bond [among these, propylene glycol monomethyl ether acetate (PGMEA) and propylene glycol monomethyl ether (PGME) are preferable] cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzyl ether, cresylmethyl ether, diphenyl ether, dibenzyl ether, phenetole, butylphenyl ether, ethylbenzene, diethylbenzene, pentylbenzene, isopropylbenzene, toluene, xylene, cymene and mesitylene; and dimethylsulfoxide (DMSO).

In the resist composition of the present embodiment, the component (S) may be used singly or as a mixed solvent of two or more solvents. Among them, PGMEA, PGME, γ-butyrolactone, EL, and cyclohexanone are preferable.

In addition, the component (S) is also preferably a mixed solvent obtained by mixing PGMEA with a polar solvent. The blending ratio (mass ratio) of the mixed solvent can be properly determined, considering the compatibility of PGMEA with the polar solvent, and is preferably in a range of 1:9 to 9:1 and more preferably in a range of 2:8 to 8:2.

More specifically, in a case where EL or cyclohexanone is blended as the polar solvent, the mass ratio of PGMEA:EL or cyclohexanone is preferably in a range of 1:9 to 9:1 and more preferably in a range of 2:8 to 8:2. In addition, in a case where PGME is blended as the polar solvent, the mass ratio of PGMEA:PGME is preferably in a range of 1:9 to 9:1, more preferably in a range of 2:8 to 8:2, and still more preferably in a range of 3:7 to 7:3. Furthermore, a mixed solvent of PGMEA, PGME, and cyclohexanone is also preferable.

In addition, the component (S) is also preferably a mixed solvent of at least one selected from PGMEA and EL and γ-butyrolactone. In this case, as the mixing ratio, the mass ratio of the former to the latter is preferably in a range of 70:30 to 95:5.

The amount of the component (S) to be used is not particularly limited and is properly set, depending on the thickness of a film to be coated, to a concentration at which the component (S) can be applied onto a substrate or the like. Generally, the component (S) is used such that the concentration of solid contents of the resist composition is in the range of 0.1% to 20% by mass and preferably 0.2% to 15% by mass.

Further, as desired, other miscible additives can be properly added to the resist composition of the present embodiment. Examples of the miscible additives include an additive resin, a dissolution inhibitor, a plasticizer, a stabilizer, a colorant, a halation prevention agent, and a dye for improving the performance of a resist film.

After dissolving the resist material in the component (S), the resist composition of the present embodiment may be subjected to removing impurities and the like by using a porous polyimide film, a porous polyamideimide film, or the like. For example, the resist composition may be filtered using a filter made of a porous polyimide film, a filter made of a porous polyamideimide film, or a filter made of a porous polyimide film and a porous polyamideimide film. An example of the porous polyimide film and the porous polyamideimide film include the film disclosed in Japanese Unexamined Patent Application, First Publication No. 2016-155121.

The resist composition of the present embodiment described above contains the component (A), component (B), and component (D0), which are described above, and the component (D0) contains the compound represented by General Formula (d0). Since the compound has an electron-withdrawing group in the cation moiety, the decomposition efficiency upon exposure is high. In addition, since the compound has a condensed ring structure in the cation moiety, the affinity for a developing solution is high. As a result, it is presumed that in resist composition of the present embodiment, which contains the compound, the generation of scum can be suppressed since the affinity for a developing solution is high.

(Method of Forming Resist Pattern)

The method of forming a resist pattern of the present embodiment is a method including a step of forming a resist film on a support using the resist composition described above, a step of exposing the resist film, and a step of developing the exposed resist film to form a resist pattern.

An example of one embodiment of such a method of forming a resist pattern includes a method of forming a resist pattern performed as described below.

First, the above-described resist composition of the embodiment is applied onto a support with a spinner or the like, and a baking (post-apply baking (PAB)) treatment is performed, for example, at the temperature condition of 80° C. to 150° C. for 40 to 120 seconds, preferably for 60 to 90 seconds, to form a resist film.

Following the selective exposure performed on the resist film by, for example, the exposure through a mask (mask pattern) having a predetermined pattern formed on the mask by using a lithography apparatus, for example, an electron beam lithography apparatus and an EUV exposure apparatus, or by the direct irradiation of the resist film for drawing with electron beam without using a mask pattern, baking treatment (post-exposure baking (PEB)) is performed, for example, under the temperature condition of 80° C. to 150° C. for 40 to 120 seconds and preferably 60 to 90 seconds.

Next, the resist film is subjected to a developing treatment. The developing treatment is performed using an alkali developing solution in a case of an alkali developing process, and a developing solution containing an organic solvent (organic developing solution) in a case of a solvent developing process.

After the developing treatment, it is preferable to perform a rinsing treatment. In a case of an alkali developing process, the rinsing treatment is preferably water rinsing using pure water, and in a case of a solvent developing process, a rinse liquid containing an organic solvent is preferably used.

In a case of a solvent developing process, after the developing treatment or the rinsing treatment, the developing solution or the rinse liquid remaining on the pattern can be removed by a treatment using a supercritical fluid.

After the developing treatment or the rinsing treatment, drying is performed. As desired, baking treatment (post-baking) can be performed following the developing treatment.

In this manner, a resist pattern can be formed.

The support is not particularly limited and a conventionally known support can be used. Examples thereof include a substrate for electronic components, and a substrate for electronic components, having a predetermined wiring pattern formed on the substrate. More specific examples of the substrate include silicon wafer, substrates made of metals such as copper, chromium, iron, and aluminum, and a glass substrate. As the material for a wiring pattern, copper, aluminum, nickel, or gold can be used.

Further, as the support, any support having the above-described substrate on which an inorganic and/or an organic film is provided may be used. An example of the inorganic film includes an inorganic antireflection film (inorganic BARC). Examples of the organic film include an organic antireflection film (organic BARC) and an organic film such as a lower-layer organic film used in a multilayer resist method.

Here, the multilayer resist method is a method in which at least one layer of an organic film (lower-layer organic film) and at least one layer of a resist film (upper-layer resist film) are provided on a substrate, and a resist pattern formed on the upper-layer resist film is used as a mask to perform patterning of the lower-layer organic film. This method is considered as a method capable of forming a pattern having a high aspect ratio. That is, according to the multilayer resist method, a desired thickness can be ensured by the lower-layer organic film, and as a result, the thickness of the resist film can be reduced, and thus a fine pattern with a high aspect ratio can be formed.

The multilayer resist method is classified into a method (double-layer resist method) in which a double-layer structure consisting of an upper-layer resist film and a lower-layer organic film is formed, and a method (triple-layer resist method) in which a multilayer structure having three or more layers that include one or more intermediate layers (thin metal films or the like) provided between the upper-layer resist film and the lower-layer organic film is formed.

The wavelength to be used for exposure is not particularly limited and the exposure can be performed using radiation such as an ArF excimer laser, a KrF excimer laser, an F₂ excimer laser, extreme ultraviolet (EUV) rays, vacuum ultraviolet (VUV) rays, electron beams (EB), X-rays, and soft X-rays. The resist composition is highly useful for a KrF excimer laser, an ArF excimer laser, EB, or EUV, more useful for an ArF excimer laser, EB or EUV, and particularly useful for EB or EUV. That is, the method of forming a resist pattern of the present embodiment is a particularly useful method in a case where the step of exposing the resist film includes an operation of exposing the resist film to extreme ultraviolet (EUV) rays or electron beams (EB).

In the method of exposing the resist film, a general exposure (dry exposure) performed in air or an inert gas such as nitrogen may be used, or liquid immersion lithography may be used.

In liquid immersion lithography, the region between the resist film and the lens at the lowermost point of the lithography apparatus is pre-filled with a solvent (liquid immersion medium) that has a refractive index higher than the refractive index of air, and exposure (dipping exposure) is performed in this state.

The liquid immersion medium is preferably a solvent that has a refractive index higher than the refractive index of air but lower than the refractive index of the resist film to be exposed. The refractive index of the solvent is not particularly limited as long as it satisfies the above-described requirements.

Examples of the solvent which exhibits a refractive index that is higher than the refractive index of air but lower than the refractive index of the resist film include water, a fluorine-based inert liquid, a silicone-based solvent, and a hydrocarbon-based solvent.

Specific examples of the fluorine-based inert liquid include liquids containing fluorine-based compounds such as C₃HC₂F₅, C₄F₉OCH₃, C₄F₉OC₂H₅ or C₅H₃F₇ as the main component, and the boiling point is preferably 70 to 180° C. and more preferably 800 to 160° C. A fluorine-based inert liquid having a boiling point in the above-described range is preferable since the medium used in the liquid immersion can be removed by a simple method after the exposure.

The fluorine-based inert liquid is particularly preferably a perfluoroalkyl compound in which all of the hydrogen atoms of the alkyl group are substituted with fluorine atoms. Examples of the perfluoroalkyl compounds include a perfluoroalkyl ether compound and a perfluoroalkylamine compound.

A specific example of the perfluoroalkyl ether compound includes perfluoro(2-butyl-tetrahydrofuran) (boiling point: 102° C.), and an example of the perfluoroalkylamine compound includes perfluorotributylamine (boiling point: 174° C.).

As the liquid immersion medium, water is preferable in terms of cost, safety, environment, and versatility.

An example of the alkali developing solution used for a developing treatment in an alkali developing process includes a 0.1 to 10% by mass aqueous solution of tetramethylammonium hydroxide (TMAH).

The organic solvent contained in the organic developing solution used for a developing treatment in a solvent developing process may be a solvent that is capable of dissolving the component (A) (prior to exposure) and can be properly selected from the conventionally known organic solvents. Specific examples of the organic solvent include polar solvents such as a ketone-based solvent, an ester-based solvent, an alcohol-based solvent, a nitrile-based solvent, an amide-based solvent, and an ether-based solvent, and a hydrocarbon-based solvent.

A ketone-based solvent is an organic solvent containing C—C(═O)—C in the structure thereof. An ester-based solvent is an organic solvent containing C—C(═O)—O—C in the structure thereof. An alcohol-based solvent is an organic solvent containing an alcoholic hydroxy group in the structure thereof. An “alcoholic hydroxy group” indicates a hydroxy group bonded to a carbon atom of an aliphatic hydrocarbon group. A nitrile-based solvent is an organic solvent containing a nitrile group in the structure thereof. An amide-based solvent is an organic solvent containing an amide group in the structure thereof. An ether-based solvent is an organic solvent containing C—O—C in the structure thereof.

Some organic solvents have a plurality of functional groups that characterizes the above-described solvent in the structure thereof. In such a case, the organic solvent corresponds to any type of solvents having the characteristic functional groups. For example, diethylene glycol monomethyl ether corresponds to an alcohol-based solvent or an ether-based solvent.

A hydrocarbon-based solvent consists of a hydrocarbon which may be halogenated and does not have any substituent other than a halogen atom. The halogen atom is preferably a fluorine atom.

Among the above, the organic solvent contained in the organic developing solution is preferably a polar solvent and more preferably a ketone-based solvent, an ester-based solvent, and a nitrile-based solvent.

Examples of the ketone-based solvent include 1-octanone, 2-octanone, 1-nonanone, 2-nonanone, acetone, 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonylalcohol, acetylcarbinol, acetophenone, methyl naphthyl ketone, isophorone, propylenecarbonate, γ-butyrolactone and methyl amyl ketone (2-heptanone). Among these, methyl amyl ketone (2-heptanone) is preferable as a ketone-based solvent.

Examples of the ester-based solvent include methyl acetate, butyl acetate, ethyl acetate, isopropyl acetate, amyl acetate, isoamyl acetate, ethyl methoxyacetate, ethyl ethoxyacetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Among these, the ester-based solvent is preferably butyl acetate.

Examples of the nitrile-based solvent include acetonitrile, propionitrile, valeronitrile, and butyronitrile.

As necessary, the organic developing solution may be blended with a conventionally known additive. Examples of the additive include surfactants. The surfactant is not particularly limited, and for example, an ionic or non-ionic fluorine and/or a silicone-based surfactant can be used. The surfactant is preferably a non-ionic surfactant and more preferably a non-ionic fluorine surfactant or a non-ionic silicone-based surfactant.

In a case where a surfactant is blended, the amount of the surfactant to be blended is typically 0.001% to 5% by mass, preferably 0.005% to 2% by mass, and more preferably 0.01% to 0.5% by mass with respect to the total amount of the organic developing solution.

The developing treatment can be performed by a conventionally known developing method. Examples thereof include a method (a dip method) in which the support is dipped in a developing solution for a predetermined time, a method (a puddle method) in which a developing solution is cast onto the surface of the support by surface tension and maintained for a predetermined period, a method (a spray method) in which a developing solution is sprayed onto the surface of the support, and a method (a dynamic dispense method) in which a developing solution is continuously ejected and applied onto the support which rotates at a constant speed while the support is scanned with a developing solution ejecting and applying nozzle at a constant speed.

As the organic solvent contained in the rinse liquid that is used in the rinsing treatment after the developing treatment in a case of a solvent developing process, an organic solvent hardly dissolving the resist pattern can be properly selected and used, among the organic solvents mentioned as inorganic solvents that are used for the organic developing solution. In general, at least one kind of solvent selected from the group consisting of a hydrocarbon-based solvent, a ketone-based solvent, an ester-based solvent, an alcohol-based solvent, an amide-based solvent, and an ether-based solvent is used. Among these, at least one kind of solvent selected from the group consisting of a hydrocarbon-based solvent, a ketone-based solvent, an ester-based solvent, an alcohol-based solvent, and an amide-based solvent is preferable, at least one kind of solvent selected from the group consisting of an alcohol-based solvent and an ester-based solvent is more preferable, and an alcohol-based solvent is particularly preferable.

The alcohol-based solvent used for the rinse liquid is preferably a monohydric alcohol having 6 to 8 carbon atoms, and the monohydric alcohol may be linear, branched, or cyclic. Specific examples thereof include 1-hexanol, 1-heptanol, 1-octanol, 2-hexanol, 2-heptanol, 2-octanol, 3-hexanol, 3-heptanol, 3-octanol, 4-octanol, and benzyl alcohol. Among these, 1-hexanol, 2-heptanol, and 2-hexanol are preferable, and 1-hexanol and 2-hexanol are more preferable.

As the organic solvent, one kind of solvent may be used alone, or two or more kinds of solvents may be used in combination. Further, an organic solvent other than the above or water may be mixed for use. However, in consideration of the development characteristics, the amount of water to be blended in the rinse liquid is preferably 30% by mass or less, more preferably 10% by mass or less, still more preferably 5% by mass or less, and most preferably 3% by mass or less, with respect to the total amount of the rinse liquid.

A conventionally known additive can be blended with the rinse liquid as necessary. Examples of the additive include surfactants. Examples of the surfactant include the same surfactants as those described above, a non-ionic surfactant is preferable, and a non-ionic fluorine surfactant or a non-ionic silicone-based surfactant is more preferable.

In a case where a surfactant is blended, the amount of the surfactant to be blended is typically 0.001% to 5% by mass, preferably 0.005% to 2% by mass, and more preferably 0.01% to 0.5% by mass, with respect to the total amount of the rinse liquid.

The rinsing treatment (washing treatment) using a rinse liquid can be performed by a conventionally known rinse method. Examples of the rinsing treatment method include a method in which the rinse liquid is continuously ejected and applied onto a support which rotates at a constant rate (a rotational coating method), a method in which a support is dipped in the rinse liquid for a predetermined time (a dip method), and a method in which the rinse liquid is sprayed onto the surface of a support (a spray method).

According to the method of forming a resist pattern of the present embodiment described above, since the resist composition of the present embodiment described above is used, it is possible to form a resist pattern in which the generation of scum is reduced.

### EXAMPLES

Hereinafter, the present invention will be described in more detail based on Examples, but the present invention is not limited to these Examples.

<Preparation of Resist Composition>

### Examples 1 to 12 and Comparative Examples 1 to 3

Each of the components shown in Tables 1 and 2 was mixed and dissolved to prepare a resist composition of each Example.

TABLE 1

| | Component | Component | Component | Component |
|---|---|---|---|---|
| | (A) | (B) | (D0) | (S) |
| Example 1 | (A)-1 | (B)-1 | (D0)-1 | (S)-1 |
| | [100] | [15] | [7.5] | [6,400] |
| Example 2 | (A)-1 | (B)-1 | (D0)-2 | (S)-1 |
| | [100] | [15] | [7.0] | [6,400] |
| Example 3 | (A)-1 | (B)-2 | (D0)-1 | (S)-1 |
| | [100] | [16.3] | [7.5] | [6,400] |
| Example 4 | (A)-1 | (B)-3 | (D0)-1 | (S)-1 |
| | [100] | [15.8] | [7.5] | [6,400] |
| Example 5 | (A)-1 | (B)-4 | (D0)-1 | (S)-1 |
| | [100] | [16.6] | [7.5] | [6,400] |
| Example 6 | (A)-2 | (B)-1 | (D0)-1 | (S)-1 |
| | [100] | [15] | [7.5] | [6,400] |
| Example 7 | (A)-3 | (B)-1 | (D0)-1 | (S)-1 |
| | [100] | [15] | [7.5] | [6,400] |
| Example 8 | (A)-4 | (B)-1 | (D0)-1 | (S)-1 |
| | [100] | [15] | [7.5] | [6,400] |
| Example 9 | (A)-5 | (B)-1 | (D0)-1 | (S)-1 |
| | [100] | [15] | [7.5] | [6,400] |
| Example 10 | (A)-1 | (B)-1 | (D0)-1 | (S)-1 |
| | [100] | [15] | [10] | [6,400] |
| Example 11 | (A)-1 | (B)-1 | (D0)-1 | (S)-1 |
| | [100] | [10] | [10] | [6,400] |
| Example 12 | (A)-1 | (B)-1 | (D0)-1 | (S)-1 |
| | [100] | [5.0] | [10] | [6,400] |

TABLE 2

| | Component | Component | Component | Component |
|---|---|---|---|---|
| | (A) | (B) | (D1) | (S) |
| Comparative | (A)-1 | (B)-1 | (D1)-1 | (S)-1 |
| Example 1 | [100] | [15] | [6.4] | [6,400] |
| Comparative | (A)-1 | (B)-1 | (D1)-2 | (S)-1 |
| Example 2 | [100] | [15] | [7.5] | [6,400] |
| Comparative | (A)-1 | (B)-4 | (D1)-3 | (S)-1 |
| Example 3 | [100] | [16.6] | [6.4] | [6,400] |

In Tables 1 and 2, each abbreviation has the following meaning. The numerical value in the bracket indicates the blending amount (parts by mass).

(A)-1: a high molecular compound represented by Chemical Formula (A-1). The standard polystyrene-equivalent weight-average molecular weight (Mw) determined by GPC measurement and the polydispersity (Mw/Mn) are respectively 7,000 and 1.70. The copolymerization compositional ratio (the ratio (molar ratio) between constitutional units in the structural formula) determined by ¹³C-NMR was 1/m=50/50.

(A)-2: a high molecular compound represented by Chemical Formula (A-2). The standard polystyrene-equivalent weight-average molecular weight (Mw) determined by GPC measurement and the polydispersity (Mw/Mn) are respectively 6,800 and 1.75. The copolymerization compositional ratio (the ratio (molar ratio) between constitutional units in the structural formula) determined by ¹³C-NMR was 1/m=50/50.

(A)-3: a high molecular compound represented by Chemical Formula (A-3). The standard polystyrene-equivalent weight-average molecular weight (Mw) determined by GPC measurement and the polydispersity (Mw/Mn) are respectively 7,100 and 1.68. The copolymerization compositional ratio (the ratio (molar ratio) between constitutional units in the structural formula) determined by ¹³C-NMR was 1/m=50/50.

(A)-4: a high molecular compound represented by Chemical Formula (A-4). The standard polystyrene-equivalent weight-average molecular weight (Mw) determined by GPC measurement and the polydispersity (Mw/Mn) are respectively 7,000 and 1.70. The copolymerization compositional ratio (the ratio (molar ratio) between constitutional units in the structural formula) determined by ¹³C-NMR was 1/m=50/50.

(A)-5: a high molecular compound represented by Chemical Formula (A-5). The standard polystyrene-equivalent weight-average molecular weight (Mw) determined by GPC measurement and the polydispersity (Mw/Mn) are respectively 7,200 and 1.72. The copolymerization compositional ratio (the ratio (molar ratio) between constitutional units in the structural formula) determined by ¹³C-NMR was 1/m=50/50.

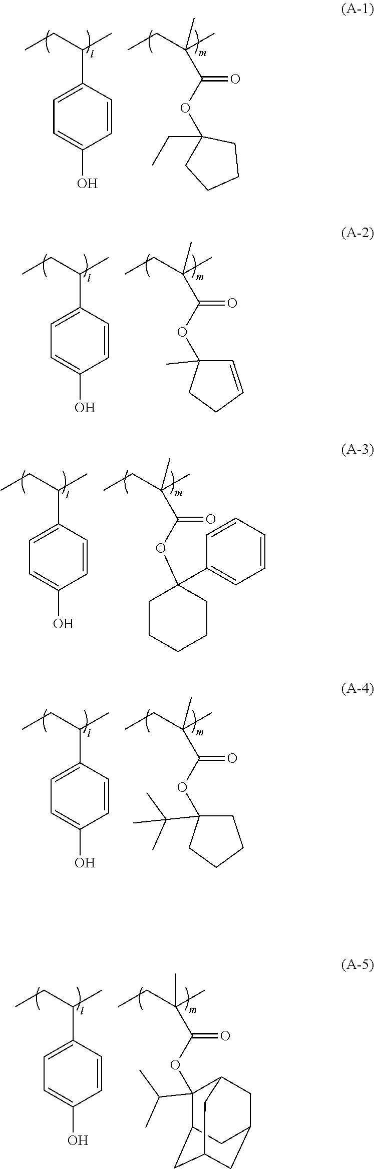

(B)-1 to (B)-4: acid generators composed of compounds respectively represented by compounds (B-1) to (B-4) described below.

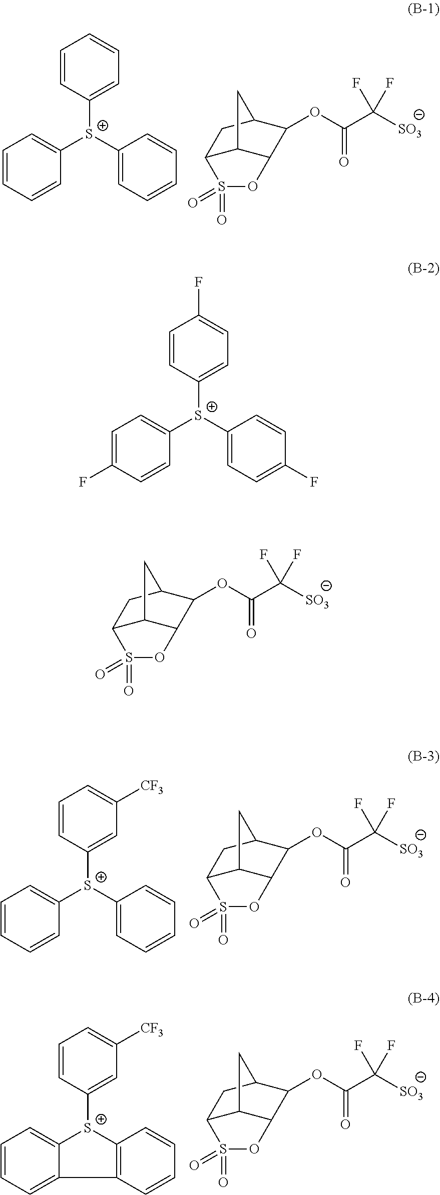

(D0)-1: an acid diffusion controlling agent composed of a compound represented by Chemical Formula (D0-1) described below.

(D0)-2: an acid diffusion controlling agent composed of a compound represented by Chemical Formula (D0-2) described below.

(D1)-1 to (D1)-3: acid diffusion controlling agents composed of compounds respectively represented by Chemical Formulae (D1-1) to (D1-3) described below.

(S)-1: a mixed solvent of propylene glycol monomethyl ether acetate/propylene glycol monomethyl ether=60/40 (mass ratio)

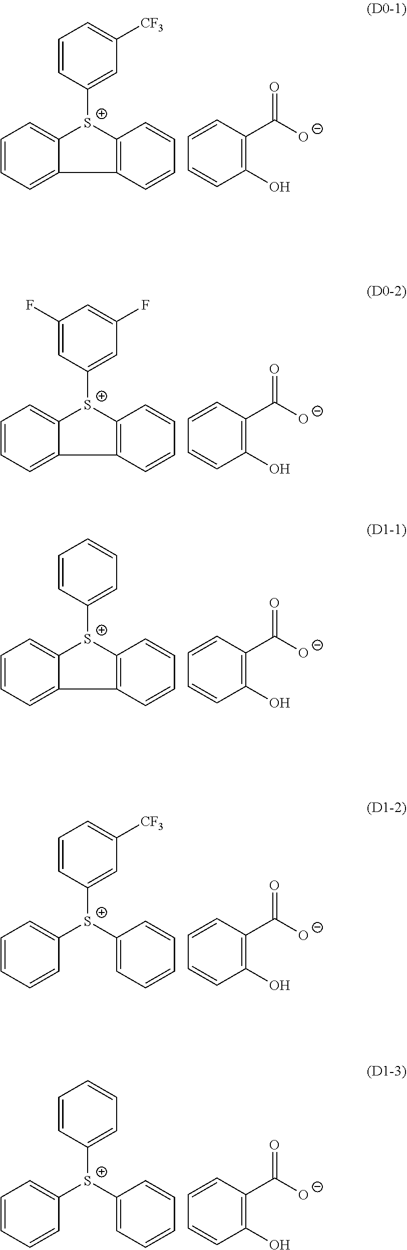

<Formation of Resist Pattern>

An 8-inch silicon substrate which had been treated with hexamethyldisilazane (HMDS) treatment was coated with each resist composition of the examples using a spinner, and a prebake (PAB) treatment was performed thereon on a hot plate at a temperature of 110° C. for 60 seconds so that the composition was dried to form a resist film having a film thickness of 50 nm.

Next, drawing (exposure) was performed on the resist film by using an electron beam lithography apparatus JEOL-JBX-9300FS (manufactured by JEOL Ltd.), with the target size being set to a line width of 50 nm of a 1:1 line-and-space pattern (hereinafter, referred to as “LS pattern”), at an accelerating voltage of 100 kV, and the post-exposure baking (PEB) treatment was performed at 90 C for 60 seconds.

Subsequently, alkali development was performed at 23° C. for 60 seconds using a 2.38% by mass tetramethylammonium hydroxide (TMAH) aqueous solution “NMD-3” (trade name, manufactured by Tokyo Ohka Kogyo Co., Ltd.), and rinsing was performed with pure water for 15 seconds. As a result, a 1:1 LS pattern having a line width of 50 nm was formed.

[Evaluation of Optimum Exposure Amount (Eop)]

According to <Formation of resist pattern> described above, an optimum exposure amount Eop (μC/cm²) for forming the LS pattern having the target size was determined. The results are shown in Tables 3 and 4 as “Eop (μC/cm²)”.

[Evaluation of Linewise Roughness (LWR)]

3σ of the LS pattern having the target size which had been formed in <Formation of resist pattern>, which is a scale indicating LWR, was determined. The results are shown in Tables 3 to 4 as “LWR (nm)”.

“3σ” is a triple value of the standard deviation determined from measurement results obtained by measuring 400 line positions in the longitudinal direction of the line with a scanning electron microscope (accelerating voltage: 800V, trade name: S-9380, manufactured by Hitachi High-Tech Corporation). It shows a triple value (3a) (unit: nm) of (a).

The smaller the value of 3a is, the smaller the roughness in the line side wall is, which means that an LS pattern having a more uniform width was obtained.

[Evaluation of Scum]

An LS pattern having a line width of 55 nm and a space width of 45 nm was formed by the same method as in <Formation of resist pattern>, except that the exposure amount was reduced from the optimum exposure amount (Eop). The formed LS pattern was observed with a scanning electron microscope S-9380 (manufactured by Hitachi High-Tech Corporation), and the amount of scum generated was evaluated according to the following criteria. The results are shown in Tables 3 and 4 as “Scum”.

[Evaluation Criteria]

A: No scum was generated after development

B: Almost no scum was generated after development

C: Scum was generated after development

| | PAB | PEB | Eop | LWR | |
|---|---|---|---|---|---|
| | (° C.) | (° C.) | [μC./cm²] | [nm] | Scum |
| Example 1 | 110 | 90 | 88 | 4.7 | B |
| Example 2 | 110 | 90 | 90 | 4.7 | B |
| Example 3 | 110 | 90 | 84 | 4.5 | A |
| Example 4 | 110 | 90 | 82 | 4.5 | A |
| Example 5 | 110 | 90 | 72 | 4.6 | A |
| Example 6 | 110 | 90 | 90 | 4.7 | B |
| Example 7 | 110 | 90 | 94 | 4.6 | B |
| Example 8 | 110 | 90 | 89 | 4.8 | B |
| Example 9 | 110 | 90 | 94 | 4.7 | B |
| Example 10 | 110 | 90 | 104 | 4.9 | B |
| Example 11 | 110 | 90 | 128 | 5.0 | B |
| Example 12 | 110 | 90 | 154 | 4.9 | B |

| | PAB | PEB | Eop | LWR | |
|---|---|---|---|---|---|
| | (° C.) | (° C.) | [μC./cm²] | [nm] | Scum |
| Comparative | 110 | 90 | 126 | 4.8 | C |
| Example 1 | | | | | |
| Comparative | 110 | 90 | 129 | 4.7 | C |
| Example 2 | | | | | |
| Comparative | 110 | 90 | 74 | 5.2 | C |
| Example 3 | | | | | |

From the results shown in Tables 3 and 4, it can be confirmed that in the resist compositions of Examples, the generation of scum is suppressed as compared with the resist composition of the Comparative Examples. Further, it can be confirmed that the resist compositions of Examples 1 to 10, in which the content of the acid generator component (B) is higher than the content of the photodegradable base (D0), are excellent in sensitivity and roughness reducing property as compared with the resist compositions of Examples 11 and 12.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description and is only limited by the scope of the appended claims.

What is claimed is:

1. A resist composition which generates an acid upon exposure and exhibits changed solubility in a developing solution under action of acid, the resist composition comprising:
a base material component (A) exhibiting changed solubility in a developing solution under action of acid;
an acid generator component (B) generating an acid upon exposure; and
a photodegradable base (D0) controlling diffusion of the acid generated from the acid generator component (B) upon exposure,
wherein the photodegradable base (D0) contains a compound represented by General Formula (d0): 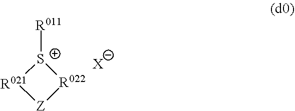
wherein R⁰¹¹ represents an aryl group having an electron-withdrawing group; R⁰²¹ and R⁰²² each independently represent an aryl group which may have a substituent; Z represents a sulfur atom, an oxygen atom, a carbonyl group, or a single bond; and X⁻ represents a counter anion.

2. The resist composition according to claim 1, wherein a content of the acid generator component (B) is higher than a content of the photodegradable base (D0).

3. The resist composition according to claim 1, wherein Z in Formula (d0) represents a single bond.

4. The resist composition according to claim 1,
wherein X⁻ in Formula (d0) is an anion represented by any one of General Formulae (d0-an-1) to (d0-an-3): 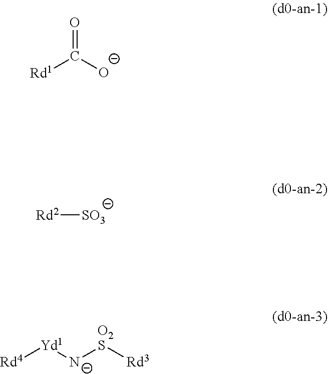
wherein Rd¹ to Rd⁴ each independently represents a cyclic group which may have a substituent, a chain alkyl group which may have a substituent, or a chain alkenyl group which may have a substituent, provided that a fluorine atom is not bonded to a carbon atom adjacent to a S atom in Rd² in Formula (d0-an-2); and Yd¹ represents a single bond or a divalent linking group.

5. The resist composition according to claim 1, wherein the photodegradable base (D0) is a compound represented by General Formula (d0-1-1): 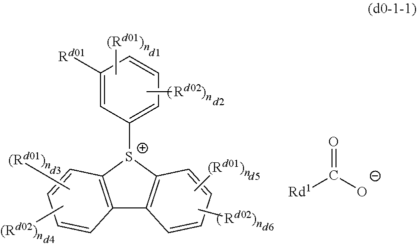
wherein R^{d01} represents a fluorine atom or a fluorinated alkyl group having 1 to 5 carbon atoms, and in a case where plurality of R^{d01} are present in the formula, the plurality of R^{d01} may be the same or different from each other; R^{d02} represents an alkyl group having 1 to 5 carbon atoms, and in a case where plurality of R^{d02} are present in the formula, the plurality of R^{d01} may be the same or different from each other; n_{d1} represents an integer of 0 to 4, n_{d3} and n_{d5} each independently represent an integer of 0 to 4, n_{d2} represents an integer of 0 to 4, and n_{d4} and n_{d6} each independently represent an integer of 0 to 4, provided that 0≤n_{d1}+n_{d2}≤4, 0≤n_{d3}+n_{d4}≤4, and 0≤n_{d5}+n_{d6}≤4 are satisfied; and Rd¹ represents a cyclic group which may have a substituent, a chain alkyl group which may have a substituent, or a chain alkenyl group which may have a substituent.

6. The resist composition according to claim 1, wherein the acid generator component (B) is a compound having an anion moiety and a cation moiety, and the cation moiety of the acid generator component (B) is a cation having an electron-withdrawing group.

7. The resist composition according to claim 1, wherein the acid generator component (B) is a compound represented by General Formula (b-1-1): 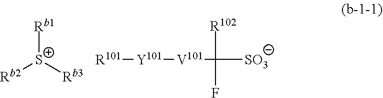
wherein R^{b1} represents an aryl group having an electron-withdrawing group; R^{b2} and R^{b3} each independently represents an aryl group which may independently have a substituent, or R^{b2} and R^{b3} are bonded to each other to form a ring together with the sulfur atom in the formula; R¹⁰¹ represents a cyclic group which may have a substituent, a chain alkyl group which may have a substituent, or a chain alkenyl group which may have a substituent; R¹⁰² represents a fluorinated alkyl group having 1 to 5 carbon atoms or a fluorine atom; Y¹⁰¹ represents a divalent linking group containing an oxygen atom or a single bond; V¹⁰¹ represents a single bond or an oxygen atom.

8. A method of forming a resist pattern, comprising:
forming a resist film on a support using the resist composition according to claim 1;
exposing the resist film; and
developing the exposed resist film to form a resist pattern.

9. The method of forming a resist pattern according to claim 8, wherein the resist film is exposed with extreme ultraviolet (EUV) rays or electron beam (EB).
